(19) United States
(12) Patent Application Publication
(10) Pub. No.: US 2025/0141187 A1
(43) Pub. Date: May 1, 2025

(54) SURFACE EMITTING LASER AND MANUFACTURING METHOD FOR SURFACE EMITTING LASER

(71) Applicant: SONY GROUP CORPORATION, Tokyo (JP)

(72) Inventors: Michinori SHIOMI, Kanagawa (JP); Mikihiro YOKOZEKI, Kanagawa (JP); Masayuki TANAKA, Kanagawa (JP); Tomomasa WATANABE, Kanagawa (JP)

(21) Appl. No.: 18/834,666

(22) PCT Filed: Dec. 19, 2022
(86) PCT No.: PCT/JP2022/046691

§ 371 Date: Jul. 31, 2024

(30) Foreign Application Priority Data
Feb. 9, 2022 (JP) 2022-018649

(51) Int. Cl. H01S 5/183; H01S 5/11; H01S 5/34

(52) U.S. Cl. CPC H01S 5/18361; H01S 5/11; H01S 5/3416

(57) ABSTRACT

The present technology provides a surface emitting laser that can achieve a high output while suppressing an increase in manufacturing cost, and includes a current constriction region.

The surface emitting laser according to the present technology includes: first and second reflection mirrors that are mutually laminated; and a middle part that is disposed between the first and second reflection mirrors, the middle part has a laminated structure formed by laminating a plurality of semiconductor structures including each of a mutually laminated active layer and tunnel junction layer as an intermediate layer, and a peripheral part of at least the tunnel junction layer of the at least one semiconductor structure has higher resistance than resistance of a center part. The surface emitting laser according to the present technology can provide the surface emitting laser that can achieve a high output while suppressing an increase in manufacturing cost, and includes a current constriction region.

### TECHNICAL FIELD

A technology according to the present disclosure (hereinafter, also referred to as a “present technology”) relates to a surface emitting laser and a manufacturing method for the surface emitting laser.

### BACKGROUND ART

Conventionally, there is known a surface emitting laser that includes a plurality of active regions laminated between first and second reflection mirrors to achieve a high output (see, for example, PTL 1).

Furthermore, conventionally, there is known a surface emitting laser that includes a semiconductor structure that includes an active layer and a buried tunnel junction and is disposed between the first and second reflection mirrors (see, for example, PTL 2). The buried tunnel junction functions as a current constriction region.

### CITATION LIST

### Patent Literature

[PTL 1]
JP 2006-019679 A
[PTL 2]
WO 2005/117135

### SUMMARY

### Technical Problem

However, to achieve a high output by laminating a plurality of semiconductor structures each including the active layer and the buried tunnel junction, etching and subsequent burial regrowth need to be performed on tunnel junction layers a number of times the number of which is the same as the number of the buried tunnel junctions, and increases manufacturing cost.

It is therefore a main object of the present technology to provide a surface emitting laser that can achieve a high output while suppressing an increase in manufacturing cost, and includes a current constriction region.

### Solution to Problem

The present technology includes: first and second reflection mirrors that are mutually laminated; and a middle part that is disposed between the first and second reflection mirrors, the middle part has a laminated structure formed by laminating a plurality of semiconductor structures including each of a mutually laminated active layer and tunnel junction layer as an intermediate layer, and a peripheral part of at least the tunnel junction layer of the at least one semiconductor structure has higher resistance than resistance of a center part.

A top layer of the laminated structure on a side of the second reflection mirror 107 may have lower resistance than the resistance of the peripheral part of the tunnel junction layer.

The top layer may be formed of an n-type semiconductor layer.

The top layer may be formed of an n-InP type layer.

A top layer of the laminated structure on a side of the first reflection mirror may have lower resistance than the resistance of the peripheral part of the tunnel junction layer.

The top layer may be formed of an n-type semiconductor layer.

The top layer may be formed of an n-InP type layer.

The semiconductor structure may include a p-type semiconductor layer that is disposed between the active layer and the tunnel junction layer, a first n-type semiconductor layer that is disposed on an opposite side of the active layer to a side of the p-type semiconductor layer, and a second n-type semiconductor layer that is disposed on an opposite side of the tunnel junction layer to the side of the p-type semiconductor layer.

The peripheral part of the p-type semiconductor layer may have the higher resistance than the resistance of the center part in the semiconductor structure. The semiconductor structure may be disposed such that the first n-type semiconductor layer is located on a side of the first reflection mirror, and the second n-type semiconductor layer is located on a side of the second reflection mirror, and the second n-type semiconductor layer of the semiconductor structure closest to the second reflection mirror, and the first n-type semiconductor layer of the semiconductor structure closest to the first reflection mirror may have lower resistance than the resistance of the peripheral part of the p-type semiconductor layer.

Peripheral parts of all layers other than the second n-type semiconductor layer of the semiconductor structure closest to the second reflection mirror, and the first n-type semiconductor layer of the semiconductor structure closest to the first reflection mirror may have higher resistance than the resistance of the center part in the laminated structure.

Peripheral parts of the second n-type semiconductor layer of the semiconductor structure closest to the second reflection mirror, the first n-type semiconductor layer of the semiconductor structure closest to the first reflection mirror, and all layers other than the first and second n-type semiconductor layers of the semiconductor structure located at a middle of the laminated structure may have higher resistance than the resistance of the center part in the laminated structure.

The semiconductor structure may be disposed such that the first n-type semiconductor layer is located on a side of the second reflection mirror, and the second n-type semiconductor layer is located on a side of the first reflection mirror, and the first n-type semiconductor layer of the semiconductor structure closest to the second reflection mirror, and the second n-type semiconductor layer of the semiconductor structure closest to the first reflection mirror may have lower resistance than the resistance of the peripheral part of the p-type semiconductor layer.

Peripheral parts of all layers other than the first n-type semiconductor layer of the semiconductor structure closest to the second reflection mirror, and the second n-type semiconductor layer of the semiconductor structure closest to the first reflection mirror may have higher resistance than the resistance of the center part in the laminated structure.

Peripheral parts of the first n-type semiconductor layer of the semiconductor structure closest to the second reflection mirror, the second n-type semiconductor layer of the semiconductor structure closest to the first reflection mirror, and all layers other than the first and second n-type semiconductor layers of the semiconductor structure located at a middle of the laminated structure may have higher resistance than the resistance of the center part in the laminated structure.

The tunnel junction layer of the semiconductor structure that is part of a plurality of the semiconductor structures is a burial type.

One of the first and second reflection mirrors may be a dielectric multilayer film reflection mirror that has a photonic crystal structure.

The middle part may include a heat dissipation member between one of the first and second reflection mirrors and the laminated structure.

The present technology also provides a manufacturing method for a surface emitting laser, including:
a step of generating a laminated body formed by laminating a plurality of semiconductor structures each including each of an active layer and a tunnel junction layer as an intermediate layer; and
a step of making resistance of a peripheral part of at least the tunnel junction layer of the semiconductor structure higher than resistance of a center part by injecting an ion into the laminated body.

A top surface on one side and/or a top surface on an other side of the laminated body may be an n-type semiconductor layer, in the step of making the resistance higher, resistance of a peripheral part of the n-type semiconductor layer is made higher than the resistance of the center part, and the manufacturing method for the surface emitting laser may further include a step of performing annealing treatment on the laminated body after the step of making the resistance higher, and making the resistance of the peripheral part of the n-type semiconductor layer lower.

### BRIEF DESCRIPTION OF DRAWINGS

FIG. 1 is a cross-sectional view of a surface emitting laser according to example 1 of an embodiment of the present technology.

FIG. 2 is a flowchart for describing an example of a manufacturing method for the surface emitting laser in FIG. 1.

FIG. 3 is a cross-sectional view of each process of the example of the manufacturing method for the surface emitting laser in FIG. 1.

FIG. 4 is a cross-sectional view of each process of the example of the manufacturing method for the surface emitting laser in FIG. 1.

FIG. 5 is a cross-sectional view of each process of the example of the manufacturing method for the surface emitting laser in FIG. 1.

FIG. 6 is a cross-sectional view of each process of the example of the manufacturing method for the surface emitting laser in FIG. 1.

FIG. 7 is a cross-sectional view of each process of the example of the manufacturing method for the surface emitting laser in FIG. 1.

FIG. 8 is a cross-sectional view of each process of the example of the manufacturing method for the surface emitting laser in FIG. 1.

FIG. 9 is a cross-sectional view of each process of the example of the manufacturing method for the surface emitting laser in FIG. 1.

FIG. 10 is a cross-sectional view of each process of the example of the manufacturing method for the surface emitting laser in FIG. 1.

FIG. 11 is a cross-sectional view of each process of the example of the manufacturing method for the surface emitting laser in FIG. 1.

FIG. 12 is a cross-sectional view of each process of the example of the manufacturing method for the surface emitting laser in FIG. 1.

FIG. 13 is a cross-sectional view of each process of the example of the manufacturing method for the surface emitting laser in FIG. 1.

FIG. 14 is a cross-sectional view of each process of the example of the manufacturing method for the surface emitting laser in FIG. 1.

FIG. 15 is a cross-sectional view of each process of the example of the manufacturing method for the surface emitting laser in FIG. 1.

FIG. 16 is a cross-sectional view of each process of the example of the manufacturing method for the surface emitting laser in FIG. 1.

FIG. 17 is a cross-sectional view of each process of the example of the manufacturing method for the surface emitting laser in FIG. 1.

FIG. 18 is a cross-sectional view of each process of the example of the manufacturing method for the surface emitting laser in FIG. 1.

FIG. 19 is a cross-sectional view of each process of the example of the manufacturing method for the surface emitting laser in FIG. 1.

FIG. 20 is a cross-sectional view of each process of the example of the manufacturing method for the surface emitting laser in FIG. 1.

FIG. 21 is a cross-sectional view of the surface emitting laser according to example 2 of the embodiment of the present technology.

FIG. 22 is a flowchart for describing an example of the manufacturing method for the surface emitting laser in FIG. 21.

FIG. 23 is a cross-sectional view of each process of the example of the manufacturing method for the surface emitting laser in FIG. 21.

FIG. 24 is a cross-sectional view of each process of the example of the manufacturing method for the surface emitting laser in FIG. 21.

FIG. 25 is a cross-sectional view of each process of the example of the manufacturing method for the surface emitting laser in FIG. 21.

FIG. 26 is a cross-sectional view of each process of the example of the manufacturing method for the surface emitting laser in FIG. 21.

FIG. 27 is a cross-sectional view of each process of the example of the manufacturing method for the surface emitting laser in FIG. 21.

FIG. 28 is a cross-sectional view of each process of the example of the manufacturing method for the surface emitting laser in FIG. 21.

FIG. 29 is a cross-sectional view of each process of the example of the manufacturing method for the surface emitting laser in FIG. 21.

FIG. 30 is a cross-sectional view of each process of the example of the manufacturing method for the surface emitting laser in FIG. 21.

FIG. 31 is a cross-sectional view of each process of the example of the manufacturing method for the surface emitting laser in FIG. 21.

FIG. 32 is a cross-sectional view of each process of the example of the manufacturing method for the surface emitting laser in FIG. 21.

FIG. 33 is a cross-sectional view of each process of the example of the manufacturing method for the surface emitting laser in FIG. 21.

FIG. 34 is a cross-sectional view of each process of the example of the manufacturing method for the surface emitting laser in FIG. 21.

FIG. 35 is a cross-sectional view of each process of the example of the manufacturing method for the surface emitting laser in FIG. 21.

FIG. 36 is a cross-sectional view of the surface emitting laser according to example 3 of the embodiment of the present technology.

FIG. 37 is a flowchart for describing an example of the manufacturing method for the surface emitting laser in FIG. 36.

FIG. 38 is a cross-sectional view of each process of the example of the manufacturing method for the surface emitting laser in FIG. 36.

FIG. 39 is a cross-sectional view of each process of the example of the manufacturing method for the surface emitting laser in FIG. 36.

FIG. 40 is a cross-sectional view of each process of the example of the manufacturing method for the surface emitting laser in FIG. 36.

FIG. 41 is a cross-sectional view of each process of the example of the manufacturing method for the surface emitting laser in FIG. 36.

FIG. 42 is a cross-sectional view of the surface emitting laser according to example 4 of the embodiment of the present technology.

FIG. 43 is a flowchart for describing an example of the manufacturing method for the surface emitting laser in FIG. 42.

FIG. 44 is a cross-sectional view of each process of the example of the manufacturing method for the surface emitting laser in FIG. 42.

FIG. 45 is a cross-sectional view of each process of the example of the manufacturing method for the surface emitting laser in FIG. 42.

FIG. 46 is a cross-sectional view of each process of the example of the manufacturing method for the surface emitting laser in FIG. 42.

FIG. 47 is a cross-sectional view of each process of the example of the manufacturing method for the surface emitting laser in FIG. 42.

FIG. 48 is a cross-sectional view of each process of the example of the manufacturing method for the surface emitting laser in FIG. 42.

FIG. 49 is a cross-sectional view of each process of the example of the manufacturing method for the surface emitting laser in FIG. 42.

FIG. 50 is a cross-sectional view of the surface emitting laser according to example 5 of the embodiment of the present technology.

FIG. 51 is a cross-sectional view of the surface emitting laser according to example 6 of the embodiment of the present technology.

FIG. 52 is a cross-sectional view of the surface emitting laser according to example 7 of the embodiment of the present technology.

FIG. 53 is a cross-sectional view of the surface emitting laser according to example 8 of the embodiment of the present technology.

FIG. 54 is a plan view of the surface emitting laser according to example 8 of the embodiment of the present technology.

FIG. 55 is a cross-sectional view of the surface emitting laser according to example 9 of the embodiment of the present technology.

FIG. 56 is a cross-sectional view of the surface emitting laser according to example 10 of the embodiment of the present technology.

FIG. 57 is a cross-sectional view of the surface emitting laser according to example 11 of the embodiment of the present technology.

FIG. 58 is a cross-sectional view of the surface emitting laser according to example 12 of the embodiment of the present technology.

FIG. 59 is a cross-sectional view of the surface emitting laser according to example 13 of the embodiment of the present technology.

FIG. 60 is a cross-sectional view of the surface emitting laser according to example 14 of the embodiment of the present technology.

FIG. 61 is a cross-sectional view of the surface emitting laser according to example 15 of the embodiment of the present technology.

FIG. 62 is a cross-sectional view of the surface emitting laser according to example 16 of the embodiment of the present technology.

FIG. 63 is a diagram illustrating an example of application of the surface emitting laser according to the present technology to a distance measurement device.

FIG. 64 is a block diagram illustrating an example of a schematic configuration of a vehicle control system.

FIG. 65 is an explanatory diagram illustrating an example of an installation position of the distance measurement device.

### DESCRIPTION OF EMBODIMENTS

A preferred embodiment of the present technology will be described in detail with reference to the accompanying figures below. In the present specification and the drawings, components having substantially the same functional configuration will be denoted by the same reference numerals, and thus repeated descriptions thereof will be omitted. The embodiment to be described below shows a representative embodiment of the present technology, and the scope of the present technology should not be narrowly instructed on the basis of this. Even when the present specification describes that a surface emitting laser and a manufacturing method for the surface emitting laser according to the present technology have a plurality of effects, the surface emitting laser and a manufacturing method for the surface emitting laser according to the present technology may have at least one effect. The advantageous effects described in the present specification are merely exemplary and are not limited, and other advantageous effects may be obtained.

Furthermore, the description will be made in the following order.
0. Introduction
1. Surface Emitting Laser According to Example 1 of Embodiment of Present Technology
2. Surface Emitting Laser According to Example 2 of Embodiment of Present Technology
3. Surface Emitting Laser According to Example 3 of Embodiment of Present Technology
4. Surface Emitting Laser According to Example 4 of Embodiment of Present Technology
5. Surface Emitting Laser According to Example 5 of Embodiment of Present Technology
6. Surface Emitting Laser According to Example 6 of Embodiment of Present Technology
7. Surface Emitting Laser According to Example 7 of Embodiment of Present Technology
8. Surface Emitting Laser According to Example 8 of Embodiment of Present Technology
9. Surface Emitting Laser According to Example 9 of Embodiment of Present Technology
10. Surface Emitting Laser According to Example 10 of Embodiment of Present Technology
11. Surface Emitting Laser According to Example 11 of Embodiment of Present Technology
12. Surface Emitting Laser According to Example 12 of Embodiment of Present Technology
13. Surface Emitting Laser According to Example 13 of Embodiment of Present Technology
14. Surface Emitting Laser According to Example 14 of Embodiment of Present Technology
15. Surface Emitting Laser According to Example 15 of Embodiment of Present Technology
16. Surface Emitting Laser According to Example 16 of Embodiment of Present Technology
17. Modification Example of Present Technology
18. Example of Application to Electronic Device
19. Application of Surface Emitting Laser to Distance Measurement Device
20. Example Where Distance Measurement Device Is Mounted on Moving Body

### 0. Introduction

In recent years, development of infrared surface emitting lasers used for 3D sensing and face recognition has been advancing. Currently, the infrared surface emitting laser mainly uses, for example, a 940 nm band as an oscillation wavelength, yet is desired to have a longer wavelength in future. For example, a 1.4 μm band in particular has an advantage that the 1.4 μm band is an eye safe band at which a damage threshold for eyes substantially increases and, in addition, noise at a time of sensing is suppressed low since the strength of sunlight is low.

On the other hand, an InP-based surface emitting laser that is suitable for a long wavelength equal to or more than, for example, 1.3 μm as the oscillation wavelength has a problem that it is difficult to make, for example, a current constriction structure due to oxidation of an AlAs layer used by a GaAs-based surface emitting laser. Hence, although a Buried Tunnel Junction (BTJ) structure is frequently used as the current constriction structure for the InP-based surface emitting laser, this BTJ structure needs etching and then buried regrowth of Tunnel Junction layers (TJ layers), and increases the number of processes.

By the way, there is proposed a surface emitting laser that is formed by laminating a plurality of active layers to achieve a high output (see, for example, Patent Literature 1). However, in a case where the BTJ structure for current constriction is provided to each active layer in this surface emitting laser, etching and subsequent burial regrowth need to be performed on tunnel junction layers a number of times the number of which is the same as the number of the active layers, and increases manufacturing cost.

Hence, as a result of earnest study, the inventors have developed a surface emitting laser according to the present technology as a surface emitting laser that can achieve a high output while suppressing an increase in manufacturing cost, and includes a current constriction region.

Hereinafter, some examples of the embodiment of the surface emitting laser according to the present technology will be described in detail.

### 1. Surface Emitting Laser According to Example 1 of Embodiment of Present Technology

### <<Configuration of Surface Emitting Laser>>

### (Overall Configuration)

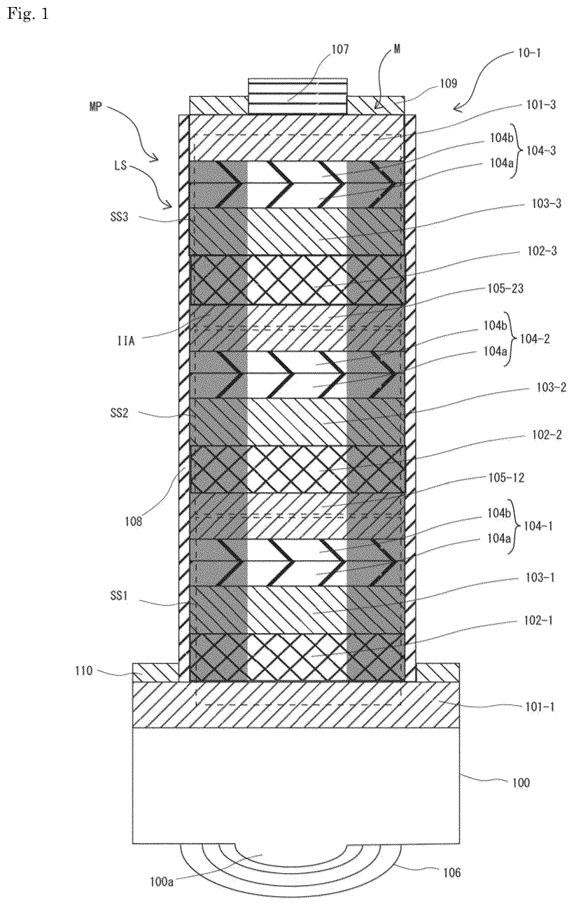

FIG. 1 is a cross-sectional view of a surface emitting laser 10-1 according to example 1 of the embodiment of the present technology. Hereinafter, description will be made assuming for convenience of description that an upper direction in the cross-sectional views in FIG. 1 and the other figures is an upper side, and a lower direction is a lower side.

The surface emitting laser 10-1 is a Vertical Cavity Surface Emitting Laser (VCSEL). The surface emitting laser 10-1 includes first and second reflection mirrors 106 and 107 that are mutually laminated, and a middle part MP that is disposed between the first and second reflection mirrors 106 and 107. The surface emitting laser 10-1 is driven by, for example, a laser driver.

The middle part MP has a laminated structure LS formed by laminating a plurality of (e.g., three) semiconductor structures SS (that are, for example, first to third semiconductor structures SS1 to SS3 and structures surrounded by broken lines in FIG. 1) each including each of a mutually laminated active layer 102 and tunnel junction layer 104 as an intermediate layer.

The middle part MP further includes a substrate 100 disposed between the laminated structure LS and the first reflection mirror 106. For example, the back surface (lower surface) of the substrate 100 is provided with the first reflection mirror 106.

The first to third semiconductor structures SS1 to SS3 are laminated in this order from the side (lower side) of the substrate 100.

The first semiconductor structure SS1 includes an active layer 102-1 and a tunnel junction layer 104-1 that are mutually laminated, a p-type semiconductor layer 103-1 that is disposed between the active layer 102-1 and the tunnel junction layer 104-1, an n-type semiconductor layer 101-1 (first n-type semiconductor layer) that is disposed on an opposite side to a p-type semiconductor layer 103-1 side of the active layer 102-1, and an n-type semiconductor layer 105-12 (second n-type semiconductor layer) that is disposed on an opposite side to the p-type semiconductor layer 103-1 side of the tunnel junction layer 104-1. The first semiconductor structure SS1 is disposed such that the n-type semiconductor layer 101-1 is located on a first reflection mirror 106 side and the n-type semiconductor layer 105-12 is located on a second reflection mirror 107 side.

The second semiconductor structure SS2 includes an active layer 102-2 and a tunnel junction layer 104-2 that are mutually laminated, a p-type semiconductor layer 103-2 that is disposed between the active layer 102-2 and the tunnel junction layer 104-2, the n-type semiconductor layer 105-12 (first n-type semiconductor layer) that is disposed on an opposite side to a p-type semiconductor layer 103-2 side of the active layer 102-2, and an n-type semiconductor layer 105-23 (second n-type semiconductor layer) that is disposed on an opposite side to the p-type semiconductor layer 103-2 side of the tunnel junction layer 104-2. The second semiconductor structure SS2 is disposed such that the n-type semiconductor layer 105-12 is located on the first reflection mirror 106 side and the n-type semiconductor layer 105-23 is located on the second reflection mirror 107 side.

The third semiconductor structure SS3 includes an active layer 102-3 and a tunnel junction layer 104-3 that are mutually laminated, a p-type semiconductor layer 103-3 that is disposed between the active layer 102-3 and the tunnel junction layer 104-3, the n-type semiconductor layer 105-23 (first n-type semiconductor layer) that is disposed on an opposite side to a p-type semiconductor layer 103-3 side of the active layer 102-3, and an n-type semiconductor layer 101-3 (second n-type semiconductor layer) that is disposed on an opposite side to the p-type semiconductor layer 103-3 side of the tunnel junction layer 104-3. The third semiconductor structure SS3 is disposed such that the n-type semiconductor layer 105-23 is located on the first reflection mirror 106 side and the n-type semiconductor layer 101-3 is located on the second reflection mirror 107 side.

The first and second semiconductor structures SS1 and SS2 share the n-type semiconductor layer 105-12. That is, the n-type semiconductor layer 105-12 functions as both of the second n-type semiconductor layer of the first semiconductor structure SS1 and the first n-type semiconductor layer of the second semiconductor structure SS2.

The second and third semiconductor structures SS2 and SS3 share the n-type semiconductor layer 105-23. That is, the n-type semiconductor layer 105-23 functions as both of the second n-type semiconductor layer of the second semiconductor structure SS2 and the first n-type semiconductor layer of the third semiconductor structure SS3.

For example, the laminated structure LS includes a mesa M provided on the n-type semiconductor layer 101-1 of the first semiconductor structure SS1. For example, the mesa M includes all layers other than the n-type semiconductor layer 101-1 of the first semiconductor structure SS1, and the second and third semiconductor structures SS2 and SS3. The mesa M has, for example, a substantially columnar shape, yet may have other shapes such as a substantially elliptical cylindrical shape, a polygonal prism shape, a truncated conical shape, an elliptical truncated conical shape, or a polygonal truncated conical shape. The diameter of the mesa M is, for example, 5 to 100 μm.

In the laminated structure LS, for example, peripheral parts of all layers other than the top layer (n-type semiconductor layer 101-1) on the first reflection mirror 106 side and the top layer (n-type semiconductor layer 101-3) on the second reflection mirror 107 side are ion implantation regions IIA (regions that are painted gray in FIG. 1). Here, the ion implantation regions IIA have a circular shape (e.g., cylindrical shape) as a whole. That is, in the laminated structure LS, the ion implantation region IIA is a high resistance region (a region having low carrier conductivity), and a region surrounded by the ion implantation region IIA is a low resistance region (a region having high carrier conductivity).

For example, the second reflection mirror 107 is provided at the center part of a top part (the upper surface of the n-type semiconductor layer 101-3) of the mesa M, and an anode electrode 109 of a circular shape (e.g., ring shape) is provided at the peripheral part of the top part of the mesa M so as to surround the second reflection mirror 107. For example, the surface emitting laser 10-1 has the upper surface of the second reflection mirror 107 as an emission surface. That is, for example, the surface emitting laser 10-1 is a surface emission-type surface emitting laser that emits light toward the surface side of the substrate 100.

For example, an insulating film 108 is formed on the side surface of the mesa M.

For example, in a region around the bottom part of the mesa M (a region around the mesa M of the n-type semiconductor layer 101-1), a cathode electrode 110 of a circular shape (e.g., ring shape) is provided so as to surround the bottom part of the mesa M with the insulating film 108 interposed therebetween.

### (Substrate)

The substrate 100 is, for example, a semiconductor substrate such as a GaAs substrate, a Si substrate, and a SiC substrate. Note that, for example, a substrate other than semiconductor substrates such as semi-insulating substrates and insulating substrates may be used as the substrate 100. The thermal conductivity of the substrate 100 is preferably, for example, 40 W/mK or more.

For example, a convex structure 100a of a substantially hemispherical shape is provided to the back surface (lower surface) of the substrate 100. The convex structure 100a is an underlayer of the first reflection mirror 106. The convex structure 100a is located at a position meeting the region (low resistance region) surrounded by the ion implantation region IIA in the laminated structure LS.

### (First Reflection Mirror)

The first reflection mirror 106 is located at a position meeting the region (low resistance region) surrounded by the ion implantation region IIA in the laminated structure LS. For example, the first reflection mirror 106 is a concave-type dielectric multilayer film reflection mirror. The first reflection mirror 106 is provided along the convex structure 100a provided on the back surface of the substrate 100. As the material of the dielectric multilayer film reflection mirror, for example, SiO₂, TiO₂, Ta₂O₅, a-Si, Al₂O₃, and the like can be used. By using a concave mirror as the first reflection mirror 106, it is possible to condense light produced by the active layer 102, so that it is possible to effectively reduce diffraction loss. By using the dielectric multilayer film reflection mirror as the first reflection mirror 106, it is possible to provide the first reflection mirror 106 that is thin (has a smaller number of pairs) and has high reflectance.

### (Second Reflection Mirror)

The second reflection mirror 107 is located at a position meeting the region (low resistance region) surrounded by the ion implantation region IIA in the laminated structure LS. For example, the second reflection mirror 107 is a plane-type dielectric multilayer film reflection mirror. As the material of the dielectric multilayer film reflection mirror, for example, SiO₂, TiO₂, Ta₂O₅, a-Si, Al₂O₃, and the like can be used. By using the dielectric multilayer film reflection mirror as the second reflection mirror 107, it is possible to provide the second reflection mirror 107 that is thin (has a smaller number of pairs) and has high reflectance. The second reflection mirror 107 has the reflectance that is set slightly lower than that of the first reflection mirror 106.

### (Active Layer)

For example, the active layer 102 (e.g., active layers 102-1 to 102-3) has a quantum well structure including a barrier layer and a quantum well layer made of an AlGaInAs-based compound semiconductor. This quantum well structure may be a single Quantum Well structure (QW structure) or may be a Multiple Quantum Well structure (MQW structure). Another example of the active layer 102 may be an InGaAs-based quantum dot active layer. Each active layer 102 is preferably disposed at a position of a belly of a standing wave in a resonator. The active layer 102 is preferably designed such that an oscillation wavelength A corresponds to a long wavelength of 900 nm or more and, moreover, 1.3 μm or more.

### (Tunnel Junction Layer)

In each semiconductor structure SS, the tunnel junction layer 104 (e.g., tunnel junction layers 104-1 to 104-3) plays a role of converting electrons implanted from the adjacent the n-type semiconductor layer 101 into holes, and implanting the holes into the adjacent p-type semiconductor layer 103. By disposing the tunnel junction layer 104 between the two adjacent active layers 102, it is possible to implant a current in each active layer 102. The tunnel junction layer 104 includes a p-type semiconductor region 104a and an n-type semiconductor region 104b that are disposed in contact with each other. Here, the p-type semiconductor region 104a is disposed on a substrate 100 side (lower side) of the n-type semiconductor region 104b. The p-type semiconductor region 104a is made of a p-type AlGaInAs-based compound semiconductor that is heavily doped with, for example, C, Mg, or Zn. The n-type semiconductor region 104b is made of an InP-based compound semiconductor or an AlGaInAs-based compound semiconductor that is heavily doped with, for example, Si.

(p-Type Semiconductor Layer)

For example, a p-type semiconductor layer 103 (e.g., p-type semiconductor layers 103-1 to 103-3) is made of a p-type InP-based compound semiconductor (e.g., p-InP). The p-type semiconductor layer is also referred to as a clad layer.

(n-Type Semiconductor Layer)

For example, the n-type semiconductor layer 101-1 (first n-type semiconductor structure) of the first semiconductor structure SS1 and the n-type semiconductor layer 101-3 (second n-type semiconductor structure) of the third semiconductor structure SS3 are each made of an n-type InP-based compound semiconductor (e.g., n-InP).

For example, the n-type semiconductor layer 105-12 of the first semiconductor structure SS1 and the second semiconductor structure SS2, and the n-type semiconductor layer 105-23 of the second semiconductor structure SS2 and the third semiconductor structure SS3 are each made of a compound semiconductor (e.g., n-AlGaInAs) that lattice-matches with InP.

Each n-type semiconductor layer is also referred to as a clad layer.

### (Insulating Film)

The insulating film 108 is made of a dielectric such as SiO₂, SiN, SiON, or the like.

### (Anode Electrode)

The anode electrode 109 is made of, for example, Au/Ni/AuGe, Au/Pt/Ti, or the like. The anode electrode 109 is electrically connected to, for example, an anode (positive electrode) of the laser driver.

### (Cathode Electrode)

The cathode electrode 110 is made of, for example, Au/Ni/AuGe, Au/Pt/Ti, or the like. The cathode electrode 110 is electrically connected to, for example, a cathode (negative electrode) of the laser driver.

### (Ion Implantation Region)

For example, the ion implantation region IIA makes the resistance of the peripheral part of at least the tunnel junction layer 104 of each of the first to third semiconductor structures SS1 to SS3 higher than that of the center part.

For example, the peripheral parts of the active layer 102-1, the p-type semiconductor layer 103-1, the tunnel junction layer 104-1, and the n-type semiconductor layer 105-12 of the first semiconductor structure SS1 are the ion implantation regions IIA, and have higher resistance than that of the center part.

For example, the n-type semiconductor layer 101-1 that is a top layer on the first reflection mirror 106 side of the laminated structure LS has lower resistance than that of the peripheral part of each tunnel junction layer 104. The top layer is formed of, for example, an n-InP layer.

For example, the peripheral parts of the n-type semiconductor layer 105-12, the active layer 102-2, the p-type semiconductor layer 103-2, the tunnel junction layer 104-2, and the n-type semiconductor layer 105-23 of the second semiconductor structure SS2 are the ion implantation regions IIA, and have higher resistance than that of the center part.

For example, the peripheral parts of the n-type semiconductor layer 105-23, the active layer 102-3, the p-type semiconductor layer 103-3, and the tunnel junction layer 104-3 of the third semiconductor structure SS3 are the ion implantation regions IIA, and have higher resistance than that of the center part.

For example, the n-type semiconductor layer 101-3 that is the top layer on the second reflection mirror 107 side of the laminated structure LS has lower resistance than that of the peripheral part of each tunnel junction layer 104. The top layer is formed of, for example, an n-InP layer.

For example, the n-type semiconductor layer 101-3 (second n-type semiconductor layer) of the third semiconductor structure SS3 that is a semiconductor structure closest to the second reflection mirror 107, and the n-type semiconductor layer 101-1 (first n-type semiconductor layer) of the first semiconductor structure SS1 that is a semiconductor structure closest to the first reflection mirror 106 have lower resistance than the resistance of the peripheral part of each p-type semiconductor layer 103.

For example, the peripheral parts of all layers other than the n-type semiconductor layer 101-3 (second n-type semiconductor layer) of the third semiconductor structure SS3 that is a semiconductor structure closest to the second reflection mirror 107, and the n-type semiconductor layer 101-1 (first n-type semiconductor layer) of a semiconductor structure closest to the first reflection mirror 106 have higher resistance than that of the center part in the laminated structure LS.

The impurity concentration of the ion implantation region IIA is preferably less than 1×10¹⁹ cm⁻³.

Impurities in the ion implantation region IIA preferably include at least one of H, He, B, C, and O.

### <<Operation of Surface Emitting Laser>>

Hereinafter, an operation of the surface emitting laser 10-1 will be described. When a drive voltage is applied by the laser driver in the surface emitting laser 10-1, the current having flowed from the anode side of the laser driver into the anode electrode 109 is implanted into the active layer 102-3 via the tunnel junction layer 104-3 and the p-type semiconductor layer 103-3 in this order while being constricted in the ion implantation region IIA via the n-type semiconductor layer 101-3, and the active layer 102-3 emits light. Furthermore, the current having passed the active layer 102-3 is implanted into the active layer 102-2 via the n-type semiconductor layer 105-23, the tunnel junction layer 104-2, and the p-type semiconductor layer 103-2 in this order while being constricted in the ion implantation region IIA, and the active layer 102-2 emits light. Furthermore, the current having passed the active layer 102-2 is implanted into the active layer 102-1 via the n-type semiconductor layer 105-12, the tunnel junction layer 104-1, and the p-type semiconductor layer 103-1 in this order while being constricted in the ion implantation region IIA, and the active layer 102-1 emits light. According to a tunneling effect of the tunnel junction layer 104-2, the substantially same current as the current implanted into the active layer 102-3 is implanted into the active layer 102-2. According to a tunneling effect of the tunnel junction layer 104-1, the substantially same current as the current implanted into the active layer 102-2 flows in the active layer 102-1. The current having passed the active layer 102-1 flows out from the cathode electrode 110 to the cathode side of the laser driver via the n-type semiconductor layer 101-1. When light produced by each active layer 102 reciprocates between the first and second reflection mirrors 106 and 107 while being amplified by each active layer 102, and satisfies an oscillation condition, the light is emitted as laser light from the upper surface (emission surface) of the second reflection mirror 107.

### <<Example of Manufacturing Method for Surface Emitting Laser>>

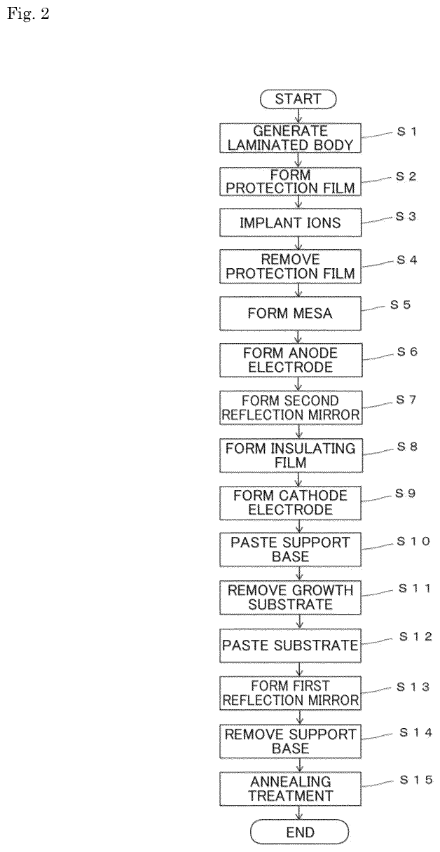

Hereinafter, an example of the manufacturing method for the surface emitting laser 10-1 will be described with reference to a flowchart in FIG. 2. Here, for example, a semiconductor manufacturing method that uses a semiconductor manufacturing device simultaneously generates a plurality of the surface emitting lasers 10-1 on one wafer that is a base material of the substrate 100, separates the plurality of series of integrated surface emitting lasers 10-1 from each other, and obtains chip-shaped surface emitting lasers (surface emitting laser chips). Note that the semiconductor manufacturing method can also simultaneously generate a plurality of surface emitting laser arrays formed by two-dimensionally disposing the plurality of surface emitting lasers 10-1 on the one wafer that is the base material of the substrate 100, separate the plurality of series of integrated surface emitting laser arrays from each other, and obtain a plurality of chip-shaped surface emitting laser arrays (surface emitting laser array chips).

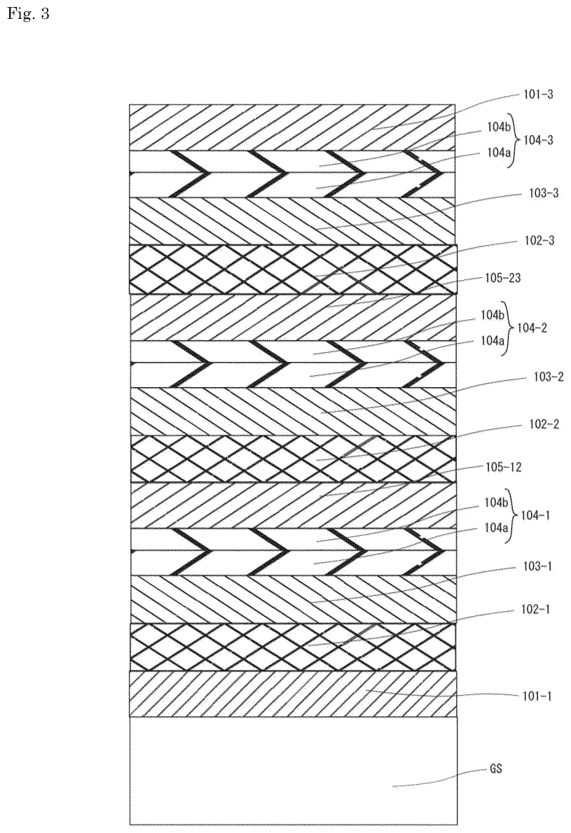

In first step S1, a laminated body is generated (see FIG. 3). More specifically, for example, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are laminated (epitaxially grown) on the growth substrate GS (e.g., InP substrate) in a growth chamber in this order by a Metal Organic Chemical Vapor Deposition method (MOCVD method) or a Molecular Beam Epitaxy method (MBE method). That is, the laminated body is generated by performing epitaxial growth once.

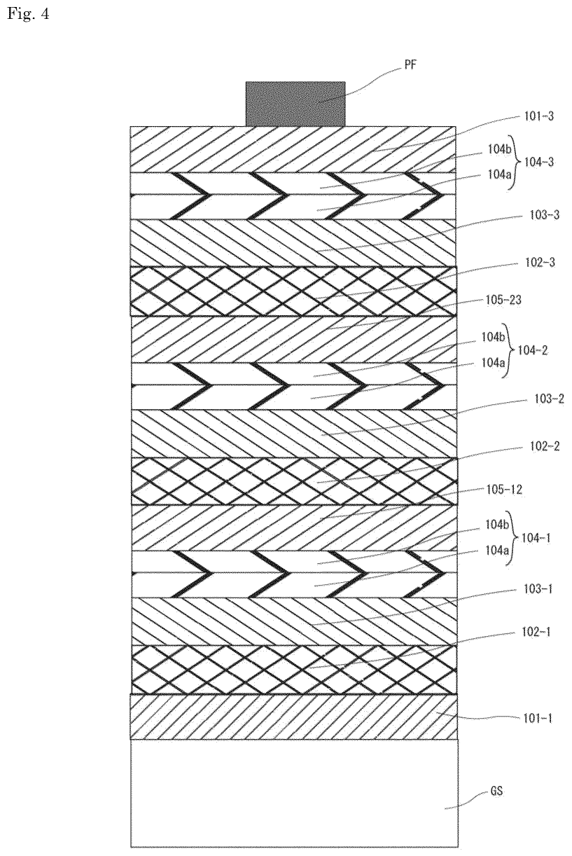

In next step S2, a protection film PF is formed on the laminated body (see FIG. 4). More specifically, a center region of the laminated body for which ion implantation to be described later is not performed is protected by the protection film PF made of SiO₂.

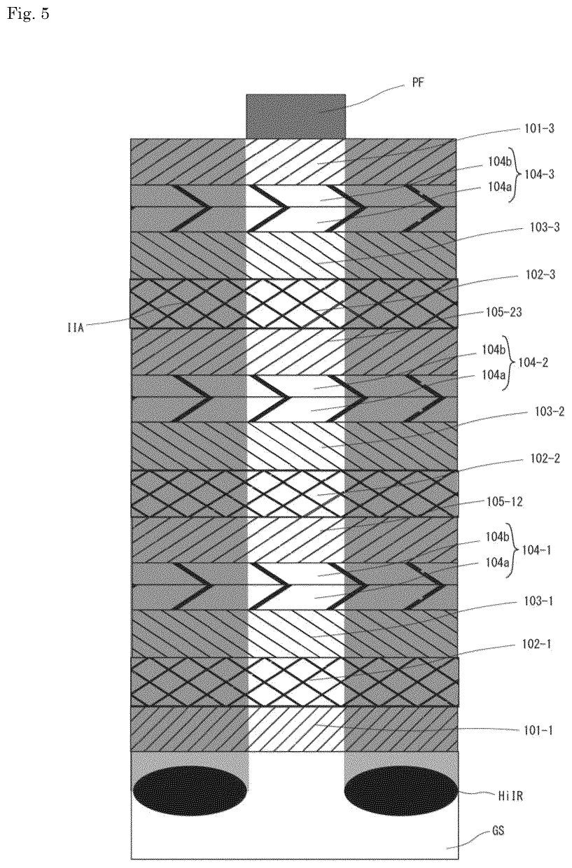

In next step S3, ion implantation is performed (see FIG. 5). More specifically, ions are implanted into a peripheral region (a region on which the protection film PF is not formed) of the laminated body from an n-type semiconductor layer 101-3 side. At this time, for example, the protons (H+) are used as ion species, ion implantation energy is set such that the protons reach (preferably concentrates) in the growth substrate GS, and the dose is set to, for example, 1×10¹⁴ ion/cm² or more. As a result, ion implantation causes crystal defects, and a region into which the ions have been implanted has increased resistance. That is, the peripheral parts of the growth substrate GS, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 have increased resistance. As a result, a high concentration ion region HiIR (parts that are painted black in FIG. 5) including regions in which the ion concentration comes to a peak is formed in the growth substrate GS.

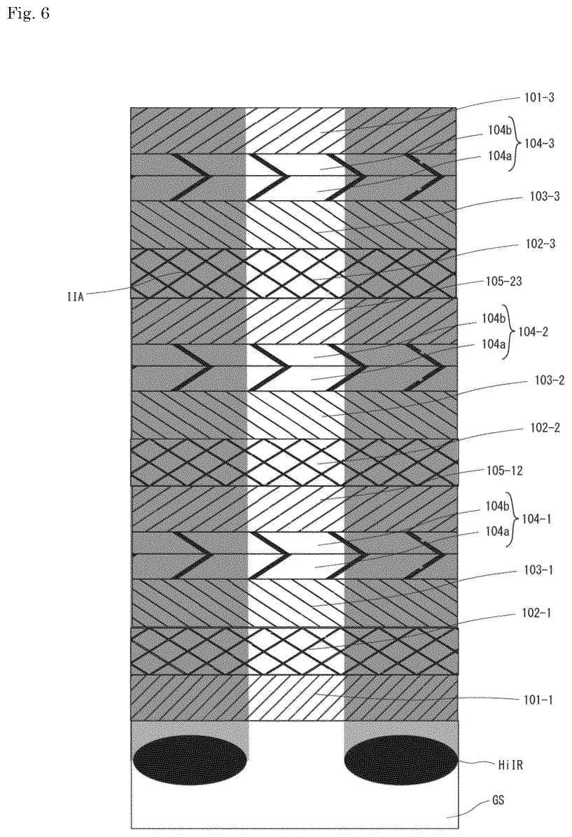

In next step S4, the protection film PF is removed (see FIG. 6).

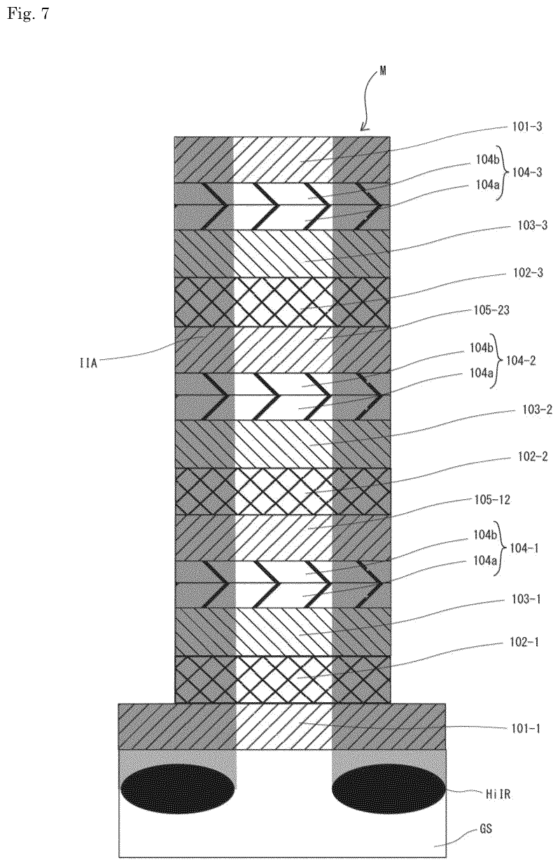

In next step S5, the mesa M is formed (see FIG. 7). More specifically, for example, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are etched to form the mesa M. More specifically, a resist pattern for forming the mesa M on the n-type semiconductor layer 101-3 of the laminated body (see FIG. 6) into which the ions have been implanted is generated by photolithography. Next, etching is performed by, for example, wet etching or dry etching using this resist pattern as a mask until the surface of at least the n-type semiconductor layer 101-1 is exposed (until the side surface of at least the active layer 102-1 is completely exposed) to form the mesa M whose diameter is, for example, 5 to 100 μm. Then, the resist pattern is removed.

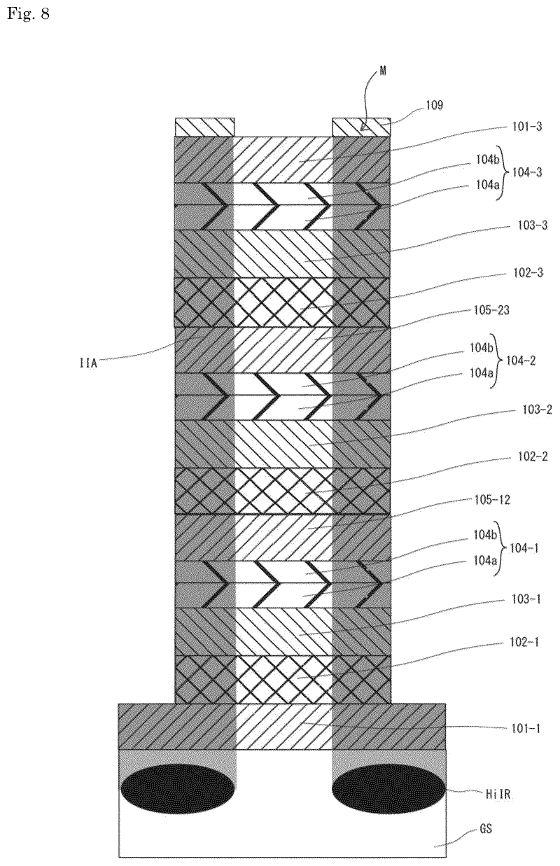

In next step S6, the anode electrode 109 is formed (see FIG. 8). More specifically, the anode electrode 109 of the circular shape (e.g., ring shape) is formed on the peripheral part of the top part of the mesa M by, for example, a lift-off method.

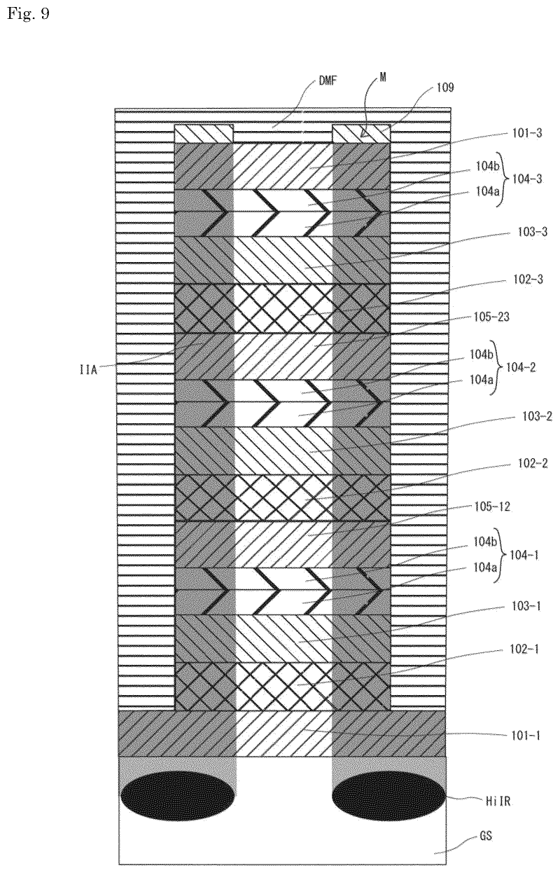

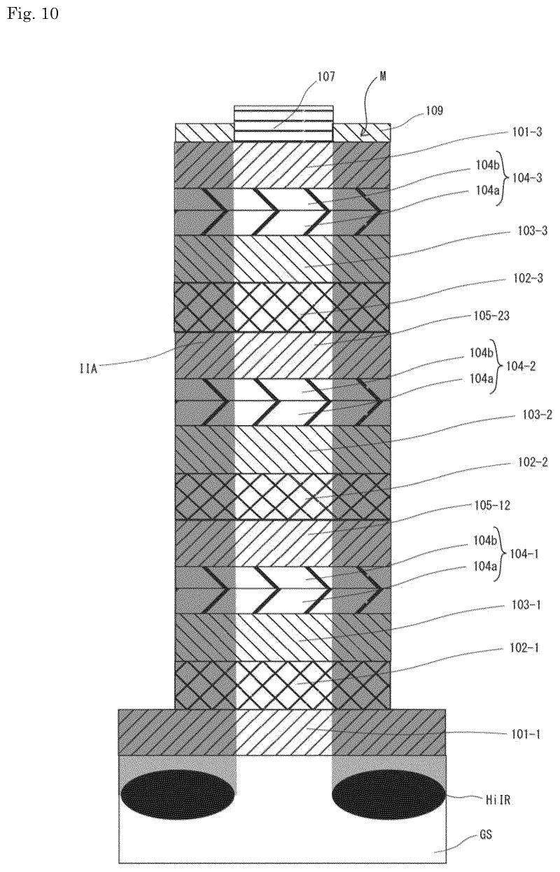

In next step S7, the second reflection mirror 107 is formed. More specifically, first, a dielectric multilayer film DMF that is a material of the second reflection mirror 107 is formed on the entire surface (see FIG. 9). Next, a dielectric multilayer film other than a dielectric multilayer film on the center region of the top part of the mesa M is removed by, for example, dry etching (see FIG. 10). As a result, a dielectric multilayer film reflection mirror that is the second reflection mirror 107 surrounded by the anode electrode 109 is formed.

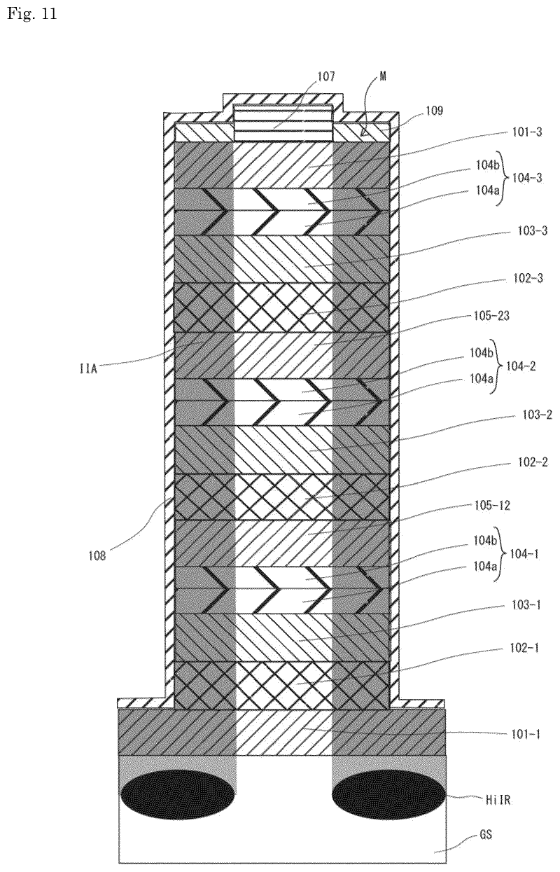

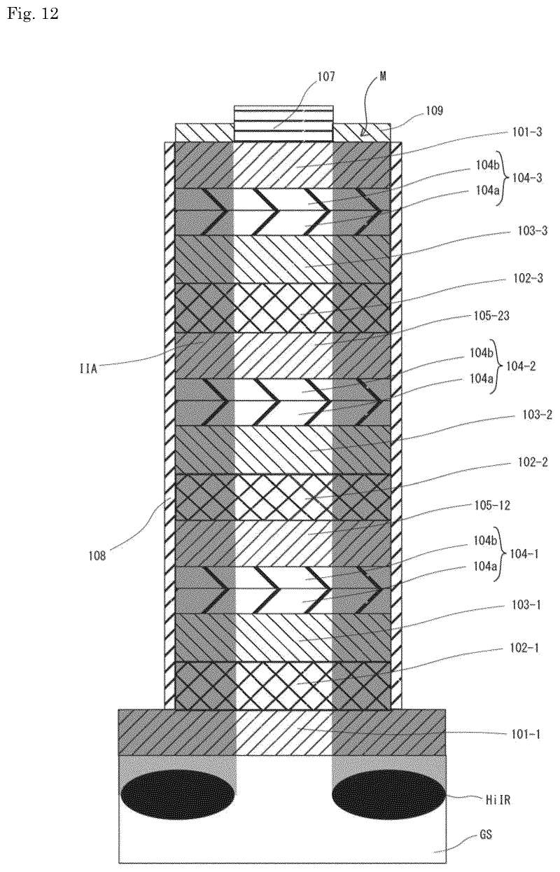

In next step S8, the insulating film 108 is formed. More specifically, first, the insulating film 108 is formed on the entire surface (see FIG. 11). Next, the insulating film 108 that covers the anode electrode 109 and the second reflection mirror 107, and the insulating film 108 that covers the region (n-type semiconductor layer 101-1) around the bottom part of the mesa M are removed by, for example, dry etching (see FIG. 12). As a result, the anode electrode 109, the second reflection mirror 107, and the region around the mesa M are exposed, and only the insulating film 108 formed on the side surface of the mesa M is left.

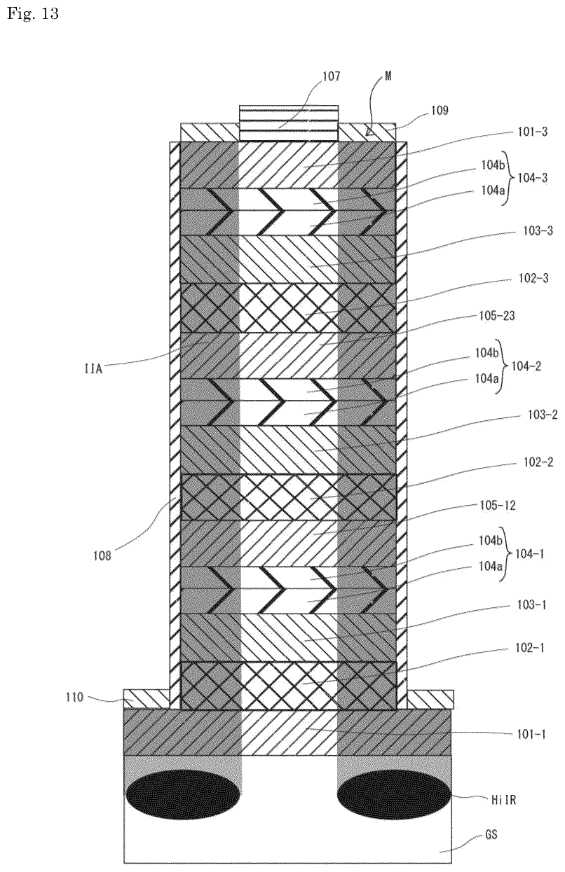

In next step S9, the cathode electrode 110 is formed (see FIG. 13). More specifically, the cathode electrode 110 of the circular shape (e.g., ring shape) is formed so as to surround the bottom part of the mesa M with the insulating film 108 interposed therebetween by, for example, the lift-off method.

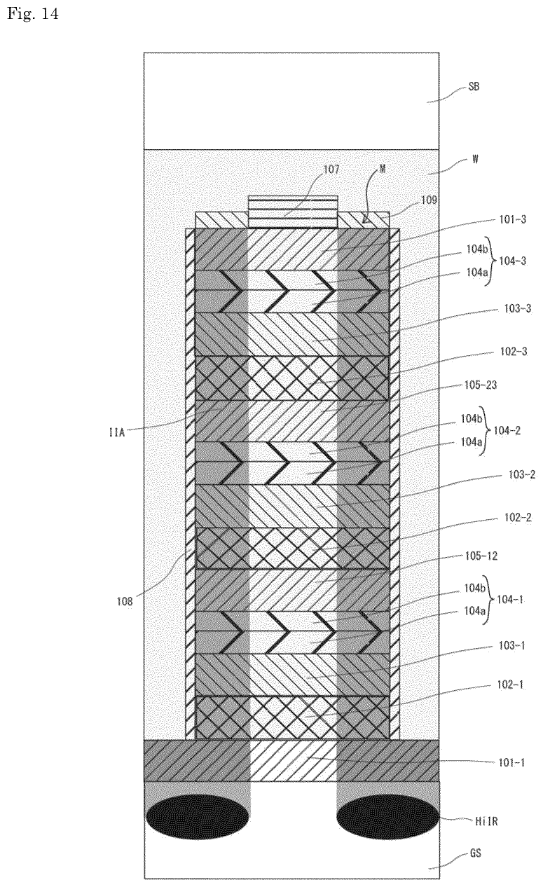

In next step S10, a support base SB is pasted (see FIG. 14). More specifically, the support base SB is pasted on a mesa M side with a wax W interposed therebetween.

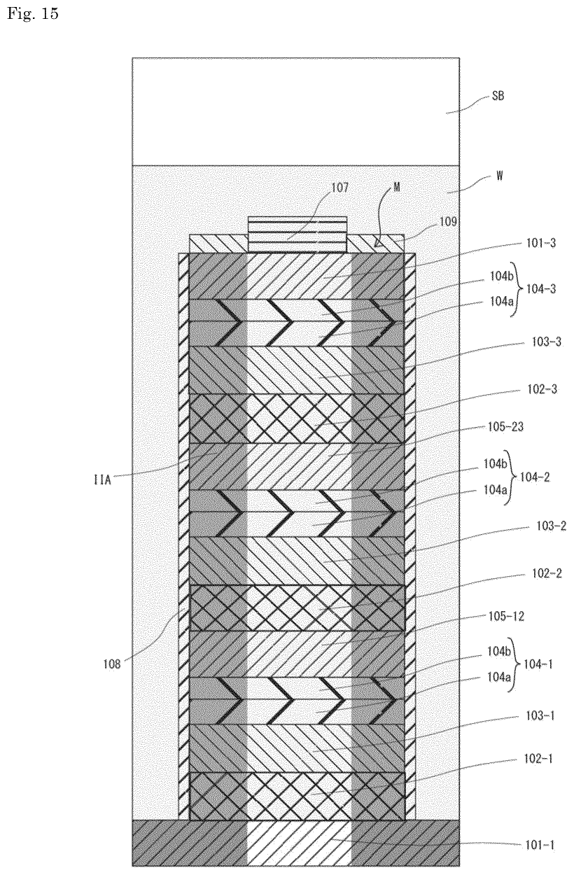

In next step S11, the growth substrate GS is removed (see FIG. 15). More specifically, first, the back surface of the growth substrate GS is polished and thinned using a back grinder. Next, the growth substrate GS is removed by wet etching using, for example, a mixed solution of hydrochloric acid and phosphoric acid. As a result, the n-type semiconductor layer 101-1 is exposed. The high concentration ion region HiIR is also removed as the growth substrate GS is removed. Here, in step S1, by disposing an etching stop layer (e.g., InGaAsP layer) between the growth substrate GS and the n-type semiconductor layer 101-1, it is possible to stop the wet etching in the etching stop layer. It is possible to remove the etching stop layer using a mixed solution of sulfuric acid, hydrogen peroxide, and water.

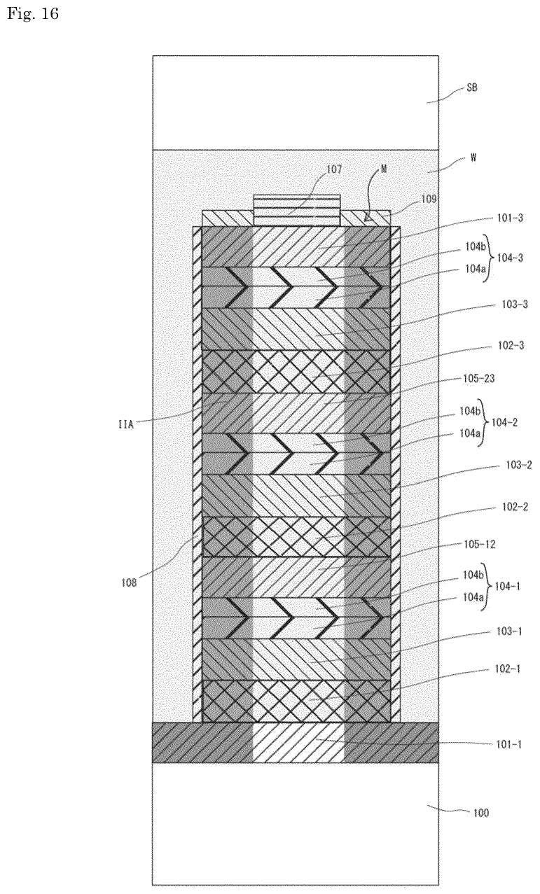

In next step S12, the substrate 100 is pasted (see FIG. 16). More specifically, the n-type semiconductor layer 101-1 and the substrate 100 are bonded. At this time, for example, plasma processing is performed on a bonding surface of the n-type semiconductor layer 101-1 with respect to the substrate 100 and a bonding surface of the substrate 100 with respect to the n-type semiconductor layer 101-1, the bonding surfaces are cleaned, and then both of the bonding surfaces are pasted to bond the n-type semiconductor layer 101-1 and the substrate 100.

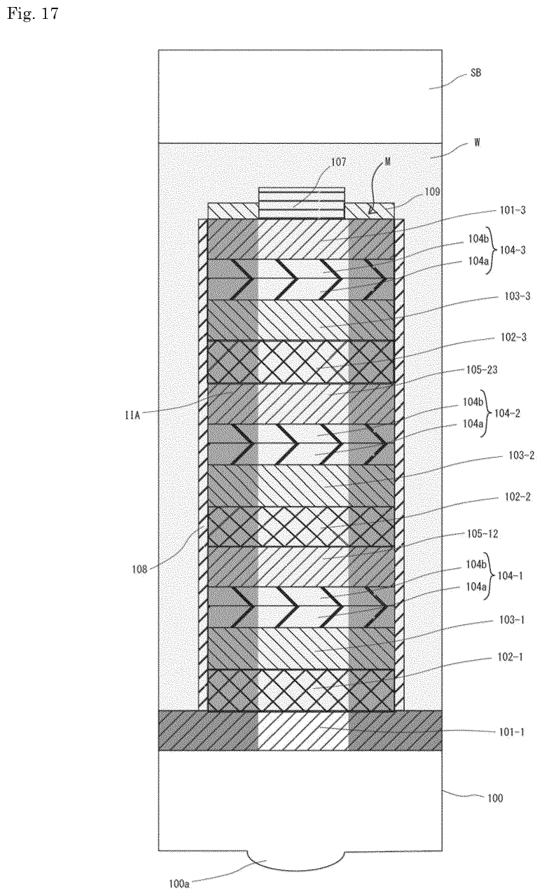

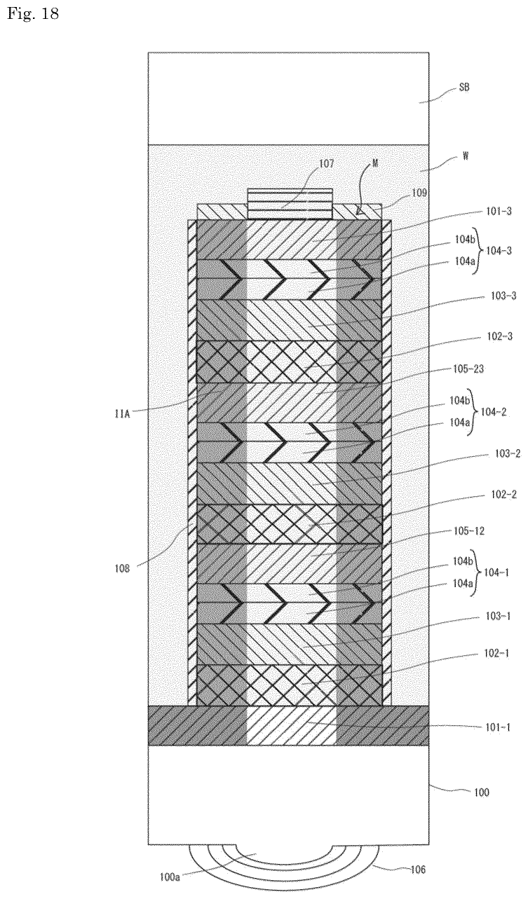

In next step S13, the first reflection mirror 106 is formed. More specifically, first, a resist is applied to the back surface (lower surface) of the substrate 100, and the substrate 100 is subjected to dry etching using as a mask a hemispherical resist obtained by heating (reflowing) the resist into a hemispherical shape to form the convex structure 100a (see FIG. 17). Next, the dielectric multilayer film is formed on the back surface of the substrate 100 on which the convex structure 100a has been formed to form a dielectric multilayer film reflection mirror that is the first reflection mirror 106 (see FIG. 18).

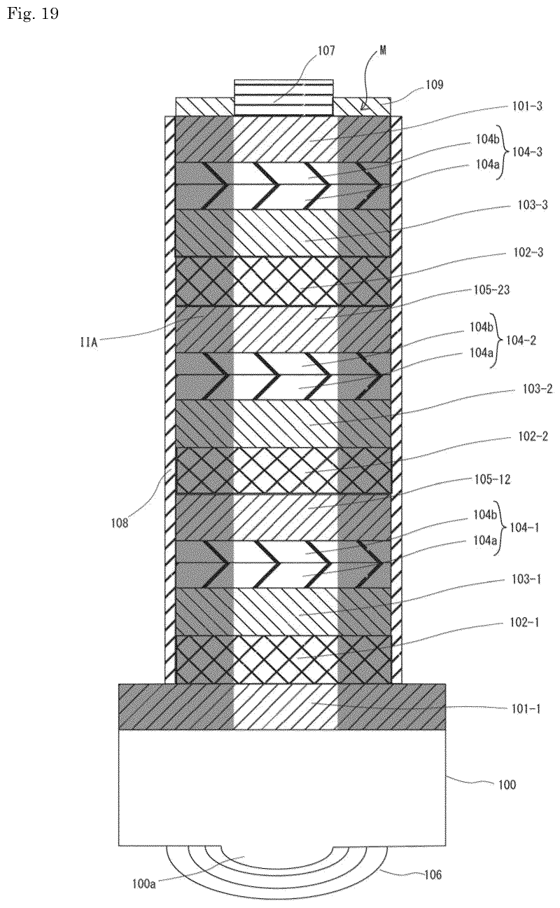

In next step S14, the support base SB is removed (see FIG. 19). More specifically, the wax W is heated at, for example, 200 to 300° C. and softened to remove the support base SB. After the support base SB is removed, the remaining wax W is removed by an usher.

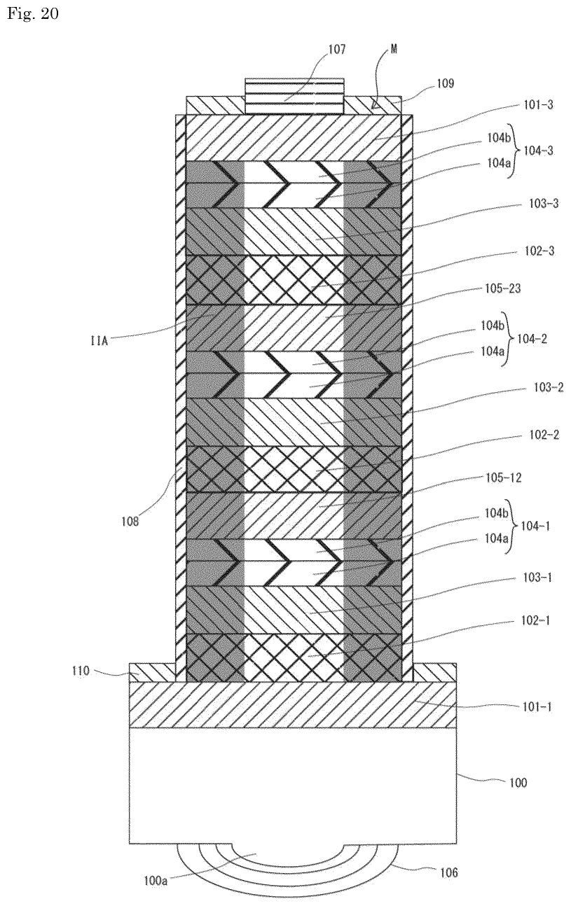

In last step S15, annealing treatment is performed (see FIG. 20). More specifically, the annealing treatment is performed at 350 to 600° C. Thus, the peripheral parts of the n-type semiconductor layers 101-1 and 101-3 that are n-InP layers that have been damaged by ion implantation (that has caused crystal defects) have reduced resistance and are repaired. On the other hand, the peripheral parts of the active layers 102-1, 102-2, and 102-3, the p-type semiconductor layers 103-1, 103-2, and 103-3, the tunnel junction layers 104-1, 104-2, and 104-3, and the n-type semiconductor layers 105-12 and 105-23 of the n-AlGaInAs layers that have been damaged by ion implantation keep increased resistance, and are not repaired. Note that the article (J. Appl. Phys. Vol . . . 89, No. 10, 15 (2001)) has reported that n-InP having increased resistance is repaired by annealing treatment, and p-InP having increased resistance is not repaired by annealing treatment. Furthermore, the article has reported that n-GaAs having increased resistance is repaired by annealing treatment, and p-GaAs having increased resistance is not repaired by annealing treatment. The annealing treatment described herein can also function as a sinter of each electrode.

### <<Effect of Surface Emitting Laser and Manufacturing Method for Surface Emitting Laser>>

The surface emitting laser 10-1 according to example 1 of the embodiment of the present technology includes the first and second reflection mirrors 106 and 107 that are mutually laminated, and the middle part MP that is disposed between the first and second reflection mirrors 106 and 107, the middle part MP has the laminated structure LS formed by laminating a plurality of the semiconductor structures SS each including each of the mutually laminated active layer 102 and tunnel junction layer 104 as an intermediate layer, and the peripheral part of at least the tunnel junction layer 104 of the at least one semiconductor structures SS (e.g., all semiconductor structures SS) has higher resistance than that of the center part.

In this case, it is possible to constrict the current without forming the tunnel junction layer 104 of the at least one semiconductor structure SS (e.g., all semiconductor structures SS) as a burial type. That is, it is possible to provide a current constriction function to the tunnel junction layer 104 without etching and performing subsequent burial regrowth on the tunnel junction layer 104.

As a result, according to the surface emitting laser 10-1, it is possible to provide a surface emitting laser that can achieve a high output while suppressing an increase in manufacturing cost, and includes a current constriction region.

The top layer on the second reflection mirror 107 side of the laminated structure LS has lower resistance than that of the peripheral part of the tunnel junction layer 104. Consequently, when, for example, the anode electrode 109 is installed on a peripheral region of the top layer, it is possible to form a current path of low resistance in the top layer in an in-plane direction in particular, and eventually achieve high efficiency.

The top layer on the second reflection mirror 107 side of the laminated structure LS is the n-type semiconductor layer 101-3. The top layer is preferably formed of, for example, an n-InP layer. Consequently, even when the resistance of the top layer is increased by ion implantation, the top layer can be repaired (the resistance is reduced) by annealing.

The top layer on the first reflection mirror 106 side of the laminated structure LS has lower resistance than that of the peripheral part of the tunnel junction layer 104. Consequently, when, for example, the cathode electrode 110 is installed on a peripheral region of the top layer, it is possible to form a current path of low resistance in the top layer in an in-plane direction in particular, and eventually achieve high efficiency.

The top layer on the first reflection mirror 106 side of the laminated structure LS is the n-type semiconductor layer 101-1. The top layer is preferably formed of, for example, an n-InP layer. Consequently, even when the resistance of the top layer is increased by ion implantation, the top layer can be repaired (the resistance is reduced) by annealing.

Each semiconductor structure SS preferably further includes the p-type semiconductor layer 103 that is disposed between the active layer 102 and the tunnel junction layer 104, the first n-type semiconductor layer that is disposed on an opposite side to a p-type semiconductor layer 103 side of the active layer 102, and the second n-type semiconductor layer that is disposed on an opposite side to the p-type semiconductor layer 103 side of the tunnel junction layer 104. Consequently, it is possible to cause the current to flow to each active layer 102, and lower an operating voltage.

The peripheral part of the p-type semiconductor layer 103 of each semiconductor structure SS has higher resistance than that of the center part. Consequently, it is possible to provide the current constriction function to the p-type semiconductor layer 103, too.

Each semiconductor structure SS is disposed such that the first n-type semiconductor layer is located on the first reflection mirror 106 side, and the second n-type semiconductor layer is disposed on the second reflection mirror 107 side, and the n-type semiconductor layer 101-3 that is the second n-type semiconductor layer of the semiconductor structure SS3 closest to the second reflection mirror 107, and the n-type semiconductor layer 101-1 that is the first n-type semiconductor layer of the semiconductor structure SS1 closest to the first reflection mirror 106 have lower resistance than that of the peripheral part of the p-type semiconductor layer 103. Consequently, it is possible to form a current path of low resistance in the top layer on the first reflection mirror 106 side and the top layer on the second reflection mirror 107 side of the laminated structure LS in the in-plane direction, and eventually achieve remarkably high efficiency.

The peripheral parts of all layers other than the n-type semiconductor layer 101-3 that is the second n-type semiconductor layer of the semiconductor structure SS3 closest to the second reflection mirror 107, and the n-type semiconductor layer 101-1 that is the first n-type semiconductor layer of the semiconductor structure SS1 closest to the first reflection mirror 106 have higher resistance than that of the center part in the laminated structure LS. Consequently, it is possible to provide the current constriction function to these all layers.

Furthermore, according to the surface emitting laser 10-1, it is possible to provide a surface emitting laser that can constrict the current in at least the tunnel junction layer 104 without performing epitaxial growth a plurality of times. Consequently, it is possible to reduce a manufacturing time and manufacturing cost.

The manufacturing method for the surface emitting laser 10-1 includes a process of generating the laminated body formed by laminating the plurality of semiconductor structures SS each including each of the active layer 102 and the tunnel junction layer 104 on the growth substrate GS; and a process of injecting ions into the laminated body, and making the resistance of the peripheral part of at least the tunnel junction layer 104 higher than the resistance of the center part.

Consequently, it is possible to manufacture the surface emitting laser that can achieve a high output while suppressing an increase in manufacturing cost, and includes the current constriction region.

The top surface on one side and/or the top surface on an other side in a lamination direction of the laminated body are n-type semiconductor layers (e.g., n-InP layers), in the process of making the resistance higher, the peripheral parts of the n-type semiconductor layers have higher resistance than that of the center part, and the manufacturing method for the surface emitting laser 10-1 further includes a process of performing annealing treatment on the laminated body after the process of making the resistance higher, and making the resistance of the peripheral parts of the n-type semiconductor layers lower. Consequently, it is possible to manufacture the surface emitting laser 10-1 that includes the current constriction region in which the top layers on the one side and the other side in the lamination direction of the laminated body can be effectively used as contact regions with respect to electrodes.

The manufacturing method further includes a process of making the ion reach an inside of the growth substrate GS at the time of ion implantation, and pasting the support base SB on a surface on an opposite side to a growth substrate GS side of the laminated body after the process of making the resistance higher, and a process of removing the growth substrate GS from the laminated body. Consequently, it is possible to remove from components of the surface emitting laser 10-1 a part that is highly likely to induce change in characteristics of elements (e.g., decrease in reliability) and in which the ion concentration comes to a peak, so that it is possible to manufacture the surface emitting laser 10-1 that can suppress the change in characteristics of each constituent layer.

The manufacturing method for the surface emitting laser 10-1 preferably includes a process of laminating the first reflection mirror 106 and the substrate 100 on the surface of the laminated body from which the growth substrate GS has been removed.

### 2. Surface Emitting Laser According to Example 2 of Embodiment of Present Technology

### <<Configuration of Surface Emitting Laser>>

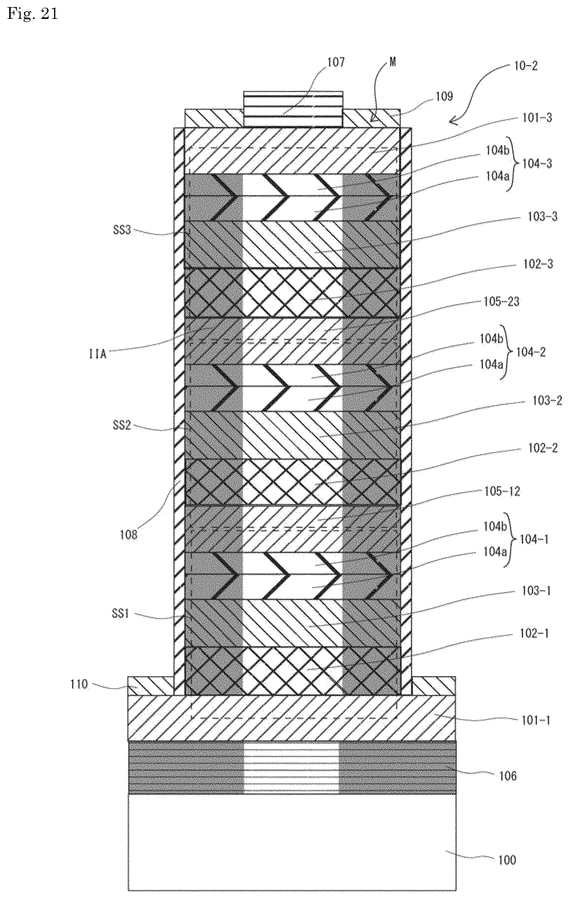

FIG. 21 is a cross-sectional view of a surface emitting laser 10-2 according to example 2 of the embodiment of the present technology. The surface emitting laser 10-2 employs the same configuration as that of the surface emitting laser 10-1 according to example 1 except that the first reflection mirror 106 is a semiconductor multilayer film reflection mirror disposed between the n-type semiconductor layer 101-1 and the substrate 100.

For example, in the surface emitting laser 10-2, the first reflection mirror 106 is made of a material (e.g., a pair such as InP/AlGaInAs or AlInAs/AlGaInAs) that lattice-matches with InP. For example, in the surface emitting laser 10-2, the first reflection mirror 106 is a plane mirror. In the surface emitting laser 10-2, the peripheral part of the first reflection mirror 106 is the ion implantation region IIA, and the peripheral part has the higher resistance than that of the center part.

### <<Operation of Surface Emitting Laser>>

The surface emitting laser 10-2 performs the same operation as that of the surface emitting laser 10-1 according to example 1.

### <<Example of Manufacturing Method for Surface Emitting Laser>>

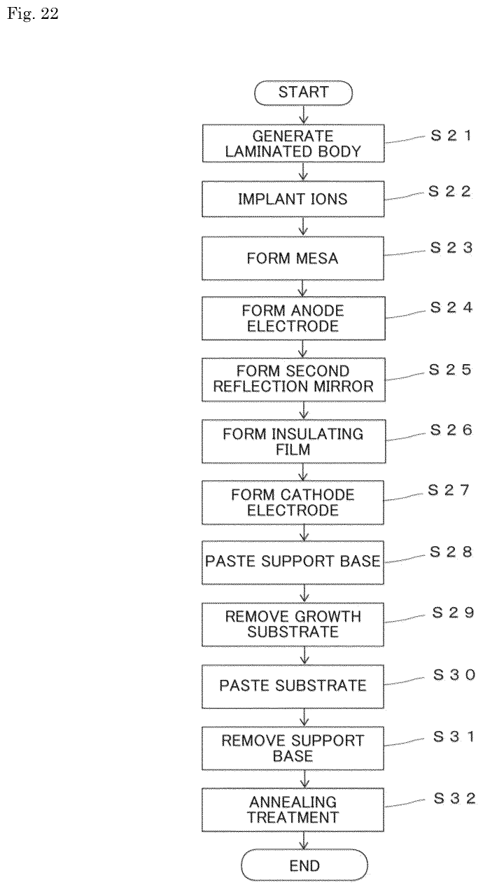

Hereinafter, an example of the manufacturing method for the surface emitting laser 10-2 will be described with reference to the flowchart in FIG. 22. Here, for example, the semiconductor manufacturing method that uses the semiconductor manufacturing device simultaneously generates a plurality of the surface emitting lasers 10-2 on one wafer that is a base material of the substrate 100, separates the plurality of series of integrated surface emitting lasers 10-2 from each other, and obtains chip-shaped surface emitting lasers (surface emitting laser chips). Note that the semiconductor manufacturing method can also simultaneously generate a plurality of surface emitting laser arrays formed by two-dimensionally disposing the plurality of surface emitting lasers 10-2 on the one wafer that is the base material of the substrate 100, separate the plurality of series of integrated surface emitting laser arrays from each other, and obtain a plurality of chip-shaped surface emitting laser arrays (surface emitting laser array chips).

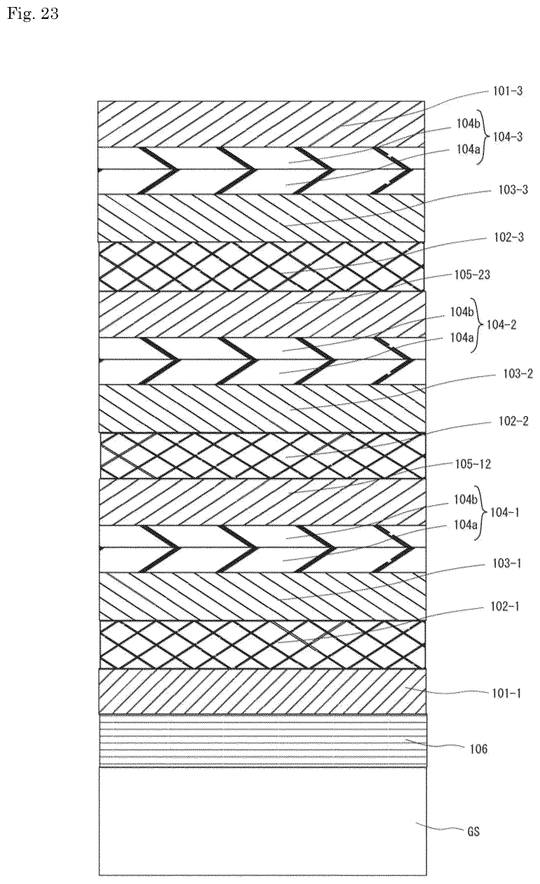

In first step S21, a laminated body is generated (see FIG. 23). More specifically, for example, the semiconductor multilayer film reflection mirror that is the first reflection mirror 106, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are laminated (epitaxially grown) on the growth substrate GS (e.g., InP substrate) in the growth chamber in this order by the Metal Organic Chemical Vapor Deposition method (MOCVD method) or the Molecular Beam Epitaxy method (MBE method). That is, the laminated body is generated by performing epitaxial growth once.

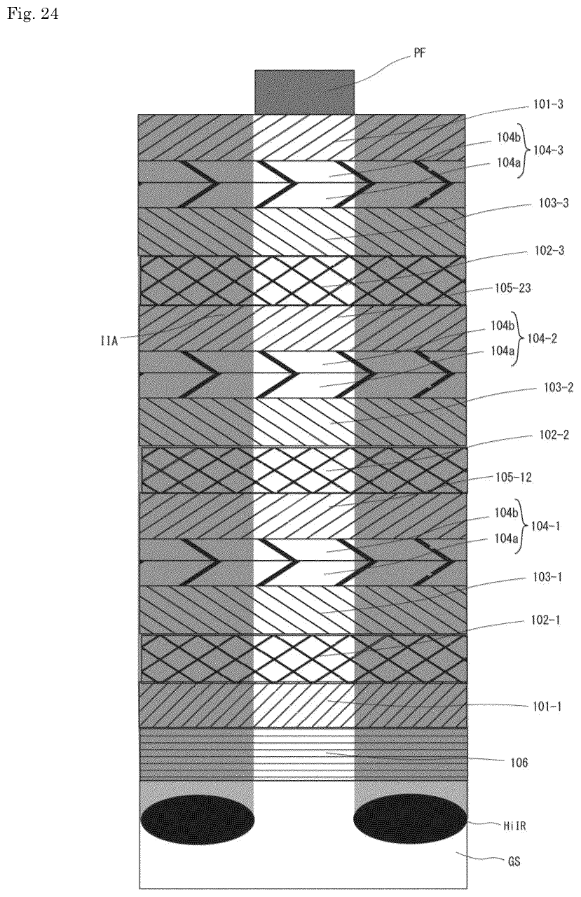

In next step S22, ion implantation is performed (see FIG. 24). More specifically, first, a center region of the laminated body for which ion implantation to be described later is not performed is protected by the protection film PF made of SiO₂. Next, ions are implanted into the peripheral region (the region on which the protection film PF is not formed) of the laminated body from the n-type semiconductor layer 101-3 side. At this time, for example, the protons (H+) are used as ion species, ion implantation energy is set such that the protons reach (preferably concentrates) in the growth substrate GS, and the dose is set to, for example, 1×10¹⁴ ion/cm² or more. As a result, ion implantation causes crystal defects, and a region in which the ions have been implanted has increased resistance. That is, the peripheral parts of the growth substrate GS, the semiconductor multilayer film reflection mirror that is the first reflection mirror 106, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 have increased resistance. As a result, the high concentration ion region HiIR (parts that are painted black in FIG. 24) including regions in which an ion concentration comes to a peak is formed in the growth substrate GS. Then, the protection film PF is removed.

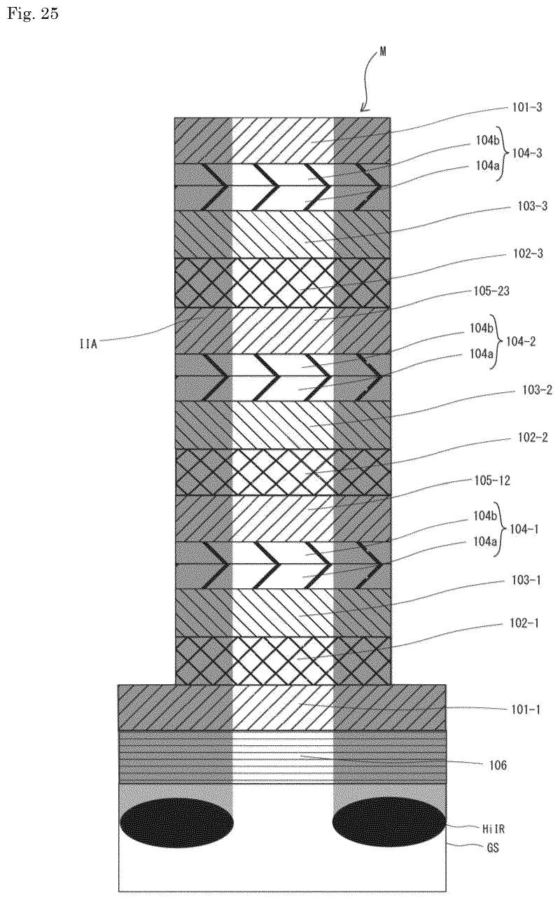

In next step S23, the mesa M is formed (see FIG. 25). More specifically, for example, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are etched to form the mesa M. More specifically, the resist pattern for forming the mesa M on the n-type semiconductor layer 101-3 of the laminated body (see FIG. 24) in which the ions have been implanted is generated by photolithography. Next, etching is performed by, for example, wet etching or dry etching using this resist pattern as a mask until the surface of at least the n-type semiconductor layer 101-1 is exposed (until the side surface of at least the active layer 102-1 is completely exposed) to form the mesa M whose diameter is, for example, 5 to 100 μm. Then, the resist pattern is removed.

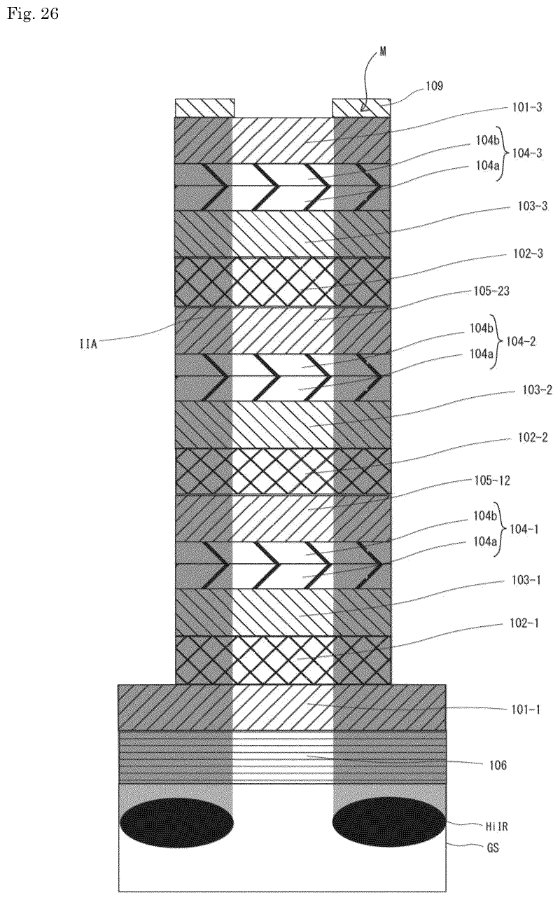

In next step S24, the anode electrode 109 is formed (see FIG. 26). More specifically, the anode electrode 109 of the circular shape (e.g., ring shape) is formed on the peripheral part of the top part of the mesa M by, for example, the lift-off method.

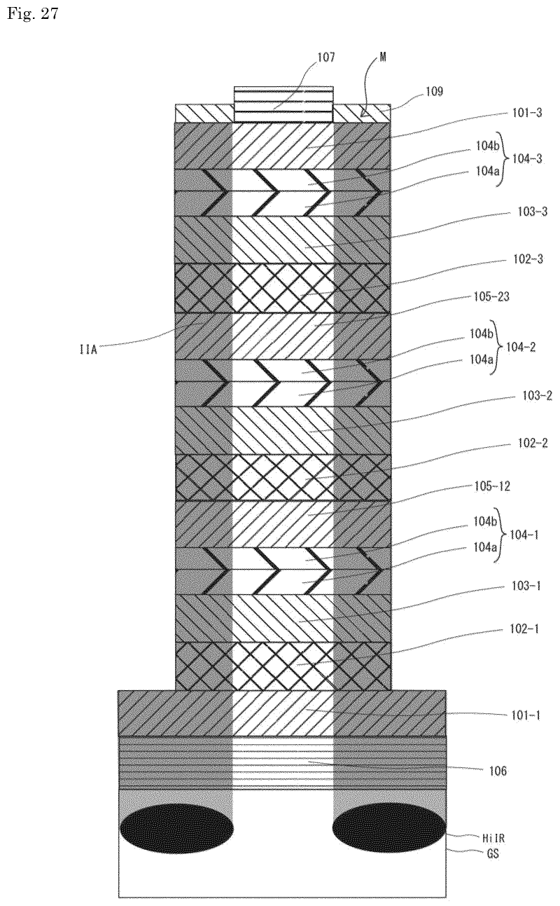

In the next step S25, the second reflection mirror 107 is formed (see FIG. 27). More specifically, first, the dielectric multilayer film that is the material of the second reflection mirror 107 is formed on the entire surface. Next, the dielectric multilayer film other than the dielectric multilayer film on the center region of the top part of the mesa M is removed by, for example, dry etching. As a result, the dielectric multilayer film reflection mirror that is the second reflection mirror 107 surrounded by the anode electrode 109 is formed.

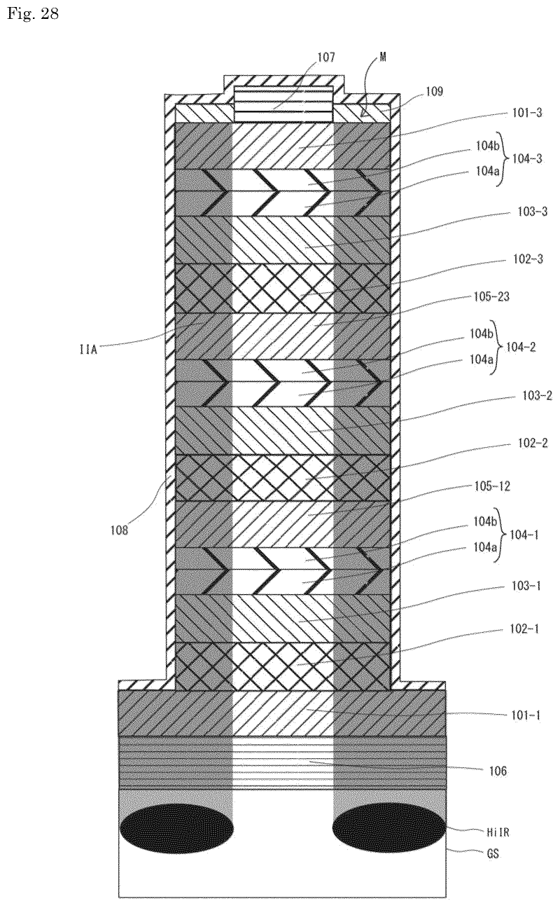

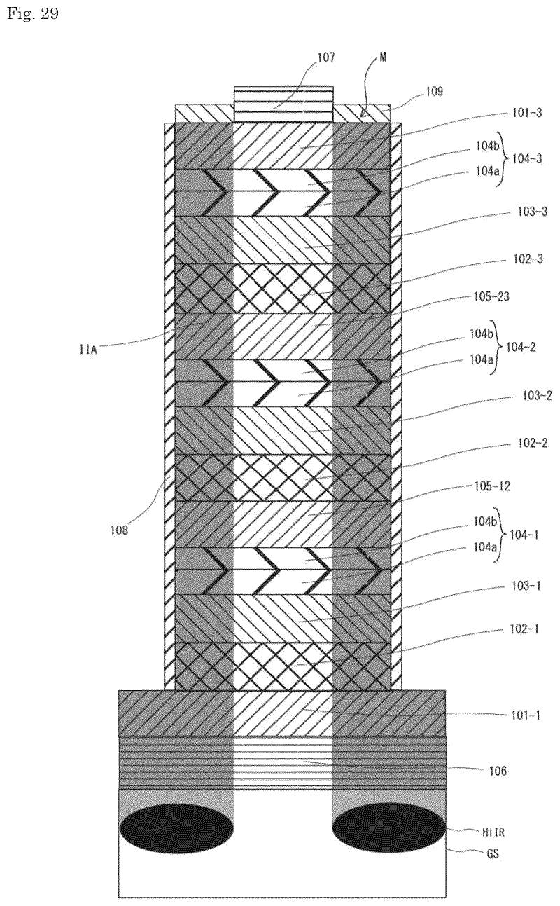

In next step S26, the insulating film 108 is formed. More specifically, first, the insulating film 108 is formed on the entire surface (see FIG. 28). Next, the insulating film 108 that covers the anode electrode 109 and the second reflection mirror 107, and the insulating film 108 that covers the region (n-type semiconductor layer 101-1) around the bottom part of the mesa M are removed by, for example, dry etching (see FIG. 29). As a result, the anode electrode 109, the second reflection mirror 107, and the region round the mesa M are exposed, and only the insulating film 108 formed on the side surface of the mesa M is left.

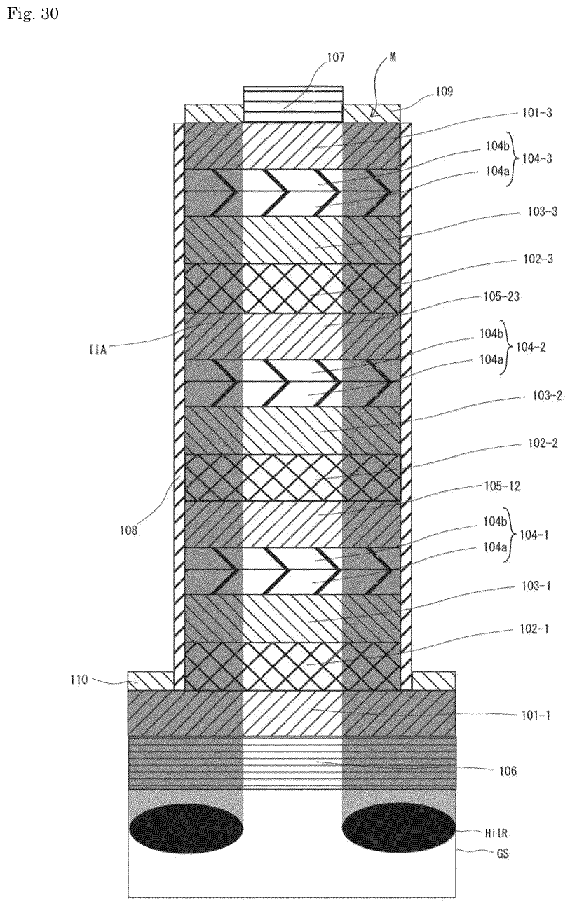

In next step S27, the cathode electrode 110 is formed (see FIG. 30). More specifically, the cathode electrode 110 of the circular shape (e.g., ring shape) is formed so as to surround the bottom part of the mesa M with the insulating film 108 interposed therebetween by, for example, the lift-off method.

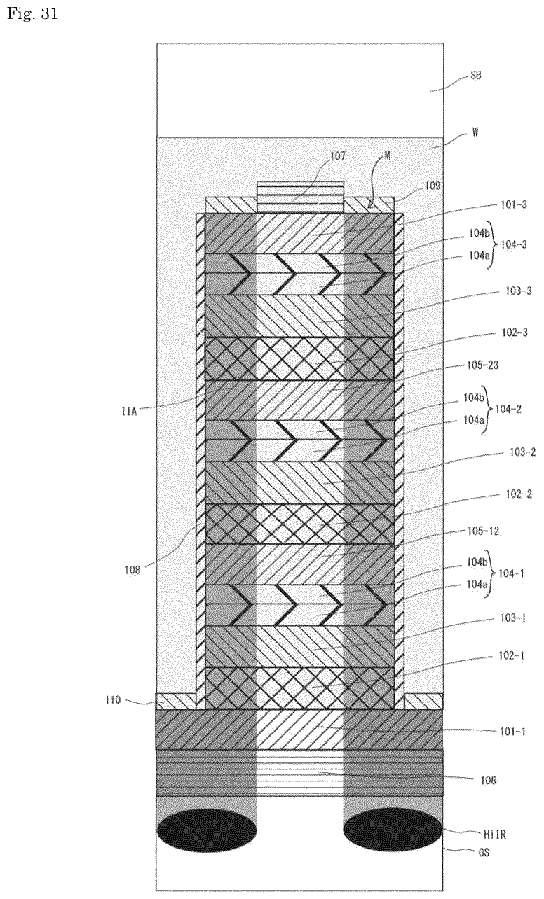

In next step S28, the support base SB is pasted (see FIG. 31). More specifically, the support base SB is pasted on the mesa M side with the wax W interposed therebetween.

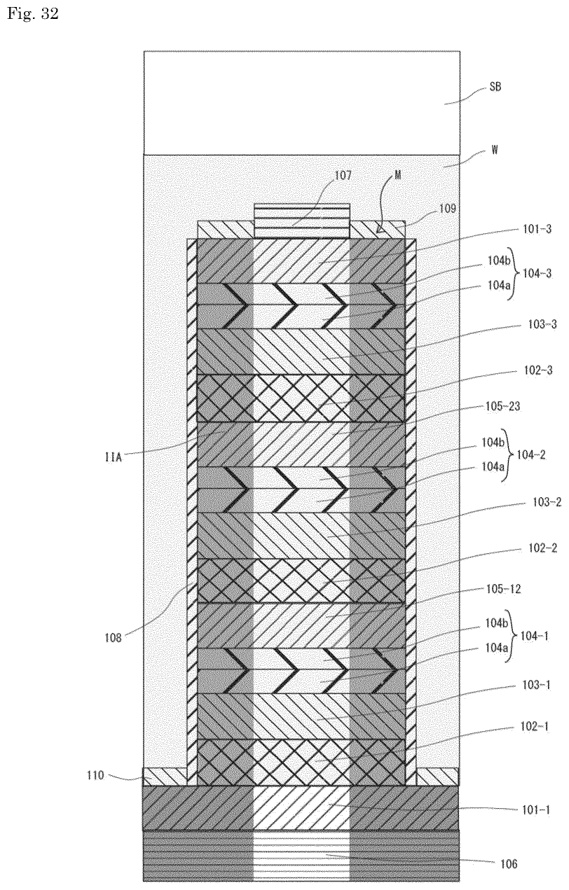

In next step S29, the growth substrate GS is removed (see FIG. 32). More specifically, first, the back surface of the growth substrate GS is polished and thinned using the back grinder. Next, the growth substrate GS is removed by wet etching using, for example, the mixed solution of hydrochloric acid and phosphoric acid. As a result, the first reflection mirror 106 is exposed. The high concentration ion region HiIR is also removed as the growth substrate GS is removed. Here, in step S21, by disposing the etching stop layer (e.g., InGaAsP layer) between the growth substrate GS and the first reflection mirror 106, it is possible to stop the wet etching in the etching stop layer. It is possible to remove the etching stop layer using the mixed solution of sulfuric acid, hydrogen peroxide, and water.

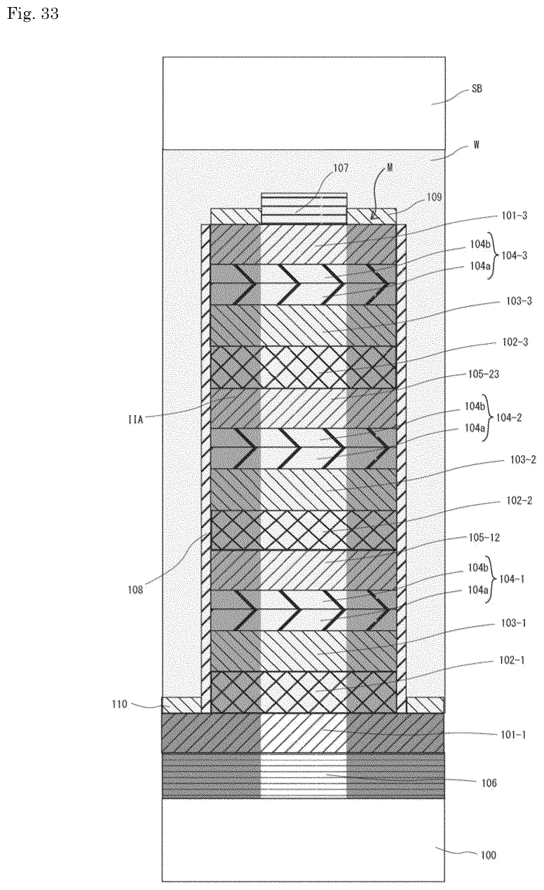

In next step S30, the substrate 100 is pasted (see FIG. 33). More specifically, the first reflection mirror 106 and the substrate 100 are bonded. At this time, for example, plasma processing is performed on a bonding surface of the first reflection mirror 106 with respect to the substrate 100 and the bonding surface of the substrate 100 with respect to the first reflection mirror 106, the bonding surfaces are cleaned, and then both of the bonding surfaces are pasted to bond the first reflection mirror 106 and the substrate 100.

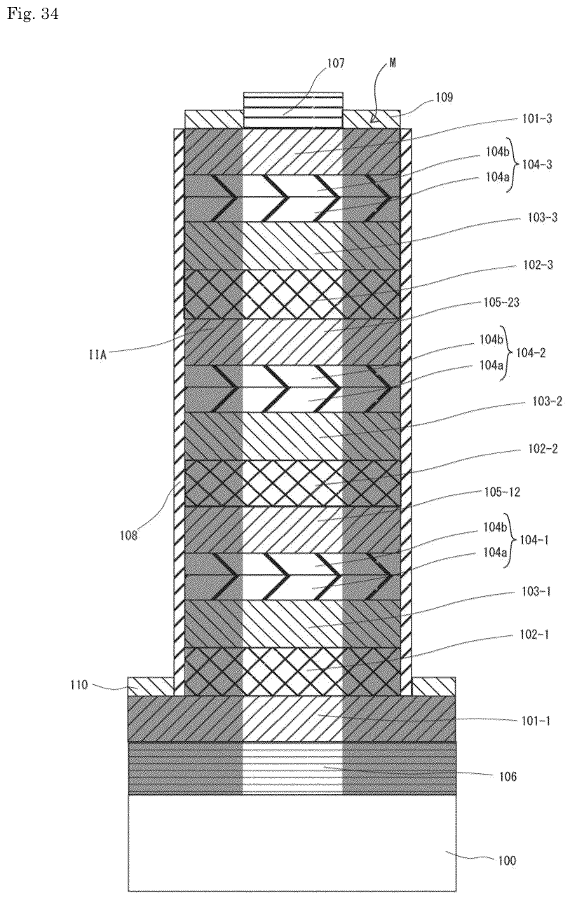

In next step S31, the support base SB is removed (see FIG. 34). More specifically, the wax W is heated at, for example, 200 to 300° C. and softened to remove the support base SB. After the support base SB is removed, the remaining wax W is removed by the usher.

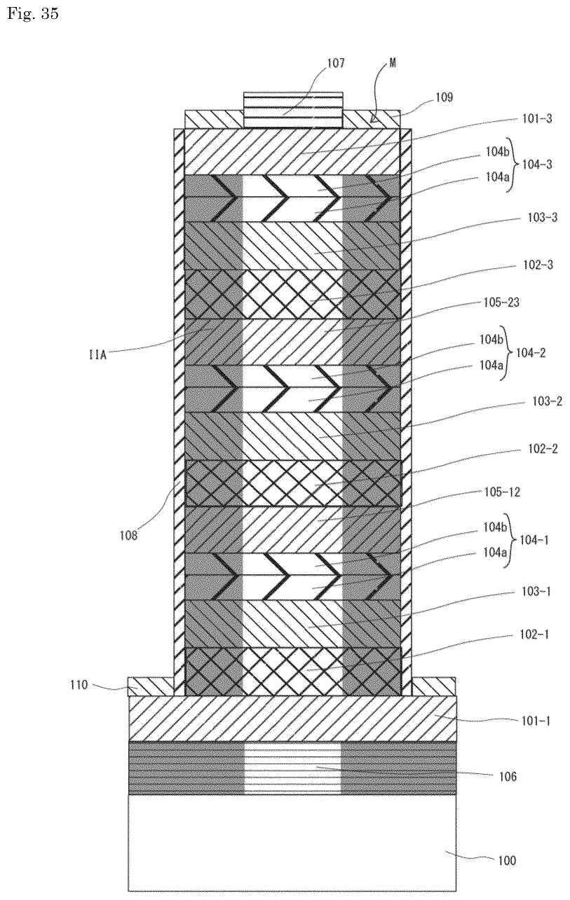

In last step S32, annealing treatment is performed (see FIG. 35). More specifically, the annealing treatment is performed at 350 to 600° C. Thus, the peripheral parts of n-InP layers that are the n-type semiconductor layers 101-1 and 101-3 that have been damaged by ion implantation (that has caused crystal defects) have reduced resistance and are repaired. On the other hand, the peripheral parts of the semiconductor multilayer film reflection mirror of the first reflection mirror 106, the active layers 102-1, 102-2, and 102-3, the p-type semiconductor layers 103-1, 103-2, and 103-3, the tunnel junction layers 104-1, 104-2, and 104-3, and the n-type semiconductor layers 105-12 and 105-23 of the n-AlGaInAs layers that have been damaged by ion implantation keep increased resistance, and are not repaired. The annealing treatment described herein can also function as the sinter of each electrode.

### <<Effect of Surface Emitting Laser and Manufacturing Method for Surface Emitting Laser>>

According to the surface emitting laser 10-2, the first reflection mirror 106 is a plane-type semiconductor multilayer film reflection mirror, so that it is possible to obtain the same effect as that of the surface emitting laser 10-1 except that it is not possible to obtain an effect unique to the concave-type dielectric multilayer film reflection mirror. According to the manufacturing method for the surface emitting laser 10-2, the first reflection mirror 106 is also epitaxially grown to generate the laminated body, so that it is possible to simplify a manufacturing process.

### 3. Surface Emitting Laser According to Example 3 of Embodiment of Present Technology

### <<Configuration of Surface Emitting Laser>>

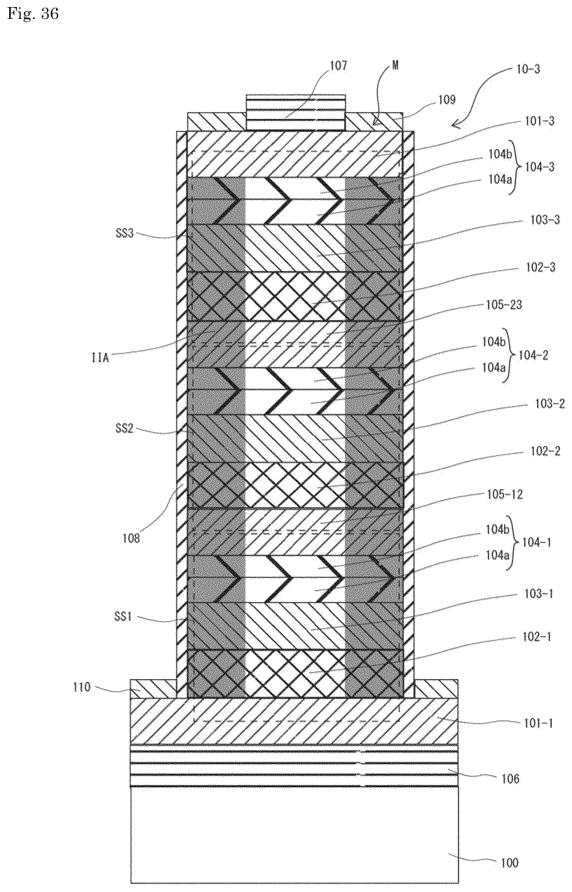

FIG. 36 is a cross-sectional view of a surface emitting laser 10-3 according to example 3 of the embodiment of the present technology. The surface emitting laser 10-3 employs the same configuration as that of the surface emitting laser 10-1 according to example 1 except that the dielectric multilayer film reflection mirror that is the first reflection mirror 106 is disposed between the n-type semiconductor layer 101-1 and the substrate 100.

For example, in the surface emitting laser 10-3, the first reflection mirror 106 is a plane mirror.

### <<Operation of Surface Emitting Laser>>

The surface emitting laser 10-3 performs the same operation as that of the surface emitting laser 10-1 according to example 1.

### <<Example of Manufacturing Method for Surface Emitting Laser>>

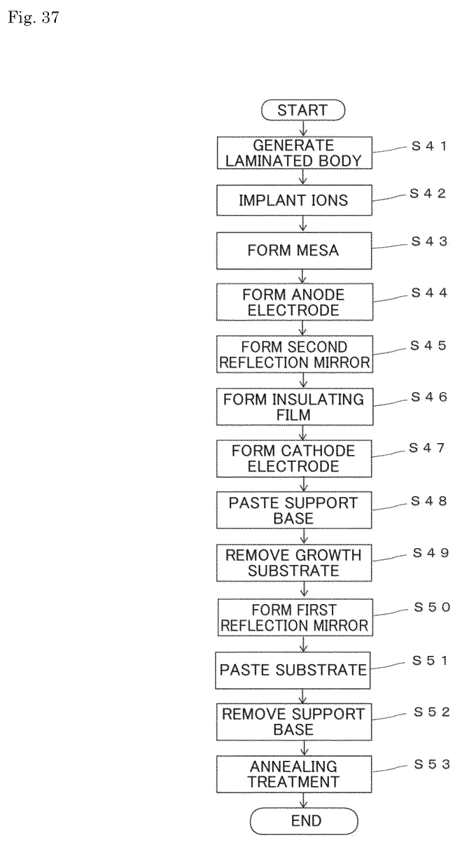

Hereinafter, an example of the manufacturing method for the surface emitting laser 10-3 will be described with reference to the flowchart in FIG. 37. Here, for example, the semiconductor manufacturing method that uses the semiconductor manufacturing device simultaneously generates a plurality of the surface emitting lasers 10-3 on one wafer that is the base material of the substrate 100, separates the plurality of series of integrated surface emitting lasers 10-3 from each other, and obtains chip-shaped surface emitting lasers (surface emitting laser chips). Note that the semiconductor manufacturing method can also simultaneously generate a plurality of surface emitting laser arrays formed by two-dimensionally disposing the plurality of surface emitting lasers 10-3 on the one wafer that is the base material of the substrate 100, separate the plurality of series of integrated surface emitting laser arrays from each other, and obtain a plurality of chip-shaped surface emitting laser arrays (surface emitting laser array chips).

In first step S41, a laminated body is generated (see FIG. 3). More specifically, for example, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are laminated (epitaxially grown) on the growth substrate GS (e.g., InP substrate) in the growth chamber in this order by the Metal Organic Chemical Vapor Deposition method (MOCVD method) or the Molecular Beam Epitaxy method (MBE method). That is, the laminated body is generated by performing epitaxial growth once.

In next step S42, ion implantation is performed (see FIG. 5). More specifically, first, a center region of the laminated body for which ion implantation to be described later is not performed is protected by the protection film PF made of SiO₂. Next, ions are implanted into the peripheral region (the region on which the protection film PF is not formed) of the laminated body from the n-type semiconductor layer 101-3 side. At this time, for example, the protons (H+) are used as ion species, ion implantation energy is set such that the protons reach (preferably concentrates) in the growth substrate GS, and the dose is set to, for example, 1×10¹⁴ ion/cm² or more. As a result, ion implantation causes crystal defects, and a region in which the ions have been implanted has increased resistance. That is, the peripheral parts of the growth substrate GS, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 have increased resistance. As a result, the high concentration ion region HiIR (parts that are painted black in FIG. 5) including regions in which an ion concentration comes to a peak is formed in the growth substrate GS. Then, the protection film PF is removed.

In next step S43, the mesa M is formed (see FIG. 7). More specifically, for example, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are etched to form the mesa M. More specifically, the resist pattern for forming the mesa M on the n-type semiconductor layer 101-3 of the laminated body (see FIG. 6) in which the ions have been implanted is generated by photolithography. Next, etching is performed by, for example, wet etching or dry etching using this resist pattern as a mask until the surface of at least the n-type semiconductor layer 101-1 is exposed (until the side surface of at least the active layer 102-1 is completely exposed) to form the mesa M whose diameter is, for example, 5 to 100 μm. Then, the resist pattern is removed.

In next step S44, the anode electrode 109 is formed (see FIG. 8). More specifically, the anode electrode 109 of the circular shape (e.g., ring shape) is formed on the peripheral part of the top part of the mesa M by, for example, the lift-off method.

In the next step S45, the second reflection mirror 107 is formed (see FIG. 10). More specifically, first, the dielectric multilayer film that is the material of the second reflection mirror 107 is formed on the entire surface. Next, the dielectric multilayer film other than the dielectric multilayer film on the center region of the top part of the mesa M is removed by, for example, dry etching. As a result, the dielectric multilayer film reflection mirror that is the second reflection mirror 107 surrounded by the anode electrode 109 is formed.

In next step S46, the insulating film 108 is formed (see FIG. 12). More specifically, first, the insulating film 108 is formed on the entire surface. Next, the insulating film 108 that covers the anode electrode 109 and the second reflection mirror 107, and the insulating film 108 that covers the region (n-type semiconductor layer 101-1) around the bottom part of the mesa M are removed by, for example, dry etching. As a result, the anode electrode 109, the second reflection mirror 107, and the region around the mesa M are exposed, and only the insulating film 108 formed on the side surface of the mesa M is left.

In next step S47, the cathode electrode 110 is formed (see FIG. 13). More specifically, the cathode electrode 110 of the circular shape (e.g., ring shape) is formed so as to surround the bottom part of the mesa M with the insulating film 108 interposed therebetween by, for example, the lift-off method.

In next step S48, the support base SB is pasted (see FIG. 14). More specifically, the support base SB is pasted on the mesa M side with the wax W interposed therebetween.

In next step S49, the growth substrate GS is removed (see FIG. 15). More specifically, first, the back surface of the growth substrate GS is polished and thinned using the back grinder. Next, the growth substrate GS is removed by wet etching using, for example, the mixed solution of hydrochloric acid and phosphoric acid. As a result, the n-type semiconductor layer 101-1 is exposed. The high concentration ion region HiIR is also removed as the growth substrate GS is removed. Here, in step S41, by disposing the etching stop layer (e.g., InGaAsP layer) between the growth substrate GS and the n-type semiconductor layer 101-1, it is possible to stop the wet etching in the etching stop layer. It is possible to remove the etching stop layer using the mixed solution of sulfuric acid, hydrogen peroxide, and water.

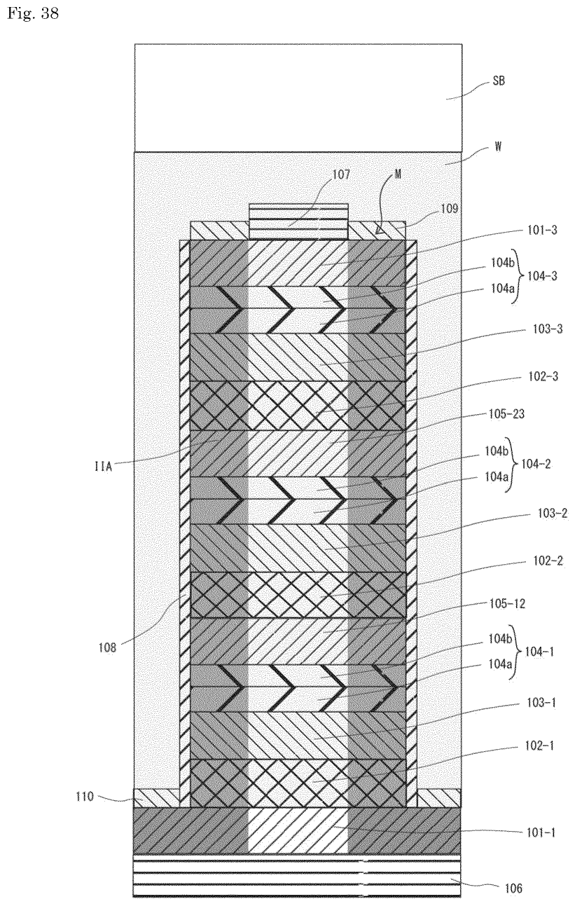

In the next step S50, the first reflection mirror 106 is formed (see FIG. 38). More specifically, the dielectric multilayer film that is the material of the dielectric multilayer film reflection mirror that is the first reflection mirror 106 is formed on the back surface (lower surface) of the n-type semiconductor layer 101-1.

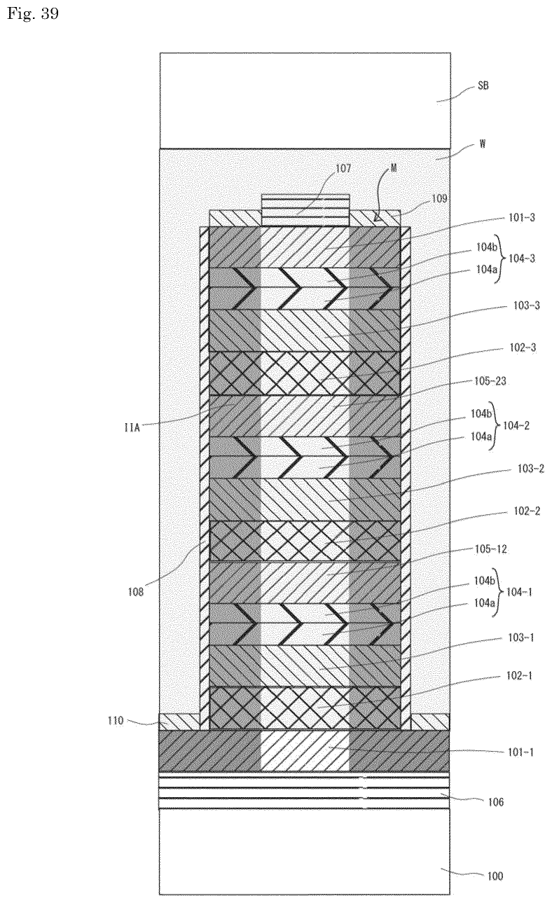

In next step S51, the substrate 100 is pasted (see FIG. 39). More specifically, the first reflection mirror 106 and the substrate 100 are bonded. At this time, for example, plasma processing is performed on the bonding surface of the first reflection mirror 106 with respect to the substrate 100 and the bonding surface of the substrate 100 with respect to the first reflection mirror 106, the bonding surfaces are cleaned, and then both of the bonding surfaces are pasted to bond the first reflection mirror 106 and the substrate 100.

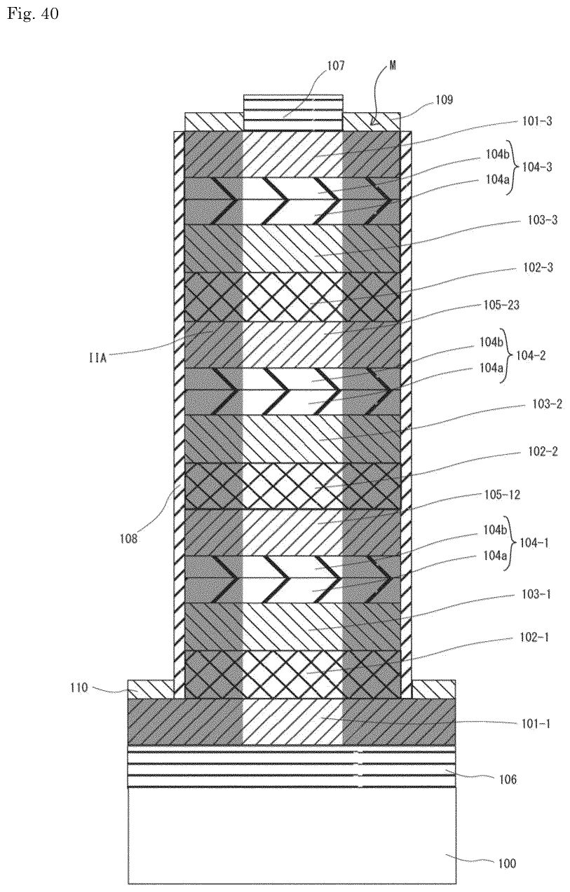

In next step S52, the support base SB is removed (see FIG. 40). More specifically, the wax W is heated at, for example, 200 to 300° C. and softened to remove the support base SB. After the support base SB is removed, the remaining wax W is removed by an usher.

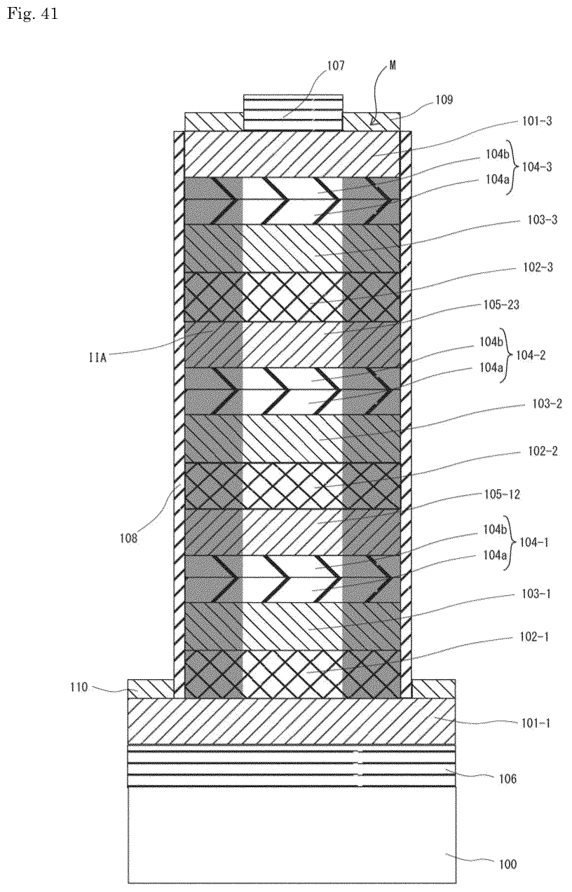

In last step S53, annealing treatment is performed (see FIG. 41). More specifically, the annealing treatment is performed at 350 to 600° C. Thus, the peripheral parts of the n-InP layers that are the n-type semiconductor layers 101-1 and 101-3 that have been damaged by ion implantation (that has caused crystal defects) have reduced resistance and are repaired. On the other hand, the peripheral parts of the active layers 102-1, 102-2, and 102-3, the p-type semiconductor layers 103-1, 103-2, and 103-3, the tunnel junction layers 104-1, 104-2, and 104-3, and the n-type semiconductor layers 105-12 and 105-23 of the n-AlGaInAs layers that have been damaged by ion implantation keep increased resistance, and are not repaired. The annealing treatment described herein can also function as the sinter of each electrode.

### <<Effect of Surface Emitting Laser and Manufacturing Method for Surface Emitting Laser>>

According to the surface emitting laser 10-3, the first reflection mirror 106 is the plane mirror, so that it is possible to obtain the same effect as that of the surface emitting laser 10-1 except that it is not possible to obtain an effect unique to the concave mirror. According to the manufacturing method for the surface emitting laser 10-3, the first reflection mirror 106 is the plane mirror, so that it is not necessary to process the substrate 100 and it is possible to simplify a manufacturing process.

### 4. Surface Emitting Laser According to Example 4 of Embodiment of Present Technology

### <<Configuration of Surface Emitting Laser>>

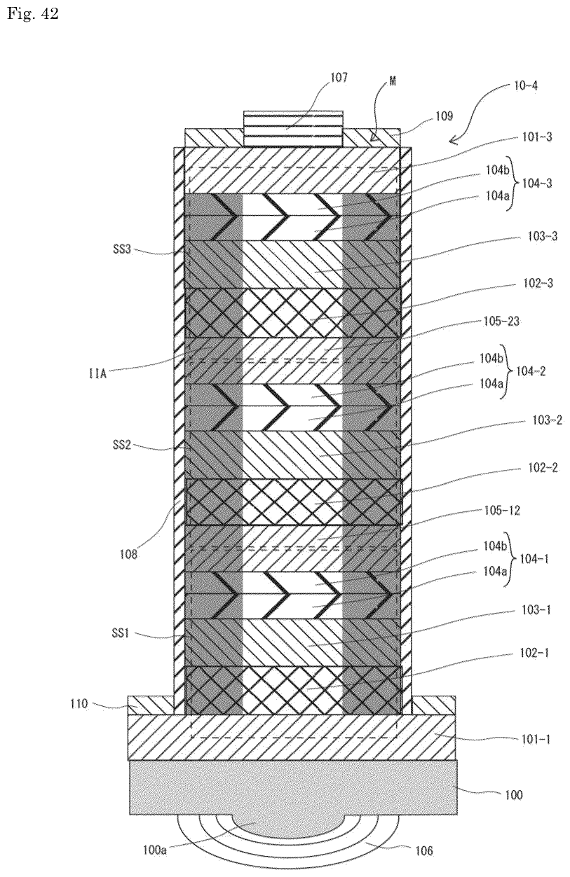

FIG. 42 is a cross-sectional view of a surface emitting laser 10-4 according to example 4 of the embodiment of the present technology. The surface emitting laser 10-4 employs the same configuration as that of the surface emitting laser 10-1 according to example 1 except that the substrate 100 is a heat conductive substrate (heat dissipation member) made of a material (e.g., Si or GaAs) having high thermal conductivity, and is thinned.

### <<Operation of Surface Emitting Laser>>

The surface emitting laser 10-4 performs the same operation as that of the surface emitting laser 10-1 according to example 1.

### <<Example of Manufacturing Method for Surface Emitting Laser>>

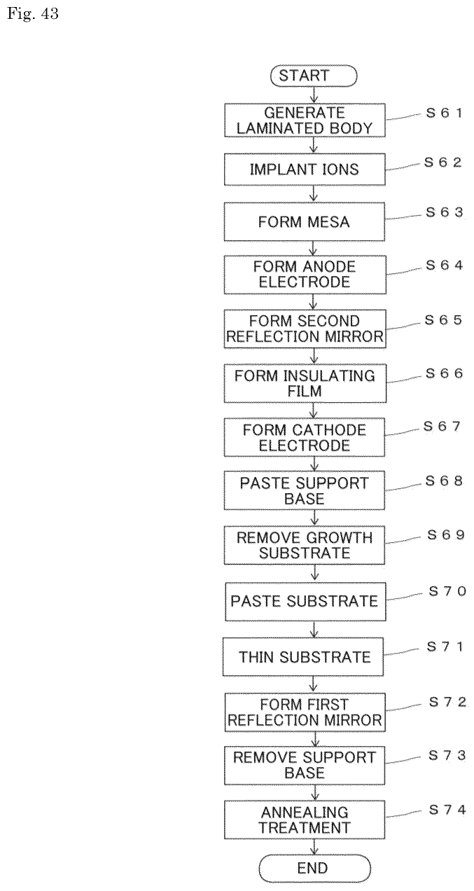

Hereinafter, an example of the manufacturing method for the surface emitting laser 10-4 will be described with reference to the flowchart in FIG. 43. Here, for example, the semiconductor manufacturing method that uses the semiconductor manufacturing device simultaneously generates a plurality of the surface emitting lasers 10-4 on one wafer that is the base material of the substrate 100, separates the plurality of series of integrated surface emitting lasers 10-4 from each other, and obtains chip-shaped surface emitting lasers (surface emitting laser chips). Note that the semiconductor manufacturing method can also simultaneously generate a plurality of surface emitting laser arrays formed by two-dimensionally disposing the plurality of surface emitting lasers 10-4 on the one wafer that is the base material of the substrate 100, separate the plurality of series of integrated surface emitting laser arrays from each other, and obtain a plurality of chip-shaped surface emitting laser arrays (surface emitting laser array chips).

In first step S61, a laminated body is generated (see FIG. 3). More specifically, for example, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are laminated (epitaxially grown) on the growth substrate GS (e.g., InP substrate) in the growth chamber in this order by the Metal Organic Chemical Vapor Deposition method (MOCVD method) or the Molecular Beam Epitaxy method (MBE method). That is, the laminated body is generated by performing epitaxial growth once.

In next step S62, ion implantation is performed (see FIG. 5). More specifically, first, a center region of the laminated body for which ion implantation to be described later is not performed is protected by the protection film PF made of SiO₂. Next, ions are implanted in the peripheral region (the region on which the protection film PF is not formed) of the laminated body from the n-type semiconductor layer 101-3 side. At this time, for example, the protons (H⁺) are used as ion species, ion implantation energy is set such that the protons reach (preferably concentrates) in the growth substrate GS, and the dose is set to, for example, 1×10¹⁴ ion/cm² or more. As a result, ion implantation causes crystal defects, and a region in which the ions have been implanted has increased resistance. That is, the peripheral parts of the growth substrate GS, the n-type semiconductor layer 101-1, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 have increased resistance. As a result, the high concentration ion region HiIR (parts that are painted black in FIG. 5) including regions in which the ion concentration comes to a peak is formed in the growth substrate GS. Then, the protection film PF is removed.

In next step S63, the mesa M is formed (see FIG. 7). More specifically, for example, the active layer 102-1, the p-type semiconductor layer 103-1, the tunnel junction layer 104-1, the n-type semiconductor layer 105-12, the active layer 102-2, the p-type semiconductor layer 103-2, the tunnel junction layer 104-2, the n-type semiconductor layer 105-23, the active layer 102-3, the p-type semiconductor layer 103-3, the tunnel junction layer 104-3, and the n-type semiconductor layer 101-3 are etched to form the mesa M. More specifically, a resist pattern for forming the mesa M on the n-type semiconductor layer 101-3 of the laminated body (see FIG. 5) into which the ions have been implanted is generated by photolithography. Next, etching is performed by, for example, wet etching or dry etching using this resist pattern as a mask until the surface of at least the n-type semiconductor layer 101-1 is exposed (until the side surface of at least the active layer 102-1 is completely exposed) to form the mesa M whose diameter is, for example, 5 to 100 μm. Then, the resist pattern is removed.

In next step S64, the anode electrode 109 is formed (see FIG. 8). More specifically, the anode electrode 109 of the circular shape (e.g., ring shape) is formed on the peripheral part of the top part of the mesa M by, for example, the lift-off method.

In the next step S65, the second reflection mirror 107 is formed (see FIG. 10). More specifically, first, the dielectric multilayer film that is the material of the second reflection mirror 107 is formed on the entire surface. Next, the dielectric multilayer film other than the dielectric multilayer film on the center region of the top part of the mesa M is removed by, for example, dry etching. As a result, the dielectric multilayer film reflection mirror that is the second reflection mirror 107 surrounded by the anode electrode 109 is formed.

In next step S66, the insulating film 108 is formed (see FIG. 12). More specifically, first, the insulating film 108 is formed on the entire surface. Next, the insulating film 108 that covers the anode electrode 109 and the second reflection mirror 107, and the insulating film 108 that covers the region (n-type semiconductor layer 101-1) around the bottom part of the mesa M are removed by, for example, dry etching. As a result, the anode electrode 109, the second reflection mirror 107, and the region around the mesa M are exposed, and only the insulating film 108 formed on the side surface of the mesa M is left.

In next step S67, the cathode electrode 110 is formed (see FIG. 13). More specifically, the cathode electrode 110 of the circular shape (e.g., ring shape) is formed so as to surround the bottom part of the mesa M with the insulating film 108 interposed therebetween by, for example, the lift-off method.

In next step S68, the support base SB is pasted (see FIG. 14). More specifically, the support base SB is pasted on the mesa M side with the wax W interposed therebetween.

In next step S69, the growth substrate GS is removed (see FIG. 15). More specifically, first, the back surface of the growth substrate GS is polished and thinned using the back grinder. Next, the growth substrate GS is removed by wet etching using, for example, the mixed solution of hydrochloric acid and phosphoric acid. As a result, the n-type semiconductor layer 101-1 is exposed. The high concentration ion region HiIR is also removed as the growth substrate GS is removed. Here, in step S61, by disposing the etching stop layer (e.g., InGaAsP layer) between the growth substrate GS and the n-type semiconductor layer 101-1, it is possible to stop the wet etching in the etching stop layer. It is possible to remove the etching stop layer using the mixed solution of sulfuric acid, hydrogen peroxide, and water.

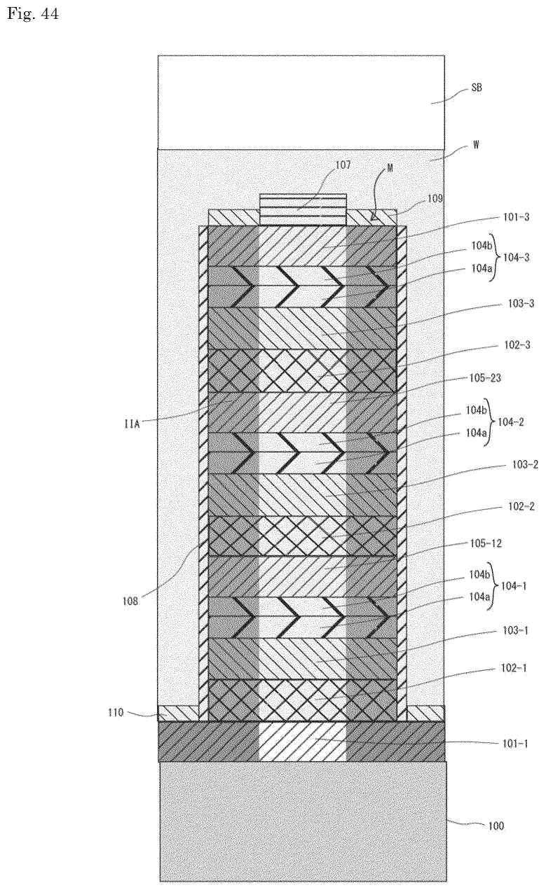

In next step S70, the substrate 100 is pasted (see FIG. 44). More specifically, the n-type semiconductor layer 101-1 and the substrate 100 (heat conductive substrate) are bonded. At this time, for example, plasma processing is performed on the bonding surface of the n-type semiconductor layer 101-1 with respect to the substrate 100 and the bonding surface of the substrate 100 with respect to the n-type semiconductor layer 101-1, the bonding surfaces are cleaned, and then both of the bonding surfaces are pasted to bond the n-type semiconductor layer 101-1 and the substrate 100.

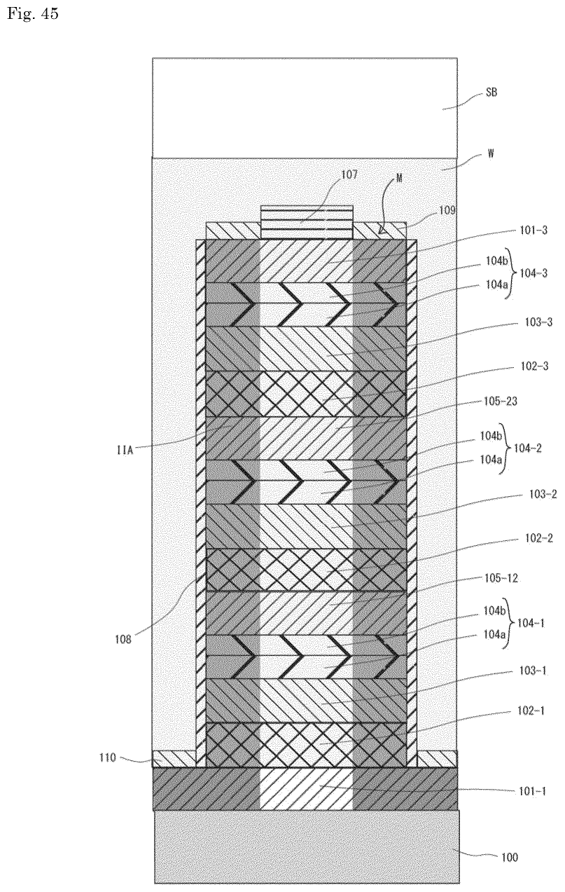

In next step S71, the substrate 100 is thinned (see FIG. 45). More specifically, the back surface of the substrate 100 is polished using a Chemical Mechanical Polishing (CMP) device to thin the substrate 100 to a predetermined thickness.

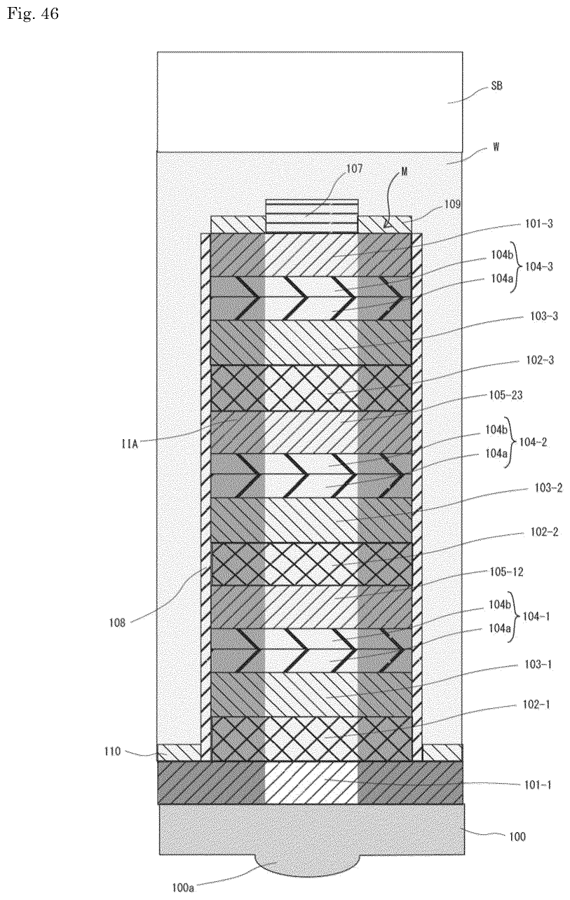

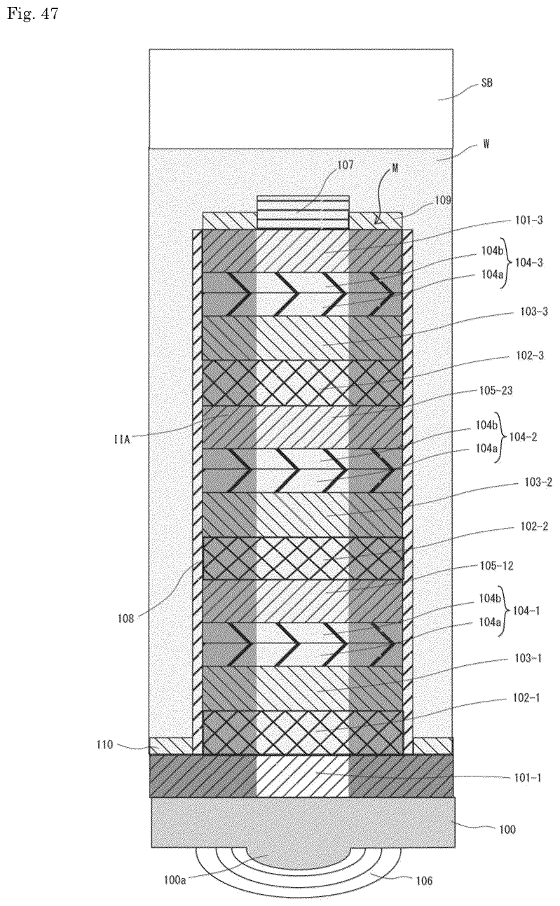

In next step S72, the first reflection mirror 106 is formed. More specifically, first, a resist is applied to the back surface (lower surface) of the substrate 100, and the substrate 100 is subjected to dry etching using as a mask a hemispherical resist obtained by heating (reflowing) the resist into a hemispherical shape to form the convex structure 100a (see FIG. 46). Next, the dielectric multilayer film is formed on the back surface of the substrate 100 on which the convex structure 100a has been formed to form the dielectric multilayer film reflection mirror that is the first reflection mirror 106 (see FIG. 47).

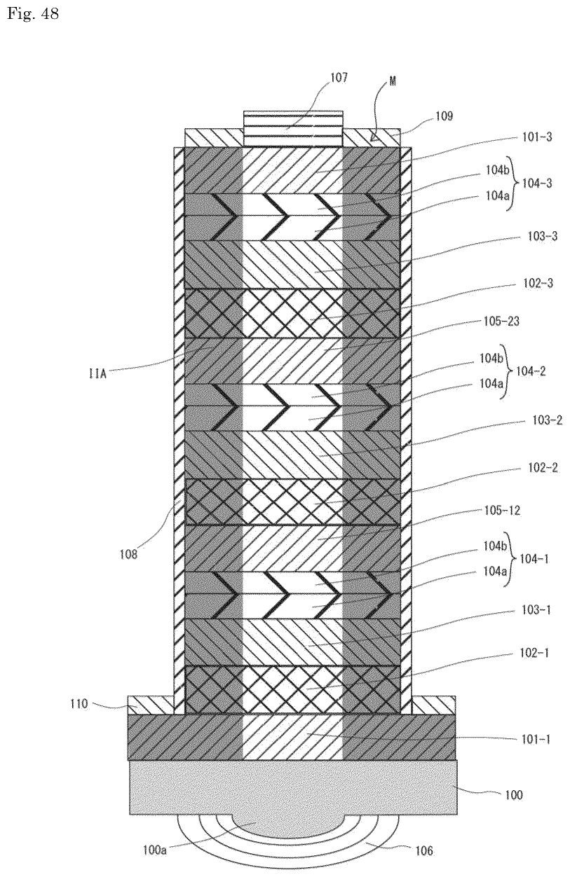

In next step S73, the support base SB is removed (see FIG. 48). More specifically, the wax W is heated at, for example, 200 to 300° C. and softened to remove the support base SB. After the support base SB is removed, the remaining wax W is removed by the usher.

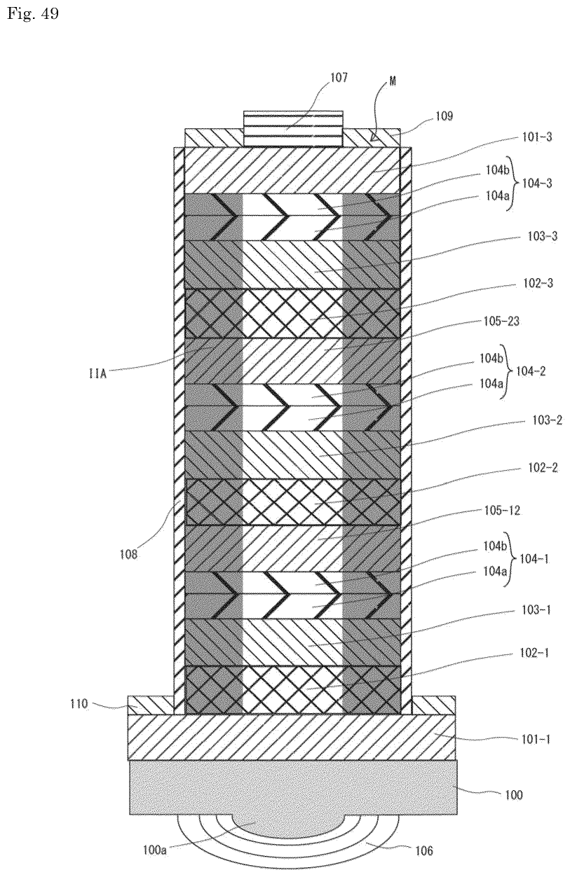

In last step S74, annealing treatment is performed (see FIG. 49). More specifically, the annealing treatment is performed at 350 to 600° C. Thus, the surrounding parts of the n-InP layers that are the n-type semiconductor layers 101-1 and 101-3 that have been damaged by ion implantation (that has caused crystal defects) have reduced resistances and are repaired. On the other hand, the peripheral parts of the active layers 102-1, 102-2, and 102-3, the p-type semiconductor layers 103-1, 103-2, and 103-3, the tunnel junction layers 104-1, 104-2, and 104-3, and the n-type semiconductor layers 105-12 and 105-23 of the n-AlGaInAs layers that have been damaged by ion implantation keep increased resistance, and are not repaired. The annealing treatment described herein can also function as the sinter of each electrode.

### <<Effect of Surface Emitting Laser and Manufacturing Method for Surface Emitting Laser>>

According to the surface emitting laser 10-4, it is possible to obtain the same effect as that of the surface emitting laser 10-1 according to example 1, and the thin heat conductive substrate is used as the substrate 100, so that it is possible to improve heat dissipation while achieving the thin surface emitting laser 10-4 as a whole. According to the manufacturing method for the surface emitting laser 10-4, although the number of processes becomes larger as the substrate 100 is made thinner, it is possible to obtain the same effect as the manufacturing method for the surface emitting laser 10-1 according to example 1. Note that step S71 (the process of thinning the substrate 100) may be omitted.

### 5. Surface Emitting Laser According to Example 5 of Embodiment of Present Technology

### <<Configuration of Surface Emitting Laser>>

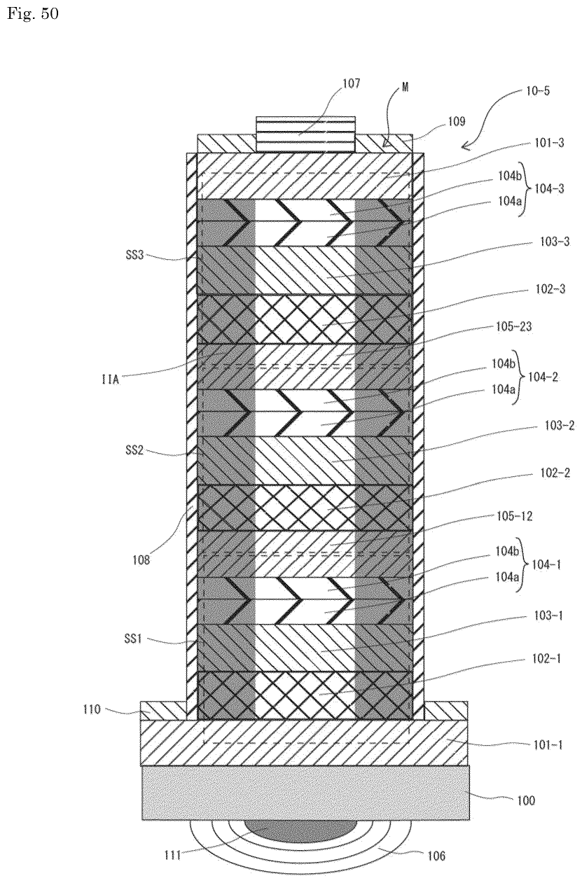

FIG. 50 is a cross-sectional view of a surface emitting laser 10-5 according to example 5 of the embodiment of the present technology. The surface emitting laser 10-5 employs the same configuration as that of the surface emitting laser 10-4 according to example 4 except that the convex structure 111 that is the underlayer of the first reflection mirror 106 is formed of a material different from that of the substrate 100.

The convex structure 111 is made of, for example, a transparent dielectric, a resin, a resist, or the like such as SiO₂.

### <<Operation of Surface Emitting Laser>>

The surface emitting laser 10-5 performs the same operation as that of the surface emitting laser 10-1 according to example 1.

### <<Manufacturing Method for Surface Emitting Laser>>

The surface emitting laser 10-5 can be manufactured by the substantially same manufacturing method as the manufacturing method for the surface emitting laser 10-4 according to example 4.

### <<Effect of Surface Emitting Laser>>

According to the surface emitting laser 10-5, it is possible to obtain the same effect as that of the surface emitting laser 10-4 according to example 4, and, form the convex structure 111 without processing the substrate 100. For example, the resist formed on the back surface of the substrate 100 and molded in the hemispherical shape by heating can be used as the underlayer of the first reflection mirror 106 as is.

### 6. Surface Emitting Laser According to Example 6 of Embodiment of Present Technology

### <<Configuration of Surface Emitting Laser>>

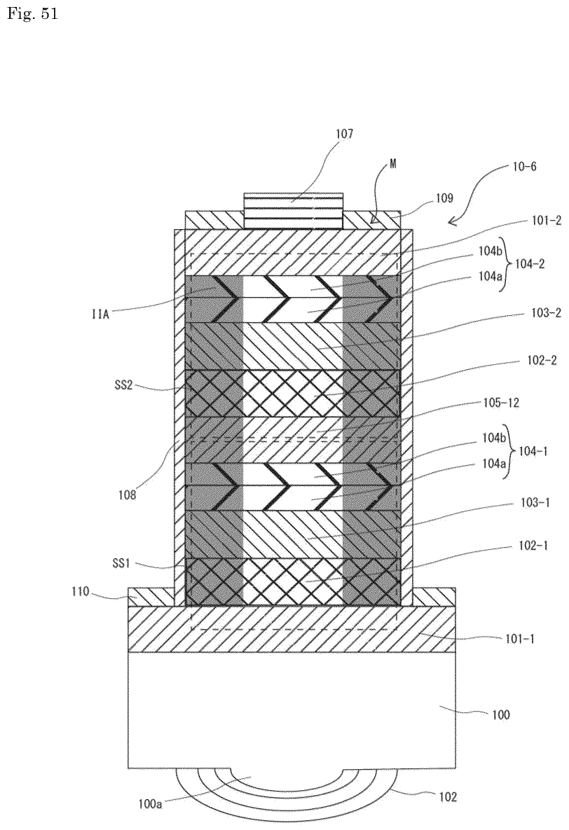

FIG. 51 is a cross-sectional view of a surface emitting laser 10-6 according to example 6 of the embodiment of the present technology. The surface emitting laser 10-6 employs the same configuration as that of the surface emitting laser 10-1 according to example 1 except that the laminated structure includes the only two semiconductor structures SS.

As illustrated in FIG. 51, in the surface emitting laser 10-6, the laminated structure includes only the first and second semiconductor structures SS1 and SS2.

### <<Operation of Surface Emitting Laser>>

The surface emitting laser 10-6 performs the same operation as that of the surface emitting laser 10-1 according to example 1.

### <<Manufacturing Method for Surface Emitting Laser>>

The surface emitting laser 10-6 can be manufactured by the substantially same manufacturing method as the manufacturing method for the surface emitting laser 10-1 according to example 1.

### <<Effect of Surface Emitting Laser>>

According to the surface emitting laser 10-6, by minimizing the number of the laminated semiconductor structures SS (to two), it is possible to provide a thin surface emitting laser that can achieve a high output while sufficiently suppressing an increase in manufacturing cost, and includes the current constriction region.

### 7. Surface Emitting Laser According to Example 7 of Embodiment of Present Technology

### <<Configuration of Surface Emitting Laser>>

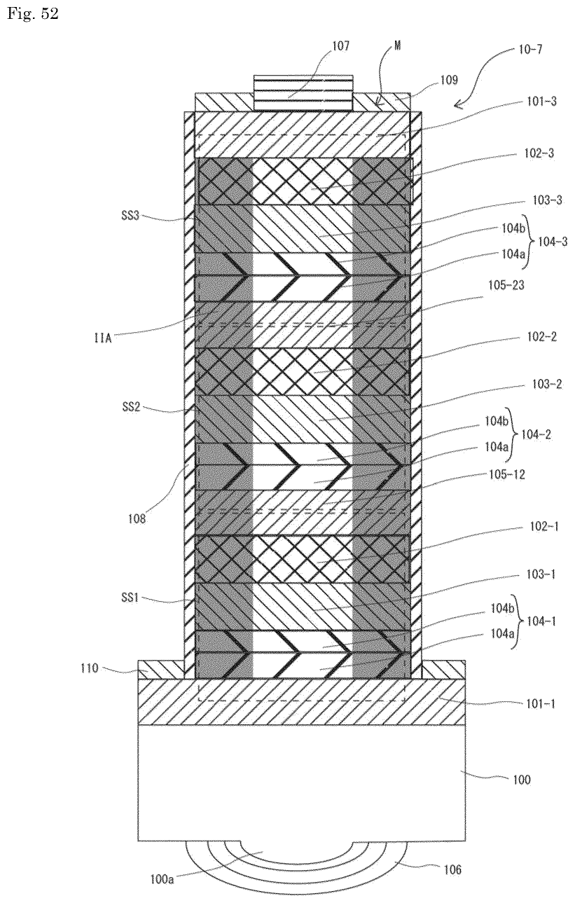

FIG. 52 is a cross-sectional view of a surface emitting laser 10-7 according to example 7 of the embodiment of the present technology. The surface emitting laser 10-7 employs the same configuration as that of the surface emitting laser 10-1 according to example 1 except that the semiconductor structures are disposed upside down.

Each semiconductor structure SS includes the p-type semiconductor layer 103 that is disposed between the active layer 102 and the tunnel junction layer 104, the first n-type semiconductor layer that is disposed on the opposite side to the p-type semiconductor layer 103 side of the active layer 102, and the second n-type semiconductor layer that is disposed on the opposite side to the p-type semiconductor layer 103 side of the tunnel junction layer 104.

Each semiconductor structure is disposed such that the first n-type semiconductor layer is located on the second reflection mirror 107 side, and the second n-type semiconductor layer is located on the first reflection mirror 106 side.

The n-type semiconductor layer 101-3 (e.g., n-InP layer) that is the first n-type semiconductor layer of the semiconductor structure SS3 closest to the second reflection mirror 107, and the n-type semiconductor layer 101-1 (e.g., n-InP layer) that is the second n-type semiconductor layer of the semiconductor structure SS1 closest to the first reflection mirror 106 have lower resistance than that of the peripheral part of the p-type semiconductor layer 103.

The peripheral parts of all layers other than the n-type semiconductor layer 101-3 that is the first n-type semiconductor layer of the semiconductor structure SS3 closest to the second reflection mirror 107, and the n-type semiconductor layer 101-1 that is the second n-type semiconductor layer of the semiconductor structure SS1 closest to the first reflection mirror 106 have higher resistance than that of the center part in the laminated structure LS.

### <<Operation of Surface Emitting Laser>>

The surface emitting laser 10-7 performs the same operation as that of the surface emitting laser 10-1 according to example 1.

### <<Manufacturing Method for Surface Emitting Laser>>

The surface emitting laser 10-7 can be manufactured by the substantially same manufacturing method as the manufacturing method for the surface emitting laser 10-1 according to example 1.

### <<Effect of Surface Emitting Laser>>

According to the surface emitting laser 10-7, it is possible to obtain the same effect as that of the surface emitting laser 10-1 according to example 1.

### 8. Surface Emitting Laser According to Example 8 of Embodiment of Present Technology

### <<Configuration of Surface Emitting Laser>>

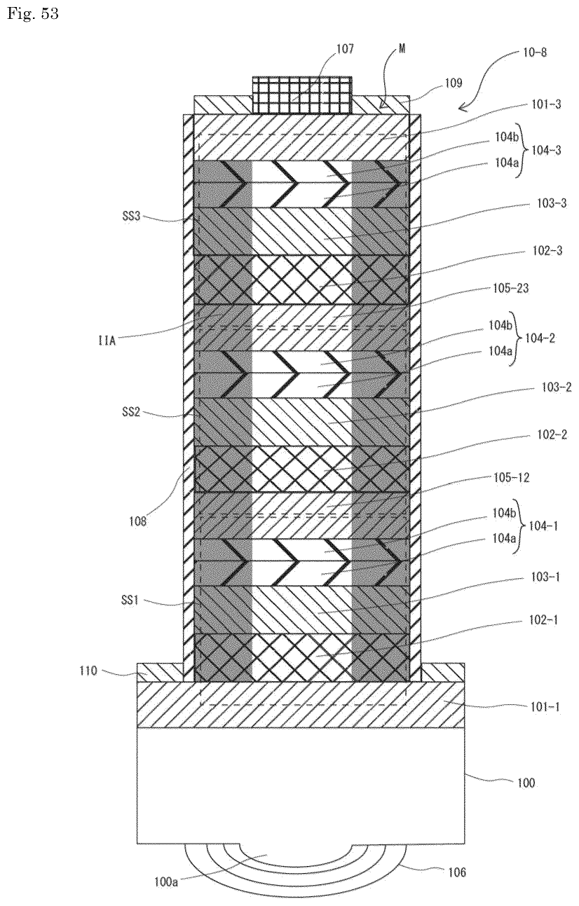

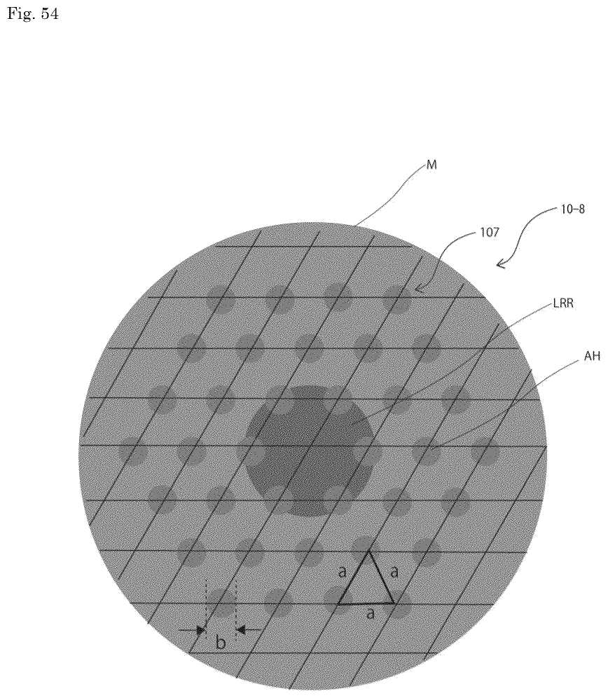

FIG. 53 is a cross-sectional view of a surface emitting laser 10-8 according to example 8 of the embodiment of the present technology. FIG. 54 is a plan view of the surface emitting laser 10-8 according to example 8 of the embodiment of the present technology. Note that, in FIG. 54, illustration of the anode electrode 109, the cathode electrode 110, and the insulating film 108 is omitted.

The surface emitting laser 10-8 employs the same configuration as that of the surface emitting laser 10-1 according to example 1 except that the second reflection mirror 107 has a photonic crystal structure as illustrated in FIGS. 53 and 54. In FIG. 54, reference numeral LRR denotes a low resistance region surrounded by the ion implantation region IIA.

As illustrated in FIG. 54, the photonic crystal structure of the second reflection mirror 107 includes a plurality of air holes AH periodically formed in the dielectric multilayer film reflection mirror. A ratio b/a of a diameter b with respect to a pitch a of the air hole AH is preferably b/a<0.5. A ratio a/λ of the pitch a of the air hole AH with respect to the oscillation wavelength λ is preferably a/λ>3. In a case of, for example, λ=1500 nm, a>4500 nm holds. Hence, in a case of, for example, a=5000 nm, b<2500 nm holds.

### <<Operation of Surface Emitting Laser>>

The surface emitting laser 10-8 performs the same operation as that of the surface emitting laser 10-1 according to example 1.

### <<Manufacturing Method for Surface Emitting Laser>>

The surface emitting laser 10-8 can be manufactured by the substantially same manufacturing method as the manufacturing method for the surface emitting laser 10-1 according to example 1.

### <<Effect of Surface Emitting Laser>>

According to the surface emitting laser 10-8, the second reflection mirror 107 that is a reflection mirror on the emission side has the photonic crystal structure, so that it is possible to control a lateral mode.

### 9. Surface Emitting Laser According to Example 9 of Embodiment of Present Technology

### <<Configuration of Surface Emitting Laser>>

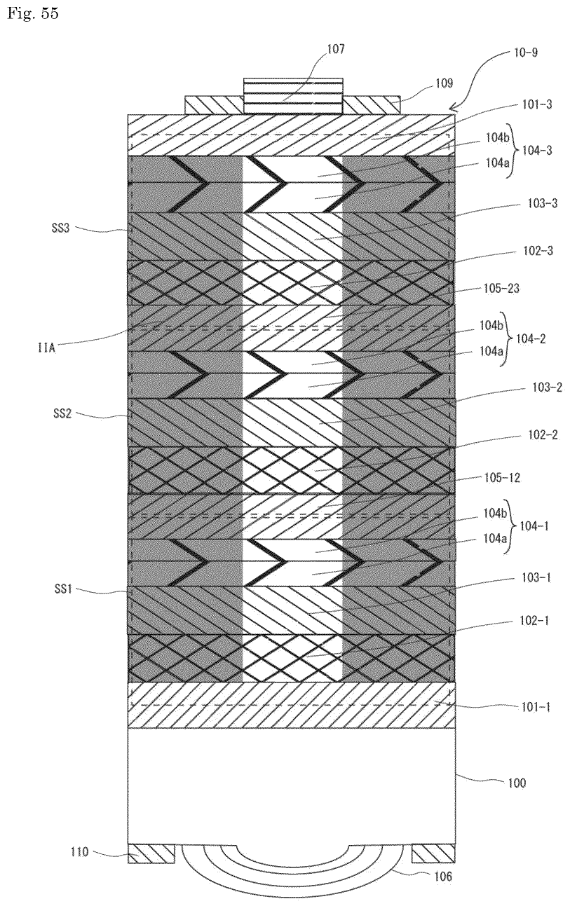

FIG. 55 is a cross-sectional view of a surface emitting laser 10-9 according to example 9 of the embodiment of the present technology.

The surface emitting laser 10-9 employs the same configuration as that of the surface emitting laser 10-1 according to example 1 except that the mesa M is not formed as illustrated in FIG. 55.

In the surface emitting laser 10-9, the cathode electrode 110 is provided to the back surface of the substrate 100 (e.g., a semiconductor substrate such as an Si substrate or a GaAs substrate) having conductivity.

### <<Operation of Surface Emitting Laser>>

The surface emitting laser 10-9 performs the same operation as that of the surface emitting laser 10-1 according to example 1.

### <<Manufacturing Method for Surface Emitting Laser>>

The surface emitting laser 10-9 can be manufactured by the substantially same manufacturing method as the manufacturing method for the surface emitting laser 10-1 according to example 1.

### <<Effect of Surface Emitting Laser>>

According to the surface emitting laser 10-9, it is possible to obtain the same effect as that of the surface emitting laser 10-1 according to example 1, and, it is not necessary to form the mesa M, so that it is possible to simplify a manufacturing process.

### 10. Surface Emitting Laser According to Example 10 of Embodiment of Present Technology

### <<Configuration of Surface Emitting Laser>>

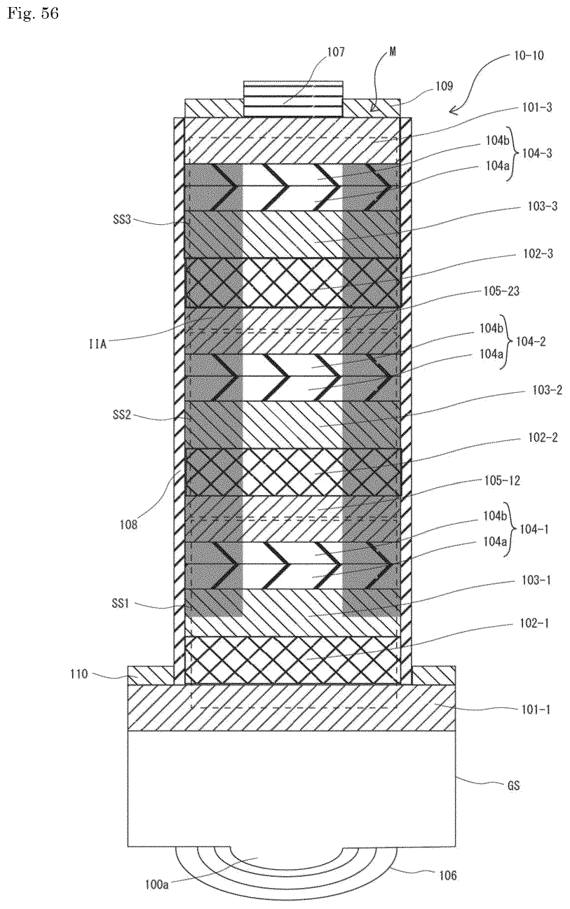

FIG. 56 is a cross-sectional view of a surface emitting laser 10-10 according to example 10 of the embodiment of the present technology.

The surface emitting laser 10-10 employs the same configuration as that of the surface emitting laser 10-1 according to example 1 except that, as illustrated in FIG. 56, the lower end of the ion implantation region IIA does not reach the upper surface of the n-type semiconductor layer 101-1 (the lower surface of the active layer 102-1) of the first semiconductor structure SS1 and the surface emitting laser 10-10 includes the growth substrate GS (e.g., InP substrate) instead of the substrate 100.

The lower end of the ion implantation region IIA may be located below (e.g., in the p-type semiconductor layer 103-1) the lower surface of the tunnel junction layer 104-1 of the semiconductor structure SS1.

In the surface emitting laser 10-10, an implantation depth of ion implantation is an upper side of the n-type semiconductor layer 101-1, and therefore the peripheral part of the n-type semiconductor layer 101-1 does not have increased resistance. Consequently, the n-type semiconductor layer 101-1 does not need to be repaired (the resistance is reduced) by annealing, so that, even when a material (e.g., n-AlGaInAs) other than n-InP is used for the n-type semiconductor layer 101-1, it is possible to use the n-type semiconductor layer 101-1 having low resistance as a contact region with respect to the cathode electrode 110. That is, the degree of freedom of selection of a material used for the n-type semiconductor layer 101-1 is high.

### <<Manufacturing Method for Surface Emitting Laser>>

The surface emitting laser 10-10 can be manufactured by the substantially same manufacturing method as the manufacturing method for the surface emitting laser 10-1 according to example 1.

### <<Operation of Surface Emitting Laser>>

The surface emitting laser 10-10 performs the same operation as that of the surface emitting laser 10-1 according to example 1.

### <<Effect of Surface Emitting Laser>>

According to the surface emitting laser 10-10, although a high concentration ion region is left in the laser, the growth substrate GS can be used as is, so that it is possible to simplify the manufacturing process.

### 11. Surface Emitting Laser According to Example 11 of Embodiment of Present Technology

### <<Configuration of Surface Emitting Laser>>

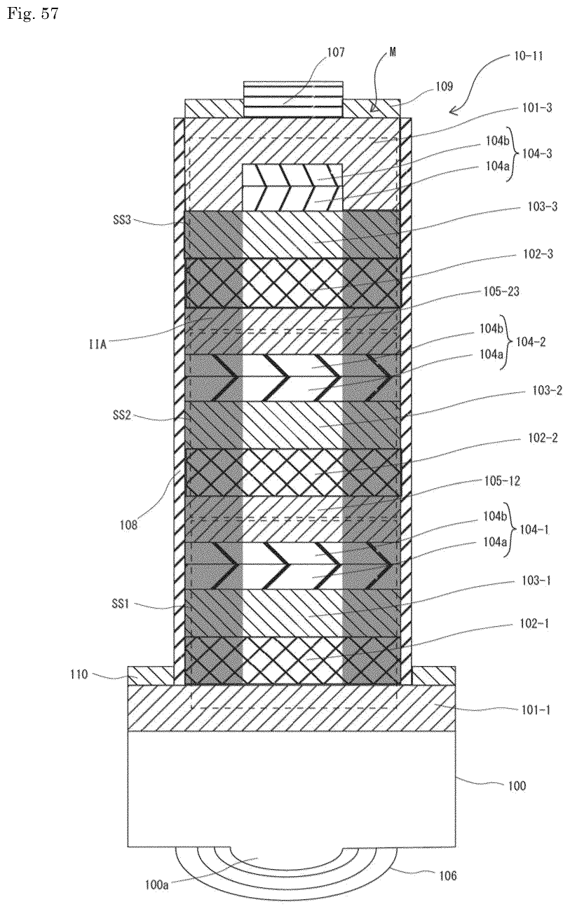

FIG. 57 is a cross-sectional view of a surface emitting laser 10-11 according to example 11 of the embodiment of the present technology.

The surface emitting laser 10-11 employs the same configuration as that of the surface emitting laser 10-1 according to example 1 except that, for example, the tunnel junction layer 104-3 of the third semiconductor structure SS3 is a burial type as illustrated in FIG. 57.

In the surface emitting laser 10-11, the tunnel junction layer 104-3 in the third semiconductor structure SS3 is provided in a mesa shape on the p-type semiconductor layer 103-3, and the surroundings of the tunnel junction layer 104-3 are buried in the n-type semiconductor layer 101-3 (e.g., the n-InP layer or the n-AlGaInAs layer).

### <<Operation of Surface Emitting Laser>>

The surface emitting laser 10-11 performs the substantially same operation as that of the surface emitting laser 10-1 according to example 1.

### <<Manufacturing Method for Surface Emitting Laser>>

The surface emitting laser 10-11 can be manufactured by the substantially same manufacturing method as the manufacturing method for the surface emitting laser 10-1 according to example 1.

### <<Effect of Surface Emitting Laser>>

According to the surface emitting laser 10-11, although the tunnel junction layer 104-3 is the burial type, and therefore it is necessary to perform etching and subsequent burial regrowth and manufacturing cost slightly increases, it is possible to obtain a light trapping effect of a refractive index difference in a lateral direction between the tunnel junction layer 104-3 and the n-type semiconductor layer 101-3.

Note that the burial type tunnel junction layer 104-3 in the surface emitting laser 10-11 is one example, and the other tunnel junction layers 104 may be the burial types, that is, part of the tunnel junction layers 104 of the plurality of tunnel junction layers 104 of the surface emitting laser may be the burial type.

### 12. Surface Emitting Laser According to Example 12 of Embodiment of Present Technology

### <<Configuration of Surface Emitting Laser>>

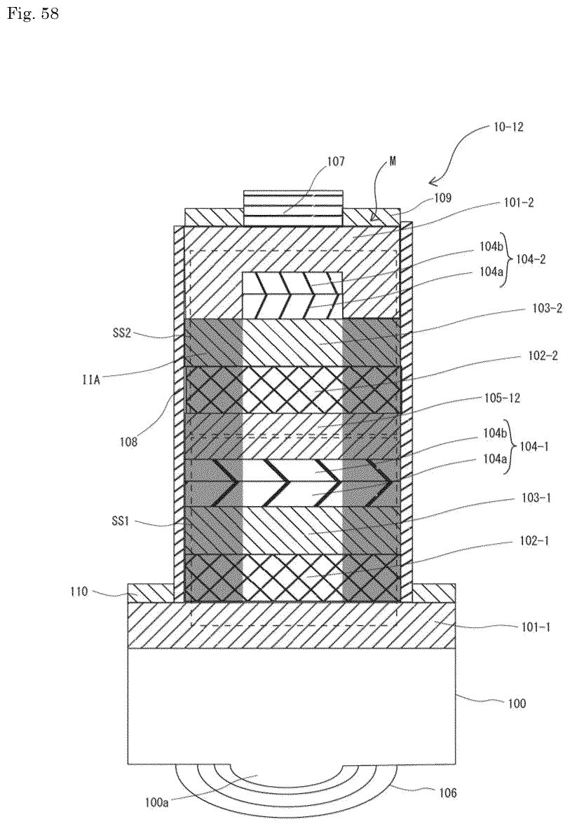

FIG. 58 is a cross-sectional view of a surface emitting laser 10-12 according to example 12 of the embodiment of the present technology.

The surface emitting laser 10-12 employs the same configuration as that of the surface emitting laser 10-1 according to example 1 except that, for example, the third semiconductor structure SS3 is not provided, and the tunnel junction layer 104-2 of the second semiconductor structure SS2 is a burial type as illustrated in FIG. 58.

In the surface emitting laser 10-12, the tunnel junction layer 104-2 in the second semiconductor structure SS2 is provided in a mesa shape on the p-type semiconductor layer 103-2, and the surroundings of the tunnel junction layer 104-2 are buried in the n-type semiconductor layer 101-2 (e.g., the n-InP layer or the n-AlGaInAs layer).

### <<Operation of Surface Emitting Laser>>

The surface emitting laser 10-12 performs the substantially same operation as that of the surface emitting laser 10-1 according to example 1.

### <<Manufacturing Method for Surface Emitting Laser>>

The surface emitting laser 10-12 can be manufactured by the substantially same manufacturing method as the manufacturing method for the surface emitting laser 10-1 according to example 1.

### <<Effect of Surface Emitting Laser>>

According to the surface emitting laser 10-12, although the tunnel junction layer 104-2 is the burial type, and therefore it is necessary to perform etching and subsequent burial regrowth and manufacturing cost slightly increases, it is possible to obtain a light trapping effect of a refractive index difference in the lateral direction between the tunnel junction layer 104-2 and the n-type semiconductor layer 101-2.

### 13. Surface Emitting Laser According to Example 13 of Embodiment of Present Technology

### <<Configuration of Surface Emitting Laser>>

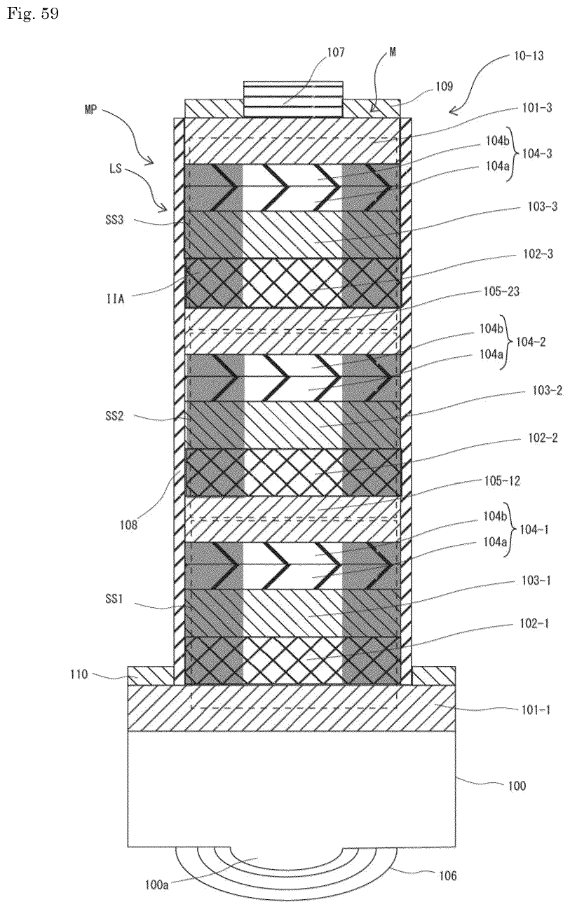

FIG. 59 is a cross-sectional view of a surface emitting laser 10-13 according to example 13 of the embodiment of the present technology.

The surface emitting laser 10-13 employs the same configuration as that of the surface emitting laser 10-1 according to example 1 except that the n-type semiconductor layer 101-1 of the first semiconductor structure SS1 and the n-type semiconductor layer 101-3 of the third semiconductor structure SS3, and, in addition, the n-type semiconductor layer 105-12 of the first and second semiconductor structures SS1 and SS2 and the n-type semiconductor layer 105-23 of the second and third semiconductor structures SS2 and SS3 are the n-InP layers.

In the surface emitting laser 10-13, the peripheral parts of all layers other than the n-type semiconductor layer 101-3 that is the second n-type semiconductor layer of the third semiconductor structure SS3 closest to the second reflection mirror 107, the n-type semiconductor layer 101-1 that is the first n-type semiconductor layer of the first semiconductor structure SS1 closest to the first reflection mirror 106, and the first and second n-type semiconductor layers 105-12 and 105-23 of the second semiconductor structure SS2 located at the middle of the laminated structure have higher resistance than that of the center part in the laminated structure.

In the surface emitting laser 10-13, the n-type semiconductor layers 105-12 and 105-23 also have lower resistance than those of the peripheral parts of the tunnel junction layer 104, the p-type semiconductor layer 103, and the active layer 102.

### <<Operation of Surface Emitting Laser>>

The surface emitting laser 10-13 performs the substantially same operation as that of the surface emitting laser 10-1 according to example 1.

### <<Manufacturing Method for Surface Emitting Laser>>

The surface emitting laser 10-13 is manufactured by the substantially same manufacturing method as the manufacturing method for the surface emitting laser 10-1. According to the surface emitting laser 10-13, the peripheral parts of the n-type semiconductor layers 101-1, 101-3, 105-12, and 105-23 whose resistance has been increased by annealing at a time of manufacturing are repaired (the resistance is reduced).

### <<Effect of Surface Emitting Laser>>

According to the surface emitting laser 10-13, it is possible to obtain the substantially same effect as that of the surface emitting laser 10-1 according to example 1.

### 14. Surface Emitting Laser According to Example 14 of Embodiment of Present Technology

### <<Configuration of Surface Emitting Laser>>

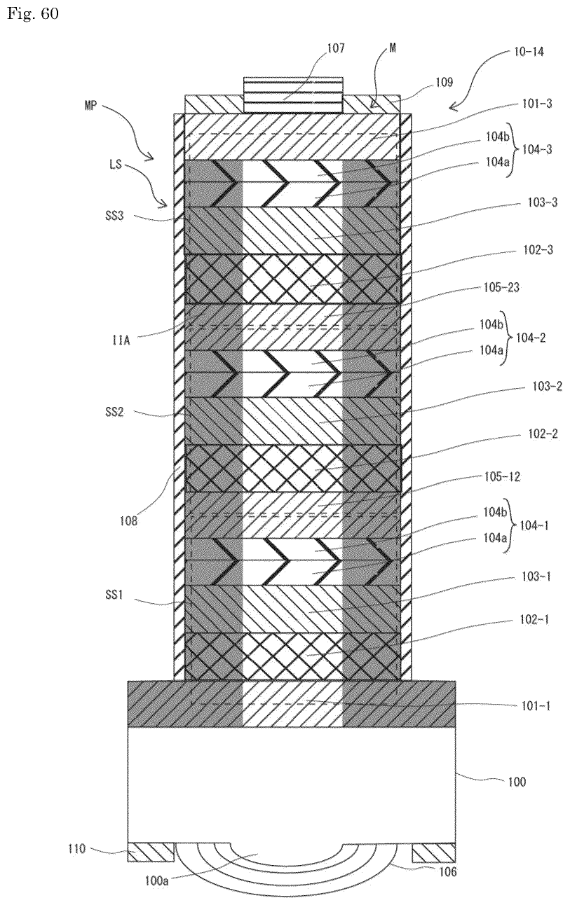

FIG. 60 is a cross-sectional view of a surface emitting laser 10-14 according to example 14 of the embodiment of the present technology.

The surface emitting laser 10-14 employs the same configuration as that of the surface emitting laser 10-1 according to example 1 except that the n-type semiconductor layer 101-1 of the first semiconductor structure SS1 is formed of, for example, the n-AlGaInAs layer and the cathode electrode 110 is provided in the circular shape (e.g., ring shape) on the back surface of the substrate 100 so as to surround the first reflection mirror 106.

In the surface emitting laser 10-14, the peripheral part of the n-type semiconductor layer 101-1 is the ion implantation region IIA, and has the higher resistance than that of the center part.

### <<Operation of Surface Emitting Laser>>

The surface emitting laser 10-14 performs the substantially same operation as that of the surface emitting laser 10-1 according to example 1. In this regard, the current having passed the n-type semiconductor layer 101-1 flows out from the cathode electrode 110 to the cathode side of the laser driver via the substrate 100.

### <<Manufacturing Method for Surface Emitting Laser>>

The surface emitting laser 10-14 is manufactured by the substantially same manufacturing method as the manufacturing method for the surface emitting laser 10-1. In this regard, according to the surface emitting laser 10-14, the peripheral part of the n-type semiconductor layers 101-1 whose resistance has been increased by annealing at a time of manufacturing is not repaired (keeps the increased resistance).

### <<Effect of Surface Emitting Laser>>

According to the surface emitting laser 10-14, it is possible to obtain the substantially same effect as that of the surface emitting laser 10-1 according to example 1.

### 15. Surface Emitting Laser According to Example 15 of Embodiment of Present Technology

### <<Configuration of Surface Emitting Laser>>

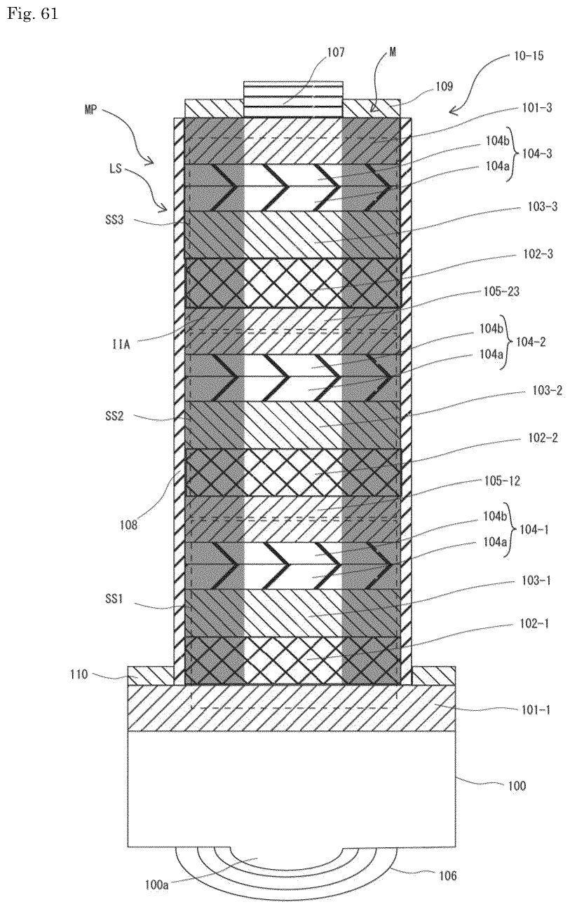

FIG. 61 is a cross-sectional view of a surface emitting laser 10-15 according to example 15 of the embodiment of the present technology.

The surface emitting laser 10-15 employs the same configuration as that of the surface emitting laser 10-1 according to example 1 except that the n-type semiconductor layer 101-3 of the third semiconductor structure SS3 is formed of, for example, the n-AlGaInAs layer.

In the surface emitting laser 10-15, the peripheral part of the n-type semiconductor layer 101-3 is the ion implantation region IIA, and has the higher resistance than that of the center part.

### <<Operation of Surface Emitting Laser>>

The surface emitting laser 10-15 performs the substantially same operation as that of the surface emitting laser 10-1 according to example 1.

### <<Manufacturing Method for Surface Emitting Laser>>

The surface emitting laser 10-15 is manufactured by the substantially same manufacturing method as the manufacturing method for the surface emitting laser 10-1. In this regard, according to the surface emitting laser 10-15, the peripheral part of the n-type semiconductor layers 101-3 whose resistance has been increased by annealing at a time of manufacturing is not repaired (keeps the increased resistance).

### <<Effect of Surface Emitting Laser>>

According to the surface emitting laser 10-15, although the n-type semiconductor layer 101-3 that is the contact region with respect to the anode electrode 109 has high resistance, and efficiency slightly lowers. It is possible to obtain the substantially same effect as that of the surface emitting laser 10-1 according to example 1.

### 16. Surface Emitting Laser According to Example 16 of Embodiment of Present Technology

### <<Configuration of Surface Emitting Laser>>

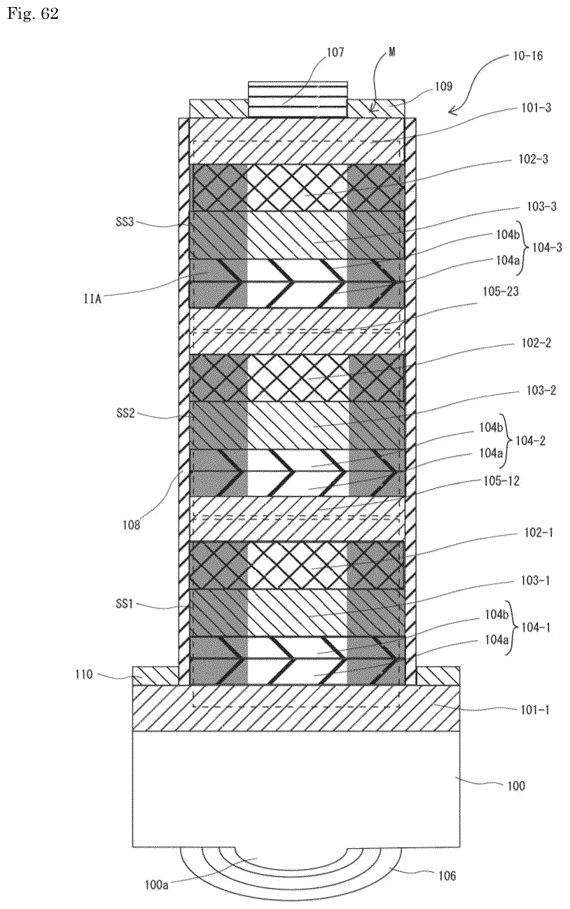

FIG. 62 is a cross-sectional view of a surface emitting laser 10-16 according to example 16 of the embodiment of the present technology.

The surface emitting laser 10-16 employs the same configuration as that of the surface emitting laser 10-7 according to example 7 except that the n-type semiconductor layer 101-1 of the first semiconductor structure SS1 and the n-type semiconductor layer 101-3 of the third semiconductor structure SS3, and, in addition, the n-type semiconductor layer 105-12 of the first and second semiconductor structures SS1 and SS2 and the n-type semiconductor layer 105-23 of the second and third semiconductor structures SS2 and SS3 are the n-InP layers.

In the surface emitting laser 10-16, the peripheral parts of all layers other than the n-type semiconductor layer 101-3 that is the first n-type semiconductor layer of the third semiconductor structure SS3 closest to the second reflection mirror 107, the n-type semiconductor layer 101-1 that is the second n-type semiconductor layer of the first semiconductor structure SS1 closest to the first reflection mirror 106, and the first and second n-type semiconductor layers 105-23 and 105-12 of the second semiconductor structure SS2 located at the middle of the laminated structure have higher resistance than that of the center part in the laminated structure.

In the surface emitting laser 10-16, the n-type semiconductor layers 105-12 and 105-23 also have lower resistance than those of the peripheral parts of the tunnel junction layer 104, the p-type semiconductor layer 103, and the active layer 102.

### <<Operation of Surface Emitting Laser>>

The surface emitting laser 10-16 performs the substantially same operation as that of the surface emitting laser 10-7 according to example 7.

### <<Manufacturing Method for Surface Emitting Laser>>

The surface emitting laser 10-16 is manufactured by the substantially same manufacturing method as the manufacturing method for the surface emitting laser 10-7 according to example 7. According to the surface emitting laser 10-16, the peripheral parts of the n-type semiconductor layers 101-1, 101-3, 105-12, and 105-23 whose resistance has been increased by annealing at a time of manufacturing are repaired (the resistance is reduced).

### <<Effect of Surface Emitting Laser>>

According to the surface emitting laser 10-16, it is possible to obtain the substantially same effect as that of the surface emitting laser 10-1 according to example 1.

### 17. Modification Example of Present Technology

The present technology is not limited to each example of the above embodiment, and can be variously modified.

For example, the four or more semiconductor structures SS may be laminated in the laminated structure LS. In this case, the tunnel junction layer 104 of part of the semiconductor structures SS may be the burial type.

In the surface emitting laser according to the present technology, each of the n-type semiconductor layer (e.g., n-type semiconductor layer 101-1) on the top layer on the one side of the laminated structure, and the n-type semiconductor layer (e.g., n-type semiconductor layer 101-3) on the top layer on the other side of the laminated structure may be made of, for example, AlGaInAs, and the outer peripheral part may be the ion implantation region IIA and has higher resistance than that of the center part.

Although each of the above examples has described the surface emission type surface emitting laser that emits light toward the surface side of the substrate citing the example, the present technology is also applicable to a back surface emission type surface emitting laser that emits light toward the back surface side of a substrate.

In the surface emitting laser according to each of the above examples, the conductive types (the p type and the n type) may be switched.

For example, the manufacturing method for the surface emitting laser according to each of the examples may perform ion implantation after forming the mesa M.

According to the surface emitting laser according to the present technology, compared to a case where the tunnel junction layers 104 of all of the semiconductor structures SS are the burial type, it is possible to improve flatness, and consequently it is possible to paste a GaAs-based semiconductor multilayer film reflection mirror that has high heat dissipation as the second reflection mirror 107 to the laminated structure LS.

Although, for example, the above embodiment has described the InP-based surface emitting laser (a surface emitting laser that includes semiconductor layers that lattice-match with InP) citing the examples, the embodiment is not limited to this, and the present technology is also applicable to, for example, a GaAs-based surface emitting laser (a surface emitting laser that includes semiconductor layers that lattice-match with GaAs).

At least one of the first and second reflection mirrors 106 and 107 may be a semiconductor multilayer film reflection mirror made of a compound of two types or more elements such as Al, Ga, and As.

Part of the components of the surface emitting laser according to each of the examples may be combined without contradicting each other.

In each of the above-described examples, the material, the conductive type, the thickness, the width, the length, the shape, the size, the arrangement, and the like of each component that constitutes the surface emitting laser can be changed as appropriate as long as the surface emitting laser functions as the surface emitting laser.

### 18. Example of Application to Electronic Device

The technology according to the present disclosure (the present technology) can be applied to various products (electronic devices). For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

The surface emitting laser according to the present technology is also applicable as, for example, light sources of devices (e.g., a laser printer, a laser copier, a projector, a head mount display, a head-up display) that form or display images with laser light.

### 19. Application of Surface Emitting Laser to Distance Measurement Device

Hereinafter, an application example of the surface emitting laser according to each of the above examples will be described.

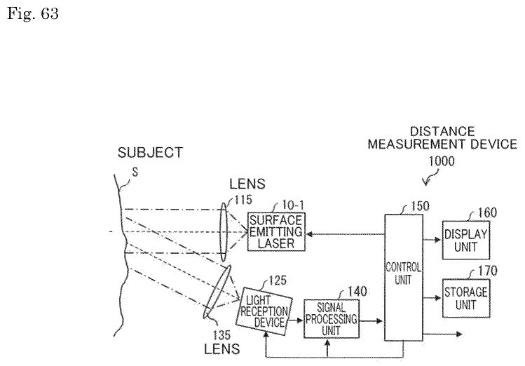

FIG. 63 illustrates an example of a schematic configuration of a distance measurement device 1000 that is an example of the electronic device according to the present technology and includes the surface emitting laser 10-1. The distance measurement device 1000 measures a distance to a subject S by the Time Of Flight (TOF) method. The distance measurement device 1000 includes the surface emitting laser 10-1 as a light source. The distance measurement device 1000 includes, for example, the surface emitting laser 10-1, a light reception device 125, lenses 115 and 135, a signal processing unit 140, a control unit 150, a display unit 160, and a storage unit 170.

The light reception device 125 detects light reflected by the subject S. The lens 115 is a lens for parallelizing the light emitted from the surface emitting laser 10-1, and is a collimator lens. The lens 135 is a lens that condenses light reflected by the subject S and guides the light to the light reception device 125, and is a condenser lens.

The signal processing unit 140 is a circuit that generates a signal corresponding to a difference between a signal input from the light reception device 125 and a reference signal input from the control unit 150. The control unit 150 includes, for example, a Time to Digital Converter (TDC). The reference signal may be a signal input from the control unit 150, or may be an output signal of a detection unit that directly detects an output of the surface emitting laser 10-1. The control unit 150 is, for example, a processor that controls the surface emitting laser 10-1, the light reception device 125, the signal processing unit 140, the display unit 160, and the storage unit 170. The control unit 150 is a circuit that measures the distance to the subject S on the basis of the signal generated by the signal processing unit 140. The control unit 150 generates a video signal for displaying information on the distance to the subject S, and outputs the video signal to the display unit 160. The display unit 160 displays the information on the distance to the subject S on the basis of the video signal input from the control unit 150. The control unit 150 stores the information on the distance to the subject S in the storage unit 170.

In this application example, instead of the surface emitting laser 10-1, one of the above surface emitting lasers 10-2 to 10-16 can be also applied to the distance measurement device 1000.

### 20. Example where Distance Measurement Device is Mounted on Moving Body

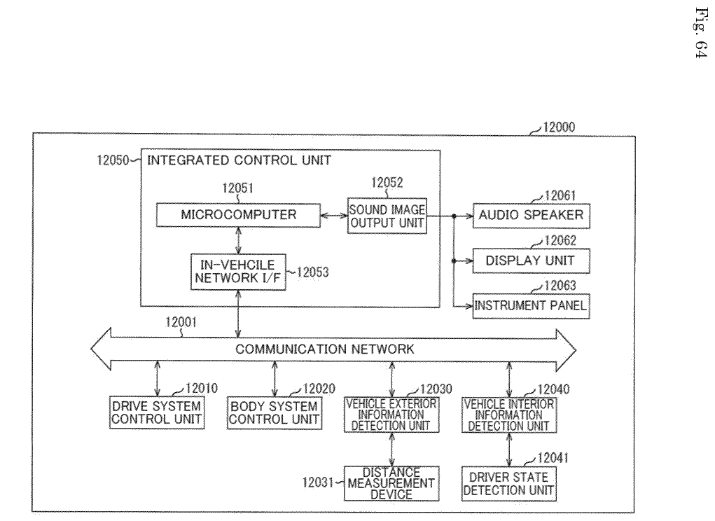

FIG. 64 is a block diagram illustrating a schematic configuration example of a vehicle control system that is an example of a moving body control system to which the technology according to the present disclosure can be applied.

The vehicle control system 12000 includes a plurality of electronic control units connected thereto via a communication network 12001. In the example illustrated in FIG. 64, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle on which the vehicle control system 12000 is mounted. For example, the vehicle exterior information detection unit 12030 is connected with a distance measurement device 12031. The distance measurement device 12031 includes the above-described distance measurement device 1000. The vehicle exterior information detection unit 12030 causes the distance measurement device 12031 to measure a distance to an object (subject S) outside the vehicle, and acquires distance data obtained by the measurement. The vehicle exterior information detection unit 12030 may perform object detection processing for people, vehicles, obstacles, signs, and the like on the basis of the acquired distance data.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information on the inside and the outside of the vehicle acquired by the vehicle exterior information detection unit 12030 or the vehicle interior information detection unit 12040, and output a control command to the drive system control unit 12010. For example, the microcomputer 12051 can perform cooperative control for the purpose of implementing functions of an Advanced Driver Assistance System (ADAS) including vehicle collision avoidance, impact mitigation, following traveling based on an inter-vehicle distance, vehicle speed maintenance driving, vehicle collision warning, vehicle lane deviation warning, and the like.

Furthermore, the microcomputer 12051 can perform cooperative control for the purpose of automated driving or the like in which autonomous travel is performed without depending on operations of the driver, by controlling the driving force generator, the steering mechanism, the braking device, or the like on the basis of information on the surroundings of the vehicle acquired by the vehicle exterior information detection unit 12030 or the vehicle interior information detection unit 12040.

In addition, the microcomputer 12051 can output a control command to the body system control unit 12020 on the basis of the information on the outside of the vehicle acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound image output unit 12052 transmits an output signal of at least one of sound and an image to an output device capable of visually or audibly notifying a passenger or the outside of the vehicle of information. In the example of FIG. 64, an audio speaker 12061, a display unit 12062, and an instrument panel 12063 are illustrated as examples of the output device. The display unit 12062 may include at least one of an on-board display and a head-up display, for example.

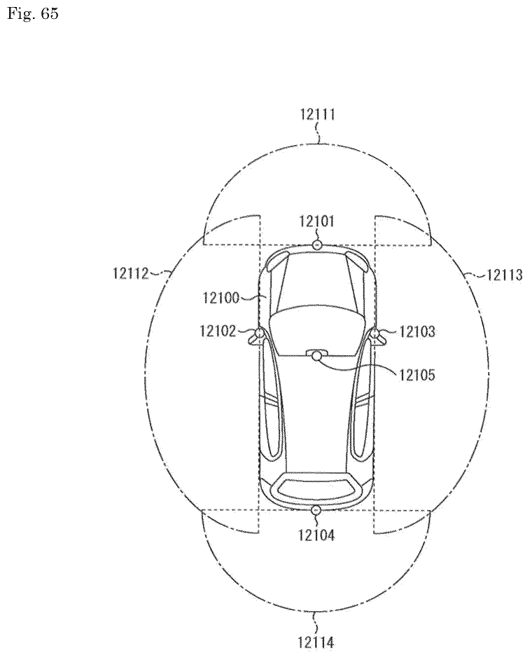

FIG. 65 is a diagram illustrating an example of an installation position of the distance measurement device 12031.

In FIG. 65, a vehicle 12100 includes distance measurement devices 12101, 12102, 12103, 12104, and 12105 as the distance measurement device 12031.

The distance measurement devices 12101, 12102, 12103, 12104, and 12105 are provided at, for example, positions of a front nose, side mirrors, a rear bumper, a back door, an upper part of a vehicle internal front windshield, and the like of the vehicle 12100. The distance measurement device 12101 provided on the front nose and the distance measurement device 12105 provided at an upper part of the front windshield inside the vehicle compartment mainly acquire data of a region in front of the vehicle 12100. The distance measurement devices 12102 and 12103 included in the side mirrors mainly acquire data of regions on the sides of the vehicle 12100. The distance measurement device 12104 included in the rear bumper or the back door mainly acquires data of a region behind the vehicle 12100. The data of the front region acquired by the distance measurement devices 12101 and 12105 are mainly used for detection of preceding vehicles, pedestrians, obstacles, traffic lights, traffic signs, lanes, and the like.

Note that FIG. 65 illustrates an example of detection ranges of the distance measurement devices 12101 to 12104. A detection range 12111 indicates a detection range of the distance measurement device 12101 provided at the front nose, detection ranges 12112 and 12113 respectively indicate detection ranges of the distance measurement devices 12102 and 12103 provided at the side mirrors, and a detection range 12114 indicates a detection range of the distance measurement device 12104 provided at the rear bumper or the back door.

By, for example, obtaining a distance to each three-dimensional object in the detection ranges 12111 to 12114 and temporal change in the distance (a relative speed with respect to the vehicle 12100) on the basis of distance data obtained from the distance measurement devices 12101 to 12104, the microcomputer 12051 can extract as a preceding vehicle, particularly, a closest three-dimensional object that is on a path of the vehicle 12100 and is traveling at a predetermined speed (e.g., 0 km/h or higher) in the substantially same direction as that of the vehicle 12100. Furthermore, the microcomputer 12051 can also set an inter-vehicle distance that needs to be secured in advance in front of the preceding vehicle, and perform automatic brake control (including tracking stop control, too) and automatic acceleration control (including tracking start control, too). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into other three-dimensional objects such as two-wheeled vehicles, normal vehicles, large vehicles, pedestrians, and electric poles on the basis of the distance data obtained from the distance measurement devices 12101 to 12104 and can use the three-dimensional data for automated avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

An example of the moving body control system to which the technology according to the present disclosure can be applied has been described above. The technology according to the present disclosure can be applied to the distance measurement device 12031 among the configurations described above.

In addition, the present technology can also have the following configurations.
(1) A surface emitting laser includes: first and second reflection mirrors that are mutually laminated; and
a middle part that is disposed between the first and second reflection mirrors, the middle part has a laminated structure formed by laminating a plurality of semiconductor structures including each of a mutually laminated active layer and tunnel junction layer as an intermediate layer, and
a peripheral part of at least the tunnel junction layer of the at least one semiconductor structure has higher resistance than resistance of a center part.
(2) In the surface emitting laser described in (1), a top layer of the laminated structure on a side of the second reflection mirror has lower resistance than the resistance of the peripheral part of the tunnel junction layer.
(3) In the surface emitting laser described in (2), the top layer is formed of an n-type semiconductor layer.
(4) In the surface emitting laser described in (2) or (3), the top layer is formed of an n-InP layer.
(5) In the surface emitting laser described in any one of (1) to (4), a top layer of the laminated structure on a side of the first reflection mirror has lower resistance than the resistance of the peripheral part of the tunnel junction layer.
(6) In the surface emitting laser described in (5), the top layer is formed of an n-type semiconductor layer.
(7) In the surface emitting laser described in (5) or (6), the top layer is formed of an n-InP layer.
(8) In the surface emitting laser described in any one of (1) to (7), the semiconductor structure includes a p-type semiconductor layer that is disposed between the active layer and the tunnel junction layer, a first n-type semiconductor layer that is disposed on an opposite side of the active layer to a side of the p-type semiconductor layer, and a second n-type semiconductor layer that is disposed on an opposite side of the tunnel junction layer to the side of the p-type semiconductor layer.
(9) In the surface emitting laser described in (8), the peripheral part of the p-type semiconductor layer has the higher resistance than the resistance of the center part in the semiconductor structure.
(10) In the surface emitting laser described in (9), the semiconductor structure is disposed such that the first n-type semiconductor layer is located on a side of the first reflection mirror, and the second n-type semiconductor layer is located on a side of the second reflection mirror, and the second n-type semiconductor layer of the semiconductor structure closest to the second reflection mirror, and the first n-type semiconductor layer of the semiconductor structure closest to the first reflection mirror have lower resistance than the resistance of the peripheral part of the p-type semiconductor layer.
(11) In the surface emitting laser described in (10), peripheral parts of all layers other than the second n-type semiconductor layer of the semiconductor structure closest to the second reflection mirror, and the first n-type semiconductor layer of the semiconductor structure closest to the first reflection mirror have higher resistance than the resistance of the center part in the laminated structure.
(12) In the surface emitting laser described in (10), peripheral parts of the second n-type semiconductor layer of the semiconductor structure closest to the second reflection mirror, the first n-type semiconductor layer of the semiconductor structure closest to the first reflection mirror, and all layers other than the first and second n-type semiconductor layers of the semiconductor structure located at a middle of the laminated structure have higher resistance than the resistance of the center part in the laminated structure.
(13) In the surface emitting laser described in (9), the semiconductor structure is disposed such that the first n-type semiconductor layer is located on a side of the second reflection mirror, and the second n-type semiconductor layer is located on a side of the first reflection mirror, and the first n-type semiconductor layer of the semiconductor structure closest to the second reflection mirror, and the second n-type semiconductor layer of the semiconductor structure closest to the first reflection mirror have lower resistance than the resistance of the peripheral part of the p-type semiconductor layer.
(14) In the surface emitting laser described in (13), peripheral parts of all layers other than the first n-type semiconductor layer of the semiconductor structure closest to the second reflection mirror, and the second n-type semiconductor layer of the semiconductor structure closest to the first reflection mirror have higher resistance than the resistance of the center part in the laminated structure.
(15) In the surface emitting laser described in (13), peripheral parts of the first n-type semiconductor layer of the semiconductor structure closest to the second reflection mirror, the second n-type semiconductor layer of the semiconductor structure closest to the first reflection mirror, and all layers other than the first and second n-type semiconductor layers of the semiconductor structure located at a middle of the laminated structure have higher resistance than the resistance of the center part in the laminated structure.
(16) In the surface emitting laser described in any one of (1) to (15), the tunnel junction layer of the semiconductor structure that is part of a plurality of the semiconductor structures is a burial type.
(17) In the surface emitting laser described in any one of (1) to (16), one of the first and second reflection mirrors is a dielectric multilayer film reflection mirror that has a photonic crystal structure.
(18) In the surface emitting laser described in any one of (1) to (17), the middle part includes a heat dissipation member between one of the first and second reflection mirrors and the laminated structure.
(19) A manufacturing method for a surface emitting laser includes:
a process of generating a laminated body including a semiconductor structure including each of an active layer and a tunnel junction layer as an intermediate layer; and
a process of making resistance of a peripheral part of at least the tunnel junction layer of the semiconductor structure higher than resistance of a center part by injecting an ion into the laminated body.
(20) According to the manufacturing method for the surface emitting laser described in (19), a top surface on one side and/or a top surface on an other side in a lamination direction of the laminated body is an n-type semiconductor layer, in the process of making the resistance higher, resistance of a peripheral part of the n-type semiconductor layer is made higher than the resistance of the center part, and the manufacturing method for the surface emitting laser further includes a process of performing annealing treatment on the laminated body after the process of making the resistance higher, and making the resistance of the peripheral part of the n-type semiconductor layer lower.
(21) According to the manufacturing method for the surface emitting laser described in (19) or (20), in the generating process, the laminated body formed by laminating a plurality of the semiconductor structures is generated.
(22) According to the manufacturing method for the surface emitting laser described in any one of (19) to (21), in the generating process, the laminated body is generated by laminating the semiconductor structure on a substrate.
(23) The manufacturing method for the surface emitting laser described in (22) further includes: a process of making the ion reach an inside of the substrate during the ion implantation, and pasting a support base on a surface of the laminated body on an opposite side to a side of the substrate after the process of making the resistance higher; and removing the substrate from the laminated body.
(24) The manufacturing method for the surface emitting laser described in (23) further includes a process of laminating on a surface of the laminated body from which the substrate has been removed a reflection mirror and a substrate.

### REFERENCE SIGNS LIST

10-1 to 10-16 Surface emitting laser
100 Substrate
101-1, 101-3, 105-12, 105-23 n-type semiconductor layer
102, 102-1, 102-2, 102-3 Active layer
103, 103-1, 103-2, 103-3, 104, 104-1, 104-2, 104-3 Tunnel junction layer
106 First reflection mirror
107 Second reflection mirror
GS Growth substrate (substrate)
MP Middle part
LS Laminated structure
SS Semiconductor structure
SS1 First semiconductor structure (semiconductor structure)
SS2 Second semiconductor structure (semiconductor structure)
SS3 Third semiconductor structure (semiconductor structure)

1. A surface emitting laser comprising:
first and second reflection mirrors that are mutually laminated; and
a middle part that is disposed between the first and second reflection mirrors, wherein
the middle part has a laminated structure formed by laminating a plurality of semiconductor structures including each of a mutually laminated active layer and tunnel junction layer as an intermediate layer, and
a peripheral part of at least the tunnel junction layer of the at least one semiconductor structure has higher resistance than resistance of a center part.

2. The surface emitting laser according to claim 1, wherein a top layer of the laminated structure on a side of the second reflection mirror has lower resistance than the resistance of the peripheral part of the tunnel junction layer.

3. The surface emitting laser according to claim 2, wherein the top layer is formed of an n-type semiconductor layer.

4. The surface emitting laser according to claim 2, wherein the top layer is formed of an n-InP layer.

5. The surface emitting laser according to claim 1, wherein a top layer of the laminated structure on a side of the first reflection mirror has lower resistance than the resistance of the peripheral part of the tunnel junction layer.

6. The surface emitting laser according to claim 5, wherein the top layer is formed of an n-type semiconductor layer.

7. The surface emitting laser according to claim 5, wherein the top layer is formed of an n-InP layer.

8. The surface emitting laser according to claim 1, wherein the semiconductor structure further include
a p-type semiconductor layer that is disposed between the active layer and the tunnel junction layer,
a first n-type semiconductor layer that is disposed on an opposite side of the active layer to a side of the p-type semiconductor layer, and
a second n-type semiconductor layer that is disposed on an opposite side of the tunnel junction layer to the side of the p-type semiconductor layer.

9. The surface emitting laser according to claim 8, wherein the peripheral part of the p-type semiconductor layer has the higher resistance than the resistance of the center part in the semiconductor structure.

10. The surface emitting laser according to claim 9, wherein
the semiconductor structure is disposed such that the first n-type semiconductor layer is located on a side of the first reflection mirror, and the second n-type semiconductor layer is disposed on a side of the second reflection mirror, and the second n-type semiconductor layer of the semiconductor structure closest to the second reflection mirror, and the first n-type semiconductor layer of the semiconductor structure closest to the first reflection mirror have lower resistance than the resistance of the peripheral part of the p-type semiconductor layer.

11. The surface emitting laser according to claim 10, wherein peripheral parts of all layers other than the second n-type semiconductor layer of the semiconductor structure closest to the second reflection mirror, and the first n-type semiconductor layer of the semiconductor structure closest to the first reflection mirror have higher resistance than the resistance of the center part in the laminated structure.

12. The surface emitting laser according to claim 10, wherein peripheral parts of the second n-type semiconductor layer of the semiconductor structure closest to the second reflection mirror, the first n-type semiconductor layer of the semiconductor structure closest to the first reflection mirror, and all layers other than the first and second n-type semiconductor layers of the semiconductor structure located at a middle of the laminated structure have higher resistance than the resistance of the center part in the laminated structure.

13. The surface emitting laser according to claim 9, wherein
the semiconductor structure is disposed such that the first n-type semiconductor layer is located on a side of the second reflection mirror, and the second n-type semiconductor layer is located on a side of the first reflection mirror, and the first n-type semiconductor layer of the semiconductor structure closest to the second reflection mirror, and the second n-type semiconductor layer of the semiconductor structure closest to the first reflection mirror have lower resistance than the resistance of the peripheral part of the p-type semiconductor layer.

14. The surface emitting laser according to claim 13, wherein peripheral parts of all layers other than the first n-type semiconductor layer of the semiconductor structure closest to the second reflection mirror, and the second n-type semiconductor layer of the semiconductor structure closest to the first reflection mirror have higher resistance than the resistance of the center part in the laminated structure.

15. The surface emitting laser according to claim 13, wherein peripheral parts of the first n-type semiconductor layer of the semiconductor structure closest to the second reflection mirror, the second n-type semiconductor layer of the semiconductor structure closest to the first reflection mirror, and all layers other than the first and second n-type semiconductor layers of the semiconductor structure located at a middle of the laminated structure have higher resistance than the resistance of the center part in the laminated structure.

16. The surface emitting laser according to claim 1, wherein the tunnel junction layer of the semiconductor structure that is part of a plurality of the semiconductor structures is a burial type.

17. The surface emitting laser according to claim 1, wherein one of the first and second reflection mirrors is a dielectric multilayer film reflection mirror that has a photonic crystal structure.

18. The surface emitting laser according to claim 1, wherein the middle part includes a heat dissipation member between one of the first and second reflection mirrors and the laminated structure.

19. A manufacturing method for a surface emitting laser, comprising:
a step of generating a laminated body formed by laminating a plurality of semiconductor structures each including each of an active layer and a tunnel junction layer as an intermediate layer; and
a step of making resistance of a peripheral part of at least the tunnel junction layer of the semiconductor structure higher than resistance of a center part by injecting an ion into the laminated body.

20. The manufacturing method for the surface emitting laser according to claim 19, wherein
a top surface on one side and/or a top surface on an other side of the laminated body is an n-type semiconductor layer,
in the step of making the resistance higher, resistance of a peripheral part of the n-type semiconductor layer is made higher than the resistance of the center part, and
the manufacturing method for the surface emitting laser further comprises a step of performing annealing treatment on the laminated body after the step of making the resistance higher, and making the resistance of the peripheral part of the n-type semiconductor layer lower.
